(19) United States
(12) Patent Application Publication
(10) Pub. No.: US 2020/0328728 A1
(43) Pub. Date: Oct. 15, 2020

(54) ACOUSTIC WAVE DEVICE, MULTIPLEXER, RADIO-FREQUENCY FRONT-END CIRCUIT, AND COMMUNICATION DEVICE

(71) Applicant: Murata Manufacturing Co., Ltd., Nagaokakyo-shi (JP)

(72) Inventors: Ryo NAKAGAWA, Nagaokakyo-shi (JP); Hideki IWAMOTO, Nagaokakyo-shi (JP); Tsutomu TAKAI, Nagaokakyo-shi (JP); Sunao YAMAZAKI, Nagaokakyo-shi (JP)

(21) Appl. No.: 16/914,520

(22) Filed: Jun. 29, 2020

Related U.S. Application Data
(63) Continuation of application No. PCT/JP2018/046696, filed on Dec. 19, 2018.

(30) Foreign Application Priority Data
Jan. 12, 2018 (JP) 2018-003866

(51) Int. Cl. H03H 9/205; H03H 9/02; H03H 9/145; H04B 1/00

(52) U.S. Cl. CPC H03H 9/205; H03H 9/02228; H04B 1/0057; H03H 9/02559; H03H 9/14541

(57) ABSTRACT

Of a plurality of acoustic wave resonators, the acoustic wave resonator electrically closest to a first terminal is an antenna end resonator, the antenna end resonator is a first acoustic wave resonator and at least one acoustic wave resonator other than the antenna end resonator of the plurality of acoustic wave resonators is a second acoustic wave resonator. An acoustic wave device satisfies a first condition. The first condition is a condition that a high acoustic velocity layer of the first acoustic wave resonator and a high acoustic velocity layer of the second acoustic wave resonator each include a silicon substrate, a surface closer to a piezoelectric layer in the silicon substrate of the first acoustic wave resonator is a plane or a plane, and a surface closer to a piezoelectric layer in the silicon substrate of the second acoustic wave resonator is a plane.

### CROSS REFERENCE TO RELATED APPLICATIONS

This application claims the benefit of priority to Japanese Patent Application No. 2018-003866 filed on Jan. 12, 2018 and is a Continuation Application of PCT Application No. PCT/JP2018/046696 filed on Dec. 19, 2018. The entire contents of each application are hereby incorporated herein by reference.

### BACKGROUND OF THE INVENTION

### 1. Field of the Invention

The present invention generally relates to an acoustic wave device, a multiplexer, a radio-frequency front-end circuit, and a communication device and, more specifically, to an acoustic wave device, a multiplexer, a radio-frequency front-end circuit, and a communication device that include a plurality of acoustic wave resonators.

### 2. Description of the Related Art

Hitherto, acoustic wave devices including a piezoelectric film are known as acoustic wave devices that are used as resonators (acoustic wave resonators), or the like (see, for example, International Publication No. 2012/086639).

The acoustic wave device described in International Publication No. 2012/086639 includes a high acoustic velocity support substrate through which bulk waves propagate at an acoustic velocity higher than acoustic waves propagate through a piezoelectric film, a low acoustic velocity film laminated on the high acoustic velocity support substrate and through which bulk waves propagate at an acoustic velocity lower than bulk waves propagate through the piezoelectric film, the piezoelectric film laminated on the low acoustic velocity film, and an interdigital transducer electrode formed on one surface of the piezoelectric film.

International Publication No. 2012/086639 describes that an electrode structure including an interdigital transducer electrode is not limited and may be modified to define a ladder filter, a longitudinally coupled filter, a lattice filter, and a transversal filter, in which resonators are combined.

With the acoustic wave device described in International Publication No. 2012/086639, there is an inconvenience that higher modes occur at frequencies higher than the resonant frequency of the acoustic wave resonator. There is also an inconvenience that higher modes occur in the acoustic wave device when the acoustic wave device described in International Publication No. 2012/086639 is applied to each of a multiplexer, a radio-frequency front-end circuit, and a communication device.

### SUMMARY OF THE INVENTION

Preferred embodiments of the present invention provide acoustic wave devices, multiplexers, radio-frequency front-end circuits, and communication devices that are each able to significantly reduce or prevent higher modes.

An acoustic wave device according to a preferred embodiment of the present invention is provided between a first terminal defining and functioning as an antenna terminal and a second terminal different from the first terminal. The acoustic wave device includes a plurality of acoustic wave resonators. The plurality of acoustic wave resonators include a plurality of series arm resonators provided in a first path connecting the first terminal and the second terminal, and a plurality of parallel arm resonators provided in a plurality of second paths each connecting an associated one of a plurality of nodes in the first path and a ground. Where, of the plurality of acoustic wave resonators, the acoustic wave resonator electrically closest to the first terminal is an antenna end resonator, the antenna end resonator is a first acoustic wave resonator, a SAW resonator, or a BAW resonator, and, of the plurality of acoustic wave resonators, at least one acoustic wave resonator other than the antenna end resonator is a second acoustic wave resonator or a third acoustic wave resonator. Where the antenna end resonator is the first acoustic wave resonator, the at least one acoustic wave resonator is the second acoustic wave resonator. Where the antenna end resonator is the SAW resonator or the BAW resonator, the at least one acoustic wave resonator is the third acoustic wave resonator. The SAW resonator includes a piezoelectric substrate and an interdigital transducer electrode including a plurality of electrode fingers. The interdigital transducer electrode is provided on or above the piezoelectric substrate. Each of the first acoustic wave resonator, the second acoustic wave resonator, and the third acoustic wave resonator includes a piezoelectric layer, an interdigital transducer electrode including a plurality of electrode fingers, and a high acoustic velocity layer. The interdigital transducer electrode of each of the first acoustic wave resonator, the second acoustic wave resonator, and the third acoustic wave resonator is provided on or above the piezoelectric layer. The high acoustic velocity member is located across the piezoelectric layer from the interdigital transducer electrode. Bulk waves propagate through the high acoustic velocity member at an acoustic velocity higher than acoustic waves propagate through the piezoelectric layer. In each of the first acoustic wave resonator, the second acoustic wave resonator, and the third acoustic wave resonator, where a wave length of acoustic waves, which is determined by an electrode finger pitch of the interdigital transducer electrode, is λ, a thickness of the piezoelectric layer is less than or equal to about 3.5λ. Where the antenna end resonator is the first acoustic wave resonator and the at least one acoustic wave resonator is the second acoustic wave resonator, the acoustic wave device satisfies at least one of a first condition, a second condition, and a third condition. The first condition is a condition that the high acoustic velocity member of the first acoustic wave resonator and the high acoustic velocity member of the second acoustic wave resonator each include a silicon substrate, a surface closer to the piezoelectric layer in the silicon substrate of the first acoustic wave resonator is a (111) plane or a (110) plane, and a surface closer to the piezoelectric layer in the silicon substrate of the second acoustic wave resonator is a (100) plane. The second condition is a condition that the piezoelectric layer of the first acoustic wave resonator is thinner than the piezoelectric layer of the second acoustic wave resonator. The third condition is a condition that each of the first acoustic wave resonator and the second acoustic wave resonator includes a low acoustic velocity film and the low acoustic velocity film of the first acoustic wave resonator is thinner than the low acoustic velocity film of the second acoustic wave resonator. The low acoustic velocity film is provided between the high acoustic velocity member and the piezoelectric layer. Bulk waves propagate through the low acoustic velocity film at an acoustic velocity lower than bulk waves propagate through the piezoelectric layer.

A multiplexer according to a preferred embodiment of the present invention includes a first filter including the acoustic wave device, and a second filter. The second filter is provided between the first terminal and a third terminal different from the first terminal. A pass band of the first filter is at lower frequencies than a pass band of the second filter.

A radio-frequency front-end circuit according to a preferred embodiment of the present invention includes the above-described multiplexer and an amplifier circuit connected to the multiplexer.

A communication device according to a preferred embodiment of the present invention includes a radio-frequency front-end circuit and an RF signal processing circuit. The RF signal processing circuit is configured to process a radio-frequency signal received by an antenna. The radio-frequency front-end circuit is configured to transmit the radio-frequency signal between the antenna and the RF signal processing circuit.

The acoustic wave devices, the multiplexers, the radio-frequency front-end circuits, and the communication devices according to preferred embodiments of the present invention are each able to significantly reduce or prevent higher modes.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of an acoustic wave device according to a first preferred embodiment of the present invention.

FIG. 2 is a diagram of a communication device including the above acoustic wave device.

FIG. 3A is a cross-sectional view of a first acoustic wave resonator in the above acoustic wave device. FIG. 3B is a cross-sectional view of a second acoustic wave resonator in the above acoustic wave device.

FIG. 4A is a plan view of a main portion of the first acoustic wave resonator in the above acoustic wave device. FIG. 4B is a cross-sectional view of the first acoustic wave resonator in the above acoustic wave device, taken along the line A-A in FIG. 4A.

FIG. 5A is a plan view of a main portion of the second acoustic wave resonator in the above acoustic wave device. FIG. 5B is a cross-sectional view of the second acoustic wave resonator in the above acoustic wave device, taken along the line A-A in FIG. 5A.

FIG. 6 is the impedance-frequency characteristic curve of each of the first acoustic wave resonator and the second acoustic wave resonator in the above acoustic wave device.

FIG. 7 is the phase-frequency characteristic curve of each of the first acoustic wave resonator and the second acoustic wave resonator in the above acoustic wave device.

FIG. 8A is a cross-sectional view of a first acoustic wave resonator in an acoustic wave device according to a first modification of the first preferred embodiment of the present invention. FIG. 8B is a cross-sectional view of a second acoustic wave resonator in the above acoustic wave device.

FIG. 9 is a circuit diagram of a multiplexer according to a second modification of the first preferred embodiment of the present invention.

FIG. 10 is a circuit diagram of an acoustic wave device according to a third modification of the first preferred embodiment of the present invention.

FIG. 11A is a cross-sectional view of a first acoustic wave resonator in an acoustic wave device according to a second preferred embodiment of the present invention. FIG. 11B is a cross-sectional view of a second acoustic wave resonator in the above acoustic wave device.

FIG. 12 is a graph showing the relationship between the thickness of an interdigital transducer electrode and a higher mode phase characteristic for an acoustic wave resonator according to a first reference example.

FIG. 13 is a graph showing the relationship between the thickness of an interdigital transducer electrode and a resonant frequency for the acoustic wave resonator according to the first reference example.

FIG. 14 is a graph showing the relationship between the thickness of an interdigital transducer electrode and the dependence of a resonant frequency on the thickness of the interdigital transducer electrode for the acoustic wave resonator according to the first reference example.

FIG. 15 is a graph showing the relationship between the thickness of an interdigital transducer electrode and TCF (the temperature coefficient of frequency) for an acoustic wave resonator according to a second reference example.

FIG. 16 is a reflection characteristic curve of the acoustic wave resonator according to the second reference example.

FIG. 17 is the frequency characteristic curve of impedance for the acoustic wave resonator according to the second reference example.

FIG. 18A is a cross-sectional view of a first acoustic wave resonator in an acoustic wave device according to a third preferred embodiment of the present invention. FIG. 18B is a cross-sectional view of a second acoustic wave resonator in the above acoustic wave device.

FIG. 19 is a graph showing the relationship between the thickness of a piezoelectric layer and a higher mode phase characteristic for an acoustic wave resonator according to a third reference example.

FIG. 20 is a graph showing the relationship between the thickness of a piezoelectric layer and a quality factor for the acoustic wave resonator according to the third reference example.

FIG. 21A is a cross-sectional view of a first acoustic wave resonator in an acoustic wave device according to a first modification of the third preferred embodiment of the present invention. FIG. 21B is a cross-sectional view of a second acoustic wave resonator in the above acoustic wave device.

FIG. 22 is a cross-sectional view of a first acoustic wave resonator and a second acoustic wave resonator of an acoustic wave device according to a second modification of the third preferred embodiment of the present invention.

FIG. 23 is a circuit diagram of the above acoustic wave device.

FIG. 24A is a cross-sectional view of a first acoustic wave resonator in an acoustic wave device according to a fourth preferred embodiment of the present invention. FIG. 24B is a cross-sectional view of a second acoustic wave resonator in the above acoustic wave device.

FIG. 25 is a graph showing the relationship between the thickness of a low acoustic velocity film and a higher mode phase characteristic for an acoustic wave resonator according to a fourth reference example.

FIG. 26 is a graph showing the relationship between the thickness of a low acoustic velocity film and a quality factor for the acoustic wave resonator according to the fourth reference example.

FIG. 27 is a cross-sectional view of a first acoustic wave resonator and a second acoustic wave resonator of an acoustic wave device according to a modification of the fourth preferred embodiment of the present invention.

FIG. 28A is a cross-sectional view of a first acoustic wave resonator in an acoustic wave device according to a fifth preferred embodiment of the present invention. FIG. 28B is a cross-sectional view of a second acoustic wave resonator in the above acoustic wave device.

FIG. 29 is a graph showing the relationship between the thickness of a dielectric film and a TCF for an acoustic wave resonator according to a fifth reference example.

FIG. 30 is a graph showing the relationship between the thickness of a dielectric film and a fractional band width for the acoustic wave resonator according to the fifth reference example.

FIG. 31 is a cross-sectional view of a first acoustic wave resonator and a second acoustic wave resonator in an acoustic wave device according to a first modification of the fifth preferred embodiment of the present invention.

FIG. 32A is a cross-sectional view of a first acoustic wave resonator in an acoustic wave device according to a second modification of the fifth preferred embodiment of the present invention. FIG. 32B is a cross-sectional view of a second acoustic wave resonator in the above acoustic wave device.

FIG. 33 is a cross-sectional view of a first acoustic wave resonator and a second acoustic wave resonator in an acoustic wave device according to a third modification of the fifth preferred embodiment of the present invention.

FIG. 34A is a cross-sectional view of a first acoustic wave resonator in an acoustic wave device according to a sixth preferred embodiment of the present invention. FIG. 34B is a cross-sectional view of a second acoustic wave resonator in the above acoustic wave device.

FIG. 35 is a graph showing the relationship between the cut angle of a piezoelectric layer and an electromechanical coupling coefficient for an acoustic wave resonator according to a sixth reference example.

FIG. 36 is a graph showing the relationship between the cut angle of a piezoelectric layer and a TCF for the acoustic wave resonator according to the sixth reference example.

FIG. 37 is a graph showing the relationship between the cut angle of a piezoelectric layer and a fractional band width for the acoustic wave resonator according to the sixth reference example.

FIG. 38A is a plan view of a SAW resonator in an acoustic wave device according to a seventh preferred embodiment of the present invention. FIG. 38B is a cross-sectional view of the SAW resonator in the above acoustic wave device, taken along the line A-A in FIG. 38A.

FIG. 39 is a cross-sectional view of a third acoustic wave resonator in the above acoustic wave device.

FIG. 40 is a graph showing the frequency characteristics of phase of each of the SAW resonator and the third acoustic wave resonator in the above acoustic wave device.

FIG. 41 is a graph showing another example of the frequency characteristics of phase of each of the SAW resonator and the third acoustic wave resonator in the above acoustic wave device.

FIG. 42 is a cross-sectional view of a BAW resonator in an acoustic wave device according to a first modification of the seventh preferred embodiment of the present invention.

FIG. 43 is a cross-sectional view of a BAW resonator in an acoustic wave device according to a second modification of the seventh preferred embodiment of the present invention.

### DETAILED DESCRIPTION OF THE PREFERRED EMBODIMENTS

Hereinafter, acoustic wave devices, multiplexers, radio-frequency front-end circuits, and communication devices according to preferred embodiments will be described with reference to the drawings.

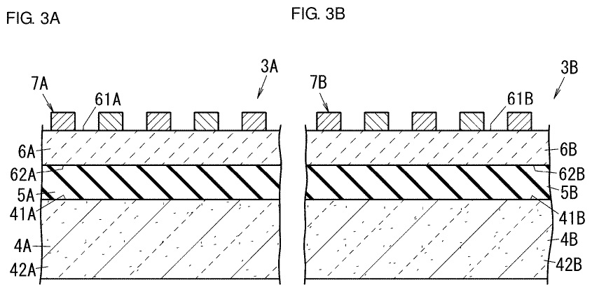

FIGS. 3A and 3B, FIGS. 4A and 4B, FIGS. 5A and 5B, FIGS. 8A and 8B, FIGS. 11A and 11B, FIGS. 18A and 18B, FIGS. 21A and 21B, FIG. 22, FIGS. 24A and 24B, FIG. 27, FIGS. 28A and 28B, FIG. 31, FIGS. 32A and 32B, FIG. 33, FIGS. 34A and 34B, FIGS. 38A and 38B, FIG. 39, FIG. 42, and FIG. 43 that will be referenced in the following preferred embodiments, and the like, all are schematic diagrams, and the ratios of the sizes and thicknesses of components in the drawings do not always reflect actual scale ratios.

### First Preferred Embodiment

### (1.1) Overall Configuration of Each of Acoustic Wave Device, Multiplexer, Radio-Frequency Front-End Circuit, and Communication Device

Hereinafter, an acoustic wave device 1, a multiplexer 100, a radio-frequency front-end circuit 300, and a communication device 400 according to a first preferred embodiment of the present invention will be described with reference to the drawings.

### (1.1.1) Acoustic Wave Device

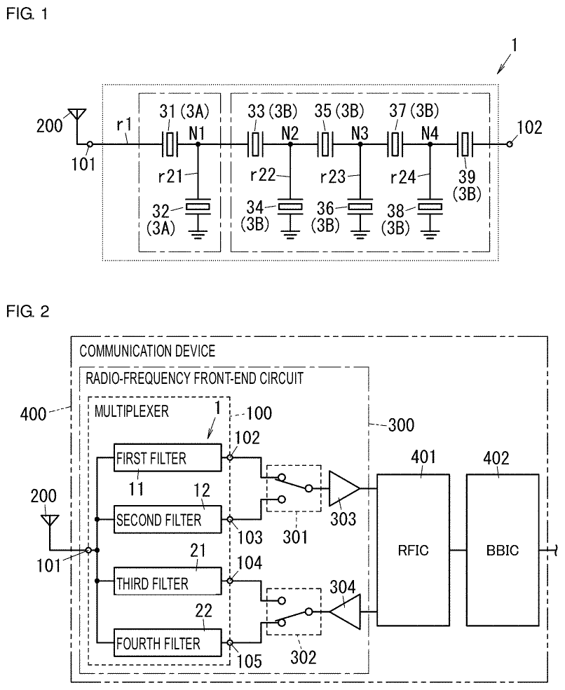

As shown in FIG. 1, the acoustic wave device 1 according to the first preferred embodiment is provided between a first terminal 101 defining and functioning as an antenna terminal electrically connected to an antenna 200 outside the acoustic wave device 1 and a second terminal 102 different from the first terminal 101. The acoustic wave device 1 is a ladder filter, and includes a plurality of (for example, nine) acoustic wave resonators 31 to 39. The plurality of acoustic wave resonators 31 to 39 include a plurality of (for example, five) series arm resonators (acoustic wave resonators 31, 33, 35, 37, 39) provided in a first path r1 connecting the first terminal 101 and the second terminal 102 and a plurality of (four) parallel arm resonators (acoustic wave resonators 32, 34, 36, 38) provided in a plurality of (four) second paths r21, r22, r23, r24 respectively connecting a plurality of (four) nodes N1, N2, N3, N4 in the first path r1 to a ground. In the acoustic wave device 1, an element that defines and functions as an inductor or a capacitor may be included as an element other than the series arm resonators in the first path r1. In the acoustic wave device 1, an element that defines and functions as an inductor or a capacitor may be included as an element other than the parallel arm resonator in each of the second paths r21, r22, r23, r24.

### (1.1.2) Multiplexer

As shown in FIG. 2, the multiplexer 100 according to the first preferred embodiment includes the first terminal 101, the second terminal 102, a third terminal 103, a first filter 11 including the acoustic wave device 1, and a second filter 12.

The first terminal 101 is an antenna terminal to be electrically connected to the antenna 200 outside the multiplexer 100.

The first filter 11 is a first receiving filter provided between the first terminal 101 and the second terminal 102. The first filter 11 passes signals in a pass band of the first filter 11 and attenuates signals outside the pass band.

The second filter 12 is a second receiving filter provided between the first terminal 101 and the third terminal 103. The second filter 12 passes signals in a pass band of the second filter 12 and attenuates signals outside the pass band.

The first filter 11 and the second filter 12 have the different pass bands. In the multiplexer 100, the pass band of the first filter 11 is at frequencies lower than the pass band of the second filter 12. Therefore, in the multiplexer 100, the pass band of the second filter 12 is at higher frequencies than the pass band of the first filter 11. In the multiplexer 100, for example, the maximum frequency of the pass band of the first filter 11 is lower than the minimum frequency of the pass band of the second filter 12.

In the multiplexer 100, the first filter 11 and the second filter 12 are connected to the common first terminal 101.

The multiplexer 100 further includes a fourth terminal 104, a fifth terminal 105, a third filter 21, and a fourth filter 22. However, in the multiplexer 100, the fourth terminal 104, the fifth terminal 105, the third filter 21, and the fourth filter 22 are not indispensable components.

The third filter 21 is a first transmission filter provided between the first terminal 101 and the fourth terminal 104. The third filter 21 passes signals in a pass band of the third filter 21 and attenuates signals outside the pass band.

The fourth filter 22 is a second transmission filter provided between the first terminal 101 and the fifth terminal 105. The fourth filter 22 passes signals in a pass band of the fourth filter 22 and attenuates signals outside the pass band.

### (1.1.3) Radio-Frequency Front-End Circuit

As shown in FIG. 2, the radio-frequency front-end circuit 300 includes the multiplexer 100, an amplifier circuit 303 (hereinafter, also referred to as first amplifier circuit 303), and a switch circuit 301 (hereinafter, also referred to as first switch circuit 301). The radio-frequency front-end circuit 300 further includes an amplifier circuit 304 (hereinafter, also referred to as second amplifier circuit 304), and a switch circuit 302 (hereinafter, also referred to as second switch circuit 302). However, in the radio-frequency front-end circuit 300, the second amplifier circuit 304 and the second switch circuit 302 are not indispensable components.

The first amplifier circuit 303 amplifies a radio-frequency signal (reception signal) passing through the antenna 200, the multiplexer 100, and the first switch circuit 301, and outputs the radio-frequency signal. The first amplifier circuit 303 is a low-noise amplifier circuit.

The first switch circuit 301 includes two selection terminals individually connected to the second terminal 102 and the third terminal 103 of the multiplexer 100, and a common terminal connected to the first amplifier circuit 303. In other words, the first switch circuit 301 is connected to the first filter 11 via the second terminal 102 and connected to the second filter 12 via the third terminal 103.

The first switch circuit 301 is preferably defined by, for example, an SPDT (single pole double throw) switch. The first switch circuit 301 is controlled by a control circuit. The first switch circuit 301 connects the common terminal to any one of the selection terminals in accordance with a control signal from the control circuit. The first switch circuit 301 may be defined by, for example, a switch IC (integrated circuit). In the first switch circuit 301, the number of the selection terminals to be connected to the common terminal is not limited to one and may be multiple. In other words, the radio-frequency front-end circuit 300 may support carrier aggregation.

The second amplifier circuit 304 amplifies a radio-frequency signal (transmission signal) output from a component (for example, an RF signal processing circuit 401 (described later)) outside the radio-frequency front-end circuit 300, and outputs the radio-frequency signal to the antenna 200 via the second switch circuit 302 and the multiplexer 100. The second amplifier circuit 304 is a power amplifier circuit.

The second switch circuit 302 is preferably defined by, for example, an SPDT switch. The second switch circuit 302 is controlled by the above-described control circuit. The second switch circuit 302 connects a common terminal to any one of selection terminals in accordance with a control signal from the control circuit. The second switch circuit 302 may be defined by, for example, a switch IC. In the second switch circuit 302, the number of the selection terminals to be connected to the common terminal is not limited to one and may be multiple.

### (1.1.4) Communication Device

As shown in FIG. 2, the communication device 400 includes the RF signal processing circuit 401 and the radio-frequency front-end circuit 300. The RF signal processing circuit 401 processes a radio-frequency signal received by the antenna 200. The radio-frequency front-end circuit 300 transmits a radio-frequency signal (a reception signal or a transmission signal) between the antenna 200 and the RF signal processing circuit 401. The communication device 400 further includes a baseband signal processing circuit 402. The baseband signal processing circuit 402 is not an indispensable component.

The RF signal processing circuit 401 is preferably, for example, an RFIC (radio frequency integrated circuit), and performs signal processing on a radio-frequency signal (reception signal). For example, the RF signal processing circuit 401 performs signal processing on a radio-frequency signal (reception signal) input from the antenna 200 via the radio-frequency front-end circuit 300 by down conversion, or the like and outputs the reception signal generated through the signal processing to the baseband signal processing circuit 402. The baseband signal processing circuit 402 is, for example, a BBIC (baseband integrated circuit). A reception signal processed by the baseband signal processing circuit 402 is, for example, used to display an image as an image signal or to talk as a voice signal.

The RF signal processing circuit 401, for example, performs signal processing on a radio-frequency signal (transmission signal) output from the baseband signal processing circuit 402 by up conversion, or the like and outputs the processed radio-frequency signal to the second amplifier circuit 304. The baseband signal processing circuit 402, for example, performs predetermined signal processing on a transmission signal from a device outside the communication device 400.

### (1.2) Acoustic Wave Device

As shown in FIG. 1, in the acoustic wave device 1, where, of the plurality of acoustic wave resonators 31 to 39, the acoustic wave resonator 31 electrically closest to the first terminal 101 is an antenna end resonator, the antenna end resonator is a first acoustic wave resonator 3A (see FIG. 3A) and, of the plurality of acoustic wave resonators 31 to 39, at least one acoustic wave resonator 31 to 39 other than the antenna end resonator is a second acoustic wave resonator 3B (see FIG. 3B). In the acoustic wave device 1 according to the first preferred embodiment, the series arm resonator electrically closest to the first terminal 101 of the plurality of series arm resonators and the parallel arm resonator electrically closest to the first terminal 101 of the plurality of parallel arm resonators each are the first acoustic wave resonator 3A.

### (1.3) Configurations of First Acoustic Wave Resonator and Second Acoustic Wave Resonator

As shown in FIGS. 3A and 3B, the first acoustic wave resonator 3A includes a piezoelectric layer 6A, an IDT (interdigital transducer) electrode 7A, and a high acoustic velocity member 4A, and the second acoustic wave resonator 3B includes a piezoelectric layer 6B, an IDT (interdigital transducer) electrode 7B, and a high acoustic velocity member 4B. The interdigital transducer electrode 7A is provided on or above the piezoelectric layer 6A. The interdigital transducer electrode 7B is provided on or above the piezoelectric layer 6B. The state of being provided on or above the piezoelectric layer 6A or the piezoelectric layer 6B includes a state of being directly provided on the piezoelectric layer 6A or the piezoelectric layer 6B and a state of being indirectly provided on the piezoelectric layer 6A or the piezoelectric layer 6B. The high acoustic velocity member 4A is located across the piezoelectric layer 6A from the interdigital transducer electrode 7A. The high acoustic velocity member 4B is located across the piezoelectric layer 6B from the interdigital transducer electrode 7B. The piezoelectric layer 6A includes a first main surface 61A closer to the interdigital transducer electrode 7A and a second main surface 62A closer to the high acoustic velocity member 4A. The piezoelectric layer 6B includes a first main surface 61B closer to the interdigital transducer electrode 7B and a second main surface 62B closer to the high acoustic velocity member 4B. Bulk waves propagate through the high acoustic velocity member 4A at an acoustic velocity higher than acoustic waves propagate through the piezoelectric layer 6A. Bulk waves propagate through the high acoustic velocity member 4B at an acoustic velocity higher than acoustic waves propagate through the piezoelectric layer 6B.

In each of the first acoustic wave resonator 3A and the second acoustic wave resonator 3B, the thickness of the piezoelectric layer 6A or the piezoelectric layer 6B is preferably, for example, less than or equal to about 3.5λ where the wave length of acoustic waves, which is determined by the electrode finger pitch of the interdigital transducer electrode 7A or the interdigital transducer electrode 7B, is λ. In each of the first acoustic wave resonator 3A and the second acoustic wave resonator 3B, when the thickness of the piezoelectric layer 6A or the piezoelectric layer 6B is less than or equal to about 3.5λ, the quality factor increases; however, higher modes also occur.

The first acoustic wave resonator 3A further includes a low acoustic velocity film 5A. The second acoustic wave resonator 3B further includes a low acoustic velocity film 5B. The low acoustic velocity film 5A is provided between the high acoustic velocity member 4A and the piezoelectric layer 6A. The low acoustic velocity film 5B is provided between the high acoustic velocity member 4B and the piezoelectric layer 6B. Bulk waves propagate through the low acoustic velocity film 5A at an acoustic velocity lower than bulk waves propagate through the piezoelectric layer 6A. Bulk waves propagate through the low acoustic velocity film 5B at an acoustic velocity lower than bulk waves propagate through the piezoelectric layer 6B. The high acoustic velocity member 4A is a high acoustic velocity support substrate 42A. The high acoustic velocity member 4B is a high acoustic velocity support substrate 42B. The high acoustic velocity support substrate 42A supports the low acoustic velocity film 5A, the piezoelectric layer 6A, and the interdigital transducer electrode 7A. The high acoustic velocity support substrate 42B supports the low acoustic velocity film 5B, the piezoelectric layer 6B, and the interdigital transducer electrode 7B. A bulk wave that propagates at the lowest acoustic velocity of a plurality of bulk waves that propagate through the high acoustic velocity support substrate 42A propagates at an acoustic velocity higher than acoustic waves propagate through the piezoelectric layer 6A. A bulk wave that propagates at the lowest acoustic velocity of a plurality of bulk waves that propagate through the high acoustic velocity support substrate 42B propagates at an acoustic velocity higher than acoustic waves propagate through the piezoelectric layer 6B. The first acoustic wave resonator 3A is a one-port acoustic wave resonator including a reflector (for example, a short-circuited grating) at each side in an acoustic wave propagation direction of the interdigital transducer electrode 7A. The second acoustic wave resonator 3B is a one-port acoustic wave resonator including a reflector (for example, a short-circuited grating) at each side in an acoustic wave propagation direction of the interdigital transducer electrode 7B. However, the reflectors are not indispensable. Each of the first acoustic wave resonator 3A and the second acoustic wave resonator 3B is not limited to a one-port acoustic wave resonator and may be, for example, a longitudinally coupled acoustic wave resonator including a plurality of interdigital transducer electrodes.

### (1.3.1) Piezoelectric Layer

Each of the piezoelectric layers 6A, 6B is preferably, for example, Γ° Y-cut X-propagation LiTaO₃ piezoelectric monocrystal (for example, 50° Y-cut X-propagation LiTaO₃ piezoelectric monocrystal). Where the three crystal axes of the LiTaO₃ piezoelectric monocrystal are an X-axis, a Y-axis, and a Z-axis, the Γ° Y-cut X-propagation LiTaO₃ piezoelectric monocrystal is a LiTaO₃ monocrystal cut along a plane of which the direction of normal is an axis rotated by Γ° in the direction from the Y-axis to the Z-axis about the X-axis and is a monocrystal through which surface acoustic waves propagate in the X-axis direction. Γ° is, for example, about 50°. The cut angle of each of the piezoelectric layers 6A, 6B is expressed by Γ=θ+90° where the cut angle is Γ[° ] and the Euler angles of each of the piezoelectric layers 6A, 6B are (ϕ, θ, ψ). Γ and Γ±180×n are synonymous with each other (crystallographically equivalent). Here, n is a natural number. Each of the piezoelectric layers 6A, 6B is not limited to the Γ° Y-cut X-propagation LiTaO₃ piezoelectric monocrystal and may be, for example, Γ° Y-cut X-propagation LiTaO₃ piezoelectric ceramics.

In the first acoustic wave resonators 3A and the second acoustic wave resonators 3B in the acoustic wave device 1 according to the first preferred embodiment, there are modes of longitudinal wave, SH (shear horizontal) wave, SV (shear vertical) wave, or a combination of some of these waves as modes of acoustic waves that propagate through each of the piezoelectric layers 6A, 6B. In the first acoustic wave resonators 3A and the second acoustic wave resonators 3B, a mode having an SH wave as a main component is used as a main mode. Higher modes are spurious modes that occur at frequencies higher than the main mode of acoustic waves that propagate through the piezoelectric layer 6A or the piezoelectric layer 6B. Whether the mode of acoustic waves that propagate through the piezoelectric layer 6A or the piezoelectric layer 6B is a main mode that is a mode including an SH wave as a main component is determined by analyzing a displacement distribution with a finite element method and then analyzing a strain by using, for example, the parameters (material, Euler angles, thickness, and the like) of the piezoelectric layer 6A or the piezoelectric layer 6B, the parameters (material, thickness, electrode finger pitch, and the like) of the interdigital transducer electrode 7A or the interdigital transducer electrode 7B, the parameters (material, thickness, and the like) of the low acoustic velocity film 5A or the low acoustic velocity film 5B, and the like. The Euler angles of each of the piezoelectric layers 6A, 6B are determined by analysis.

The material of each of the piezoelectric layers 6A, 6B is not limited to LiTaO₃ (lithium tantalate) and may be, for example, LiNbO₃ (lithium niobate). When each of the piezoelectric layers 6A, 6B is made of, for example, a Y-cut X-propagation LiNbO₃ piezoelectric monocrystal or a piezoelectric ceramics, the first acoustic wave resonator 3A and the second acoustic wave resonator 3B are able to use a mode having an SH wave as a main component as a main mode by using Love waves as acoustic waves. The monocrystal material and the cut angle of each of the piezoelectric layers 6A, 6B may be determined according to, for example, predetermined specifications (filter characteristics, for example, bandpass characteristics, attenuation characteristics, temperature characteristics, and band width), and the like of the filter.

The thickness of the piezoelectric layer 6A is preferably, for example, less than or equal to about 3.5λ where the wave length of acoustic waves, which is determined by the electrode finger pitch of the interdigital transducer electrode 7A, is λ. The thickness of the piezoelectric layer 6B is preferably, for example less than or substantially equal to about 3.5λ where the wave length of acoustic waves, which is determined by the electrode finger pitch of the interdigital transducer electrode 7B, is λ.

### (1.3.2) Interdigital Transducer Electrode

Each of the interdigital transducer electrodes 7A, 7B may be made of an appropriate material, for example, Al, Cu, Pt, Au, Ag, Ti, Ni, Cr, Mo, W, and an alloy including any one of these metals as a main element. Alternatively, each of the interdigital transducer electrodes 7A, 7B may have a structure including a plurality of metal films made of any one of these metals and alloys is laminated. For example, each of the interdigital transducer electrodes 7A, 7B is preferably an Al film. However, the interdigital transducer electrodes 7A, 7B are not limited to this. For example, each of the interdigital transducer electrodes 7A, 7B may be a laminated film including an adhesion film made of a Ti film provided on the piezoelectric layer 6A or the piezoelectric layer 6B and a main electrode film made of an Al film and provided on the adhesion film. The thickness of the adhesion film is preferably, for example, about 10 nm. The thickness of the main electrode film is preferably, for example, about 130 nm each.

### (1.3.2.1) Interdigital Transducer Electrode of First Acoustic Wave Resonator

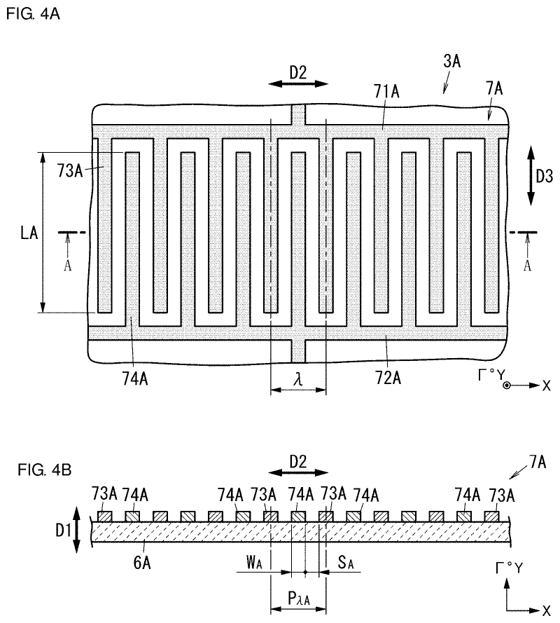

As shown in FIGS. 4A and 4B, the interdigital transducer electrode 7A includes a first busbar 71A, a second busbar 72A, a plurality of first electrode fingers 73A, and a plurality of second electrode fingers 74A. In FIG. 4B, the high acoustic velocity member 4A and the low acoustic velocity film 5A shown in FIG. 3A are not shown.

The first busbar 71A and the second busbar 72A each have a long shape of which the longitudinal direction is a second direction D2 (X-axis direction) orthogonal or substantially orthogonal to a first direction D1 (Γ° Y direction) along the thickness direction of the high acoustic velocity member 4A. In the interdigital transducer electrode 7A, the first busbar 71A and the second busbar 72A are opposed to each other in a third direction D3 orthogonal or substantially orthogonal to both the first direction D1 and the second direction D2.

The plurality of first electrode fingers 73A are connected to the first busbar 71A and extend toward the second busbar 72A. Here, the plurality of first electrode fingers 73A extend from the first busbar 71A along the third direction D3. The distal ends of the plurality of first electrode fingers 73A are spaced apart from the second busbar 72A. For example, the plurality of first electrode fingers 73A have the same or substantially the same length and width.

The plurality of second electrode fingers 74A are connected to the second busbar 72A and extend toward the first busbar 71A. Here, the plurality of second electrode fingers 74A extend from the second busbar 72A along the third direction D3. The distal ends of the plurality of second electrode fingers 74A are spaced apart from the first busbar 71A. For example, the plurality of second electrode fingers 74A have the same or substantially the same length and width. In the example of FIG. 4A, the length and width of each of the plurality of second electrode fingers 74A are respectively the same or substantially the same as the length and width of the plurality of first electrode fingers 73A.

In the interdigital transducer electrode 7A, the plurality of first electrode fingers 73A and the plurality of second electrode fingers 74A are provided alternately one by one and spaced apart from each other in the second direction D2. Therefore, the first electrode finger 73A and the second electrode finger 74A adjacent to each other in the longitudinal direction of the first busbar 71A are spaced apart from each other. Where the width of each of the first electrode fingers 73A and the second electrode fingers 74A is W_{A} (see FIG. 4B) and a space width between any adjacent first electrode finger 73A and second electrode finger 74A is S_{A}, a duty ratio is defined by W_{A}/(W_{A}+S_{A}) in the interdigital transducer electrode 7A. The duty ratio of the interdigital transducer electrode 7A is preferably, for example, about 0.5. Where the wave length of acoustic waves, which is determined by the electrode finger pitch of the interdigital transducer electrode 7A, is λ, λ is equal to the electrode finger pitch. The electrode finger pitch is defined by a cycle period P_{λA}(see FIG. 4B) of the plurality of first electrode fingers 73A or the plurality of second electrode fingers 74A. Therefore, the cycle period P_{λA} and λ are equal to each other. The duty ratio of the interdigital transducer electrode 7A is the ratio of the width W_{A} of the first electrode finger 73A or the second electrode finger 74A to a value (W_{A}+S_{A}) half the electrode finger pitch.

The plurality of first electrode fingers 73A and the plurality of second electrode fingers 74A are spaced apart from each other in the second direction D2. In addition, and the plurality of first electrode fingers 73A and the plurality of second electrode fingers 74A may not be provided alternately and spaced apart from each other. For example, a region in which the first electrode finger 73A and the second electrode finger 74A are provided one by one and spaced apart from each other and a region in which the two first electrode fingers 73A or the two second electrode fingers 74A are provided in the second direction D2 may be mixed. The number of the plurality of first electrode fingers 73A and the number of the plurality of second electrode fingers 74A in the interdigital transducer electrode 7A are not limited.

### (1.3.2.2) Interdigital Transducer Electrode of Second Acoustic Wave Resonator

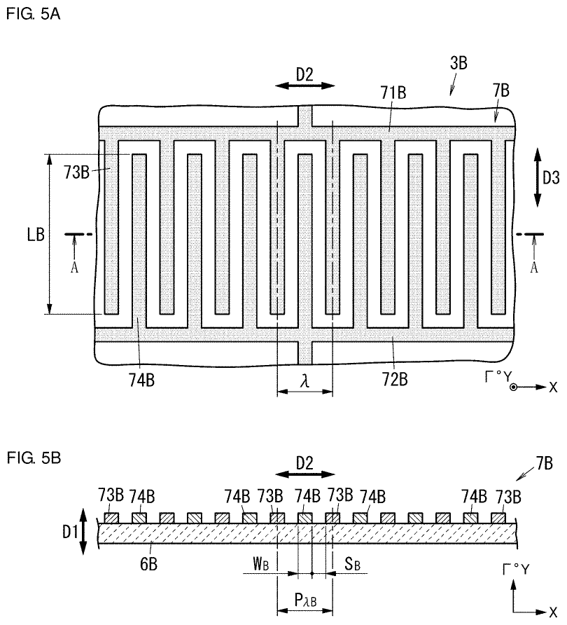

As shown in FIGS. 5A and 5B, the interdigital transducer electrode 7B includes a first busbar 71B, a second busbar 72B, a plurality of first electrode fingers 73B, and a plurality of second electrode fingers 74B. In FIG. 5B, the high acoustic velocity member 4B and the low acoustic velocity film 5B shown in FIG. 3B are not shown.

The first busbar 71B and the second busbar 72B each have a long shape of which the longitudinal direction is a second direction D2 (X-axis direction) orthogonal or substantially orthogonal to a first direction D1 (Γ° Y direction) along the thickness direction of the high acoustic velocity member 4B. In the interdigital transducer electrode 7B, the first busbar 71B and the second busbar 72B are opposed to each other in a third direction D3 orthogonal or substantially orthogonal to both the first direction D1 and the second direction D2.

The plurality of first electrode fingers 73B are connected to the first busbar 71B and extend toward the second busbar 72B. Here, the plurality of first electrode fingers 73B extend from the first busbar 71B along the third direction D3. The distal ends of the plurality of first electrode fingers 73B are spaced apart from the second busbar 72B. For example, the plurality of first electrode fingers 73B have the same or substantially the same length and width.

The plurality of second electrode fingers 74B are connected to the second busbar 72B and extend toward the first busbar 71B. Here, the plurality of second electrode fingers 74B extend from the second busbar 72B along the third direction D3. The distal ends of the plurality of second electrode fingers 74B are spaced apart from the first busbar 71B. For example, the plurality of second electrode fingers 74B have the same or substantially the same length and width. In the example of FIG. 5A, the length and width of each of the plurality of second electrode fingers 74B are respectively the same or substantially the same as the length and width of the plurality of first electrode fingers 73B.

In the interdigital transducer electrode 7B, the plurality of first electrode fingers 73B and the plurality of second electrode fingers 74B are provided alternately one by one and spaced apart from each other in the second direction D2. Therefore, the first electrode finger 73B and the second electrode finger 74B adjacent to each other in the longitudinal direction of the first busbar 71B are spaced apart from each other. Where the width of each of the first electrode fingers 73B and the second electrode fingers 74B is W_{B} (see FIG. 5B) and a space width between any adjacent first electrode finger 73B and second electrode finger 74B is S_{B}, a duty ratio is defined by W_{B}/(W_{B}+S_{B}) in the interdigital transducer electrode 7B. The duty ratio of the interdigital transducer electrode 7B is preferably, for example, about 0.5. Where the wave length of acoustic waves, which is determined by the electrode finger pitch of the interdigital transducer electrode 7B, is λ, λ is equal to the electrode finger pitch. The electrode finger pitch is defined by a cycle period P_{λB}(see FIG. 5B) of the plurality of first electrode fingers 73B or the plurality of second electrode fingers 74B. Therefore, the cycle period P_{λB} and λ are equal or substantially equal to each other. The duty ratio of the interdigital transducer electrode 7B is the ratio of the width W_{A} of the first electrode finger 73B or the second electrode finger 74B to a value (W_{B}+S_{B}) half the electrode finger pitch.

The plurality of first electrode fingers 73B and the plurality of second electrode fingers 74B are spaced apart from each other in the second direction D2. In addition, the plurality of first electrode fingers 73B and the plurality of second electrode fingers 74B may not be provided alternately and spaced apart from each other. For example, a region in which the first electrode finger 73B and the second electrode finger 74B are provided one by one and spaced apart from each other and a region in which the two first electrode fingers 73B or the two second electrode fingers 74B are provided in the second direction D2 may be mixed. The number of the plurality of first electrode fingers 73B and the number of the plurality of second electrode fingers 74B in the interdigital transducer electrode 7B are not limited.

### (1.3.3) Low Acoustic Velocity Film of Each of First Acoustic Wave Resonator and Second Acoustic Wave Resonator

As shown in FIGS. 3A and 3B, the first acoustic wave resonator 3A includes the low acoustic velocity film 5A provided between the high acoustic velocity member 4A that is the high acoustic velocity support substrate 42A and the piezoelectric layer 6A, and the second acoustic wave resonator 3B includes the low acoustic velocity film 5B provided between the high acoustic velocity member 4B that is the high acoustic velocity support substrate 42B and the piezoelectric layer 6B, so the acoustic velocity of acoustic waves decreases. The energy of acoustic waves concentrates in a low acoustic velocity medium. Therefore, with the first acoustic wave resonator 3A, the effect of enclosing acoustic wave energy into the piezoelectric layer 6A and the interdigital transducer electrode 7A in which acoustic waves are excited is significantly improved, and with the second acoustic wave resonator 3B, the effect of enclosing acoustic wave energy into the piezoelectric layer 6B and the interdigital transducer electrode 7B in which acoustic waves are excited is significantly improved. Therefore, with each of the first acoustic wave resonator 3A and the second acoustic wave resonator 3B, a loss is reduced, and the quality factor is increased, in comparison with the case where no low acoustic velocity film 5A or no low acoustic velocity film 5B is provided. The first acoustic wave resonator 3A may, for example, include an adhesion layer provided between the low acoustic velocity film 5A and the piezoelectric layer 6A. The second acoustic wave resonator 3B may, for example, include an adhesion layer provided between the low acoustic velocity film 5B and the piezoelectric layer 6B. Thus, the first acoustic wave resonator 3A significantly reduces or prevents occurrence of peel between the low acoustic velocity film 5A and the piezoelectric layer 6A, and the second acoustic wave resonator 3B significantly reduces or prevents occurrence of peel between the low acoustic velocity film 5B and the piezoelectric layer 6B. The adhesion layer includes, for example, a resin (epoxy resin, polyimide resin, or the like), a metal, or the like. Not limited to the adhesion layer, the first acoustic wave resonator 3A may include a dielectric film between the low acoustic velocity film 5A and the piezoelectric layer 6A on or above the piezoelectric layer 6A or on or below the low acoustic velocity film 5A. Not limited to the adhesion layer, the second acoustic wave resonator 3B may include a dielectric film between the low acoustic velocity film 5B and the piezoelectric layer 6B on or above the piezoelectric layer 6B or on or below the low acoustic velocity film 5B.

The material of each of the low acoustic velocity films 5A, 5B is preferably at least one material selected from a group consisting of, for example, silicon oxide, glass, silicon oxynitride, tantalum oxide, and a chemical compound provided by adding fluorine, carbon, or boron to silicon oxide.

With the first acoustic wave resonator 3A, for example, when the low acoustic velocity film 5A is silicon oxide, the frequency-temperature characteristics are significantly improved as compared to when no low acoustic velocity film 5A is included. With the second acoustic wave resonator 3B, for example, when the low acoustic velocity film 5B is silicon oxide, the frequency-temperature characteristics are significantly improved as compared to when no low acoustic velocity film 5B is included. The elastic constant of LiTaO₃ has negative temperature characteristics, and the elastic constant of silicon oxide has positive temperature characteristics. Therefore, with the first acoustic wave resonator 3A and the second acoustic wave resonator 3B, the absolute value of TCF (temperature coefficient of frequency) is reduced. In addition, the specific acoustic impedance of silicon oxide is less than the specific acoustic impedance of LiTaO₃. Therefore, with the first acoustic wave resonator 3A and the second acoustic wave resonator 3B, both an expansion of fractional band width resulting from an increase in electromechanical coupling coefficient and significant improvement in frequency-temperature characteristics are able to be provided.

The thickness of the low acoustic velocity film 5A is preferably, for example, less than or substantially equal to about 2.0λ where the wave length of acoustic waves, which is determined by the electrode finger pitch of the interdigital transducer electrode 7A, is λ. The thickness of the low acoustic velocity film 5B is preferably, for example, less than or substantially equal to about 2.0λ where the wave length of acoustic waves, which is determined by the electrode finger pitch of the interdigital transducer electrode 7B, is λ.

### (1.3.4) High Acoustic Velocity Member

The high acoustic velocity member 4A is the high acoustic velocity support substrate 42A supporting the piezoelectric layer 6A, the interdigital transducer electrode 7A, and the like. The high acoustic velocity member 4B is the high acoustic velocity support substrate 42B supporting the piezoelectric layer 6A, the interdigital transducer electrode 7B, and the like. Bulk waves propagate through the high acoustic velocity support substrate 42A at an acoustic velocity higher than acoustic waves propagate through the piezoelectric layer 6A. Bulk waves propagate through the high acoustic velocity support substrate 42B at an acoustic velocity higher than acoustic waves propagate through the piezoelectric layer 6B.

### (1.3.4.1) High Acoustic Velocity Member of First Acoustic Wave Resonator

The plan-view shape of the high acoustic velocity member 4A (the outer peripheral shape of the high acoustic velocity member 4A when viewed in the first direction D1) is a rectangular or substantially rectangular shape. However, the shape is not limited to a rectangular or substantially rectangular shape and may be, for example, a square or substantially square shape. The high acoustic velocity member 4A is a crystal substrate. Specifically, the high acoustic velocity member 4A is a crystal substrate having a cubic crystal structure. As an example, the high acoustic velocity member 4A is preferably a silicon substrate. The thickness of the high acoustic velocity member 4A is preferably, for example, about 120 μm.

In the first acoustic wave resonator 3A, a surface 41A closer to the piezoelectric layer 6A in the silicon substrate included in the high acoustic velocity member 4A is a (111) plane. The (111) plane is orthogonal or substantially orthogonal to [111] crystal axis in the crystal structure of silicon having a diamond structure. The phrase “the surface 41A closer to the piezoelectric layer 6A in the silicon substrate is a (111) plane” means that the surface 41A is not limited to a (111) plane and includes a crystal plane of which the off angle from the (111) plane is greater than zero degrees and less than or substantially equal to about five degrees. The phrase “the surface 41A closer to the piezoelectric layer 6A in the silicon substrate is a (111) plane” means that the surface 41A includes a crystal plane equivalent to a (111) plane and the surface 41A is a {111} plane. In the first acoustic wave resonator 3A, the surface 41A closer to the piezoelectric layer 6A in the silicon substrate is not limited to a (111) plane and may be a (110) plane. The (110) plane is orthogonal or substantially orthogonal to [110] crystal axis in the crystal structure of silicon having a diamond structure. The phrase “the surface 41A closer to the piezoelectric layer 6A in the silicon substrate is a (110) plane” means that the surface 41A is not limited to a (110) plane and the surface 41A includes a crystal plane of which the off angle from the (110) plane greater than zero degrees and less than or substantially equal to about five degrees. The phrase “the surface 41A closer to the piezoelectric layer 6A in the silicon substrate is a (110) plane” means that the surface 41A includes a crystal plane equivalent to a (110) plane and the surface 41A is a {110} plane. The plane direction of the surface 41A is analyzed by, for example, X-ray diffractometry. The crystal substrate having a crystal structure may be, for example, a germanium substrate, a diamond substrate, or the like other than the silicon substrate. Therefore, the material of the high acoustic velocity member 4A is not limited to silicon and may be, for example, germanium, diamond, or the like.

### (1.3.4.2) High Acoustic Velocity Member of Second Acoustic Wave Resonator

The plan-view shape of the high acoustic velocity member 4B (the outer peripheral shape of the high acoustic velocity member 4B when viewed in the first direction D1) is a rectangular or substantially rectangular shape. However, the shape is not limited to a rectangular or substantially rectangular shape and may be, for example, a square or substantially square shape. The high acoustic velocity member 4B is a crystal substrate. Specifically, the high acoustic velocity member 4B is a crystal substrate having a cubic crystal structure. As an example, the high acoustic velocity member 4B is preferably a silicon substrate. The thickness of the high acoustic velocity member 4B is preferably, for example, about 120 μm.

In the second acoustic wave resonator 3B, a surface 41B closer to the piezoelectric layer 6B in the silicon substrate included in the high acoustic velocity member 4B is a (100) plane. The (100) plane is orthogonal or substantially orthogonal to [100]crystal axis in the crystal structure of silicon having a diamond structure. The phrase “the surface 41B closer to the piezoelectric layer 6B in the silicon substrate is a (100) plane” means that the surface 41B is not limited to a (100) plane and includes a crystal plane of which the off angle from the (100) plane is greater than zero degrees and less than or substantially equal to about five degrees. In the silicon substrate, the (100), a (001) plane, and a (010) plane are crystal planes equivalent to one another, so the phrase “the surface 41B closer to the piezoelectric layer 6B in the silicon substrate is a (100) plane” means that the surface 41B is a {100} plane. The plane direction of the surface 41A is analyzed by, for example, X-ray diffractometry. The crystal substrate having a crystal structure may be, for example, a germanium substrate, a diamond substrate, or the like other than the silicon substrate. Therefore, the material of the high acoustic velocity member 4B is not limited to silicon and may be, for example, germanium, diamond, or the like.

### (1.4) Characteristics of First Acoustic Wave Resonator, Second Acoustic Wave Resonator, and Acoustic Wave Device

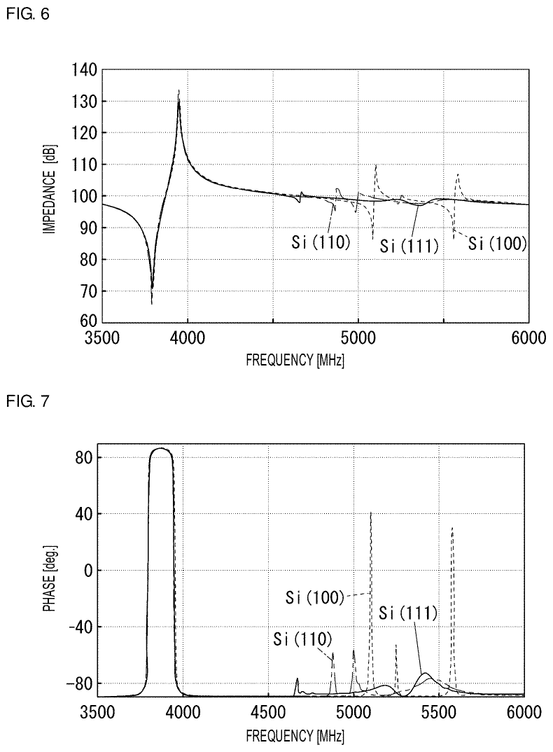

FIG. 6 shows an example of the impedance-frequency characteristics of each of the first acoustic wave resonator 3A and the second acoustic wave resonator 3B. FIG. 7 shows the phase-frequency characteristics of each of the first acoustic wave resonator 3A and the second acoustic wave resonator 3B. In FIG. 6 and FIG. 7, the line indicated by “Si(111)” represents characteristics when the surface 41A of the silicon substrate included in the high acoustic velocity member 4A is a (111) plane in the first acoustic wave resonator 3A. The line indicated by “Si(110)” represents characteristics when the surface 41A of the silicon substrate included in the high acoustic velocity member 4A is a (110) plane in the first acoustic wave resonator 3A. The line indicated by “Si(100)” represents characteristics when the surface 41B of the silicon substrate included in the high acoustic velocity member 4B is a (100) plane in the second acoustic wave resonator 3B.

For the first acoustic wave resonator 3A, the surface 41A of the silicon substrate included in the high acoustic velocity member 4A including the silicon substrate is a (111) plane or a (110) plane. The thicknesses of the low acoustic velocity film 5A, the piezoelectric layer 6A, and the interdigital transducer electrode 7A are normalized by λ that is the wave length of acoustic waves, which is determined by the electrode finger pitch of the interdigital transducer electrode 7A. In the first acoustic wave resonator 3A, λ is about 1 μm, for example. In the first acoustic wave resonator 3A, the thickness of the low acoustic velocity film 5A made of silicon oxide is preferably about 0.34λ, the thickness of the piezoelectric layer 6A made of 50° Y-cut X-propagation LiTaO₃ piezoelectric monocrystal is preferably about 0.3λ, and the thickness of the interdigital transducer electrode 7A made of aluminum is preferably about 0.08λ. These numeric values are examples.

For the second acoustic wave resonator 3B, the surface 41B of the silicon substrate included in the high acoustic velocity member 4B made of the silicon substrate is a (100) plane. The thicknesses of the low acoustic velocity film 5B, the piezoelectric layer 6B, and the interdigital transducer electrode 7B are normalized by λ that is the wave length of acoustic waves, which is determined by the electrode finger pitch of the interdigital transducer electrode 7B. In the second acoustic wave resonator 3B, λ is about 1 μm, for example. The thickness of the low acoustic velocity film 5B including silicon oxide is preferably about 0.34λ, the thickness of the piezoelectric layer 6B including 50° Y-cut X-propagation LiTaO₃ piezoelectric monocrystal is preferably about 0.3λ, and the thickness of the interdigital transducer electrode 7B including aluminum is preferably about 0.08λ. These numeric values are examples.

It is found from FIG. 6 and FIG. 7 that, in each of the first acoustic wave resonator 3A and the second acoustic wave resonator 3B, higher modes are occurring at frequencies higher than the resonant frequency. It is also found from FIG. 6 and FIG. 7 that, for the magnitude of response of higher modes in the range from about 4500 MHz to about 6000 MHz, there is a magnitude relationship that [Second acoustic wave resonator 3B in which the surface 41B of the silicon substrate included in the high acoustic velocity member 4B is a (100) plane]>[First acoustic wave resonator 3A in which the surface 41A of the silicon substrate included in the high acoustic velocity member 4A is a (110) plane]>[First acoustic wave resonator 3A in which the surface 41A of the silicon substrate included in the high acoustic velocity member 4A is a (111) plane]. In other words, it is found from FIG. 6 and FIG. 7 that, with the first acoustic wave resonator 3A, the intensity of higher modes is reduced as compared to the second acoustic wave resonator 3B.

On the other hand, with the second acoustic wave resonator 3B, cracking, peeling, and the like of the silicon substrate are less likely to occur in a thermal shock test as compared to the first acoustic wave resonator 3A. Here, cracking and peeling occur because of, for example, the plane direction of a side of the silicon substrate, and thermal stress due to, for example, a difference in coefficient of linear expansion between the high acoustic velocity member 4A and the piezoelectric layer 6A or a difference in coefficient of linear expansion between the high acoustic velocity member 4B and the piezoelectric layer 6B. In the first acoustic wave resonator 3A, when cracking, peeling, or the like, occurs, characteristic degradation, for example, an increase in insertion loss in a filter pass band, may occur. The coefficient of linear expansion of LiTaO₃ is greater than the coefficient of linear expansion of silicon.

From the above results, the inventors of preferred embodiments of the present invention determined that, of the first acoustic wave resonator 3A and the second acoustic wave resonator 3B, the first acoustic wave resonator 3A significantly reduces or prevents higher modes in the acoustic wave device 1. On the other hand, the inventors of preferred embodiments of the present invention determined that, of the first acoustic wave resonator 3A and the second acoustic wave resonator 3B, the second acoustic wave resonator 3B significantly reduces or prevents characteristic degradation in the acoustic wave device 1.

In addition, the inventors of preferred embodiments of the present invention discovered that, when the acoustic wave device 1 was applied to, for example, the multiplexer 100, or the like, a major portion of the influence of higher modes of the acoustic wave device 1 on other filters was determined by the characteristics of the antenna end resonator electrically closest to the antenna 200 when viewed from the antenna 200 among the plurality of acoustic wave resonators 31 to 39. In the acoustic wave device 1 according to the first preferred embodiment, from the viewpoint of significantly reducing or preventing higher modes while significantly reducing or preventing characteristic degradation, each of the acoustic wave resonators 31, 32 of a first group including the antenna end resonator includes the first acoustic wave resonator 3A, and each of the acoustic wave resonators 33 to 39 of a second group other than the first group includes the second acoustic wave resonator 3B. In the acoustic wave device 1, the acoustic wave resonators 31, 32 of the first group are integrated into a single chip, and the acoustic wave resonators 33 to 39 of the second group are integrated into a single chip. In the acoustic wave device 1, of the plurality of acoustic wave resonators 31 to 39, only the acoustic wave resonator 31 that is the antenna end resonator may include the first acoustic wave resonator 3A, and each of the acoustic wave resonators 32 to 39 other than the antenna end resonator may include the second acoustic wave resonator 3B.

### (1.5) Advantageous Effects

The acoustic wave device 1 according to the first preferred embodiment is provided between the first terminal 101 defining and functioning as the antenna terminal and the second terminal 102 different from the first terminal 101. The acoustic wave device 1 includes the plurality of acoustic wave resonators 31 to 39. The plurality of acoustic wave resonators 31 to 39 include the plurality of series arm resonators (acoustic wave resonators 31, 33, 35, 37, 39) provided in the first path r1 connecting the first terminal 101 and the second terminal 102 and the plurality of parallel arm resonators (acoustic wave resonators 32, 34, 36, 38) provided in the plurality of second paths r21, r22, r23, r24 respectively connecting the plurality of nodes N1, N2, N3, N4 in the first path r1 to the ground. Where, of the plurality of acoustic wave resonators 31 to 39, the acoustic wave resonator electrically closest to the first terminal 101 is the antenna end resonator, the antenna end resonator is the first acoustic wave resonator 3A, and, of the plurality of acoustic wave resonators 31 to 39, at least one acoustic wave resonator other than the antenna end resonator is the second acoustic wave resonator 3B. The first acoustic wave resonator 3A includes the piezoelectric layer 6A, the interdigital transducer electrode 7A having the plurality of electrode fingers (the first electrode fingers 73A and the plurality of second electrode fingers 74A), and the high acoustic velocity member 4A. The second acoustic wave resonator 3B includes the piezoelectric layer 6B, the interdigital transducer electrode 7B having the plurality of electrode fingers (the first electrode fingers 73B and the plurality of second electrode fingers 74B), and the high acoustic velocity member 4B. The interdigital transducer electrode 7A of the first acoustic wave resonator 3A is provided on or above the piezoelectric layer 6A. The interdigital transducer electrode 7B of the second acoustic wave resonator 3B is provided on or above the piezoelectric layer 6B. The high acoustic velocity member 4A is located across the piezoelectric layer 6A from the interdigital transducer electrode 7A. The high acoustic velocity member 4B is located across the piezoelectric layer 6B from the interdigital transducer electrode 7B. Bulk waves propagate through the high acoustic velocity member 4A at an acoustic velocity higher than acoustic waves propagate through the piezoelectric layer 6A. Bulk waves propagate through the high acoustic velocity member 4B at an acoustic velocity higher than acoustic waves propagate through the piezoelectric layer 6B. In each of the first acoustic wave resonator 3A and the second acoustic wave resonator 3B, the thickness of the piezoelectric layer 6A or the piezoelectric layer 6B is preferably, for example, less than or equal to about 3.5λ where the wave length of acoustic waves, which is determined by the electrode finger pitch of the interdigital transducer electrode 7A or the interdigital transducer electrode 7B, is λ. The acoustic wave device 1 satisfies a first condition. The first condition is a condition that the high acoustic velocity member 4A of the first acoustic wave resonator 3A and the high acoustic velocity member 4B of the second acoustic wave resonator 3B each include a silicon substrate, the surface 41A closer to the piezoelectric layer 6A in the silicon substrate of the first acoustic wave resonator 3A is a (111) plane or a (110) plane, and the surface 41B closer to the piezoelectric layer 6B in the silicon substrate of the second acoustic wave resonator 3B is a (100) plane.

With the acoustic wave device 1 according to the first preferred embodiment, the antenna end resonator is the first acoustic wave resonator 3A, and the surface 41A closer to the piezoelectric layer 6A in the silicon substrate of the first acoustic wave resonator 3A is a (111) plane or a (110) plane, so higher modes are significantly reduced or prevented. In addition, with the acoustic wave device 1 according to the first preferred embodiment, of the plurality of acoustic wave resonators 31 to 39, at least one acoustic wave resonator 33 to 39 other than the antenna end resonator is the second acoustic wave resonator 3B, and the surface 41B closer to the piezoelectric layer 6B in the silicon substrate of the second acoustic wave resonator 3B is a (100) plane, so characteristic degradation is significantly reduced or prevented.

In the acoustic wave device 1 according to the first preferred embodiment, the first acoustic wave resonator 3A includes the low acoustic velocity film 5A, and the second acoustic wave resonator 3B includes the low acoustic velocity film 5B. The low acoustic velocity film 5A is provided between the high acoustic velocity member 4A and the piezoelectric layer 6A. The low acoustic velocity film 5B is provided between the high acoustic velocity member 4B and the piezoelectric layer 6B. Bulk waves propagate through the low acoustic velocity film 5A at an acoustic velocity lower than bulk waves propagate through the piezoelectric layer 6A. Bulk waves propagate through the low acoustic velocity film 5B at an acoustic velocity lower than bulk waves propagate through the piezoelectric layer 6B. The high acoustic velocity member 4A is the high acoustic velocity support substrate 42A through which bulk waves propagate at an acoustic velocity higher than acoustic waves propagate through the piezoelectric layer 6A. The high acoustic velocity member 4B is the high acoustic velocity support substrate 42B through which bulk waves propagate at an acoustic velocity higher than acoustic waves propagate through the piezoelectric layer 6B. Thus, with the acoustic wave device 1, from the property that the energy of acoustic waves concentrates in a low acoustic velocity medium, the effect of enclosing acoustic wave energy into the piezoelectric layer 6A and the interdigital transducer electrode 7A in which acoustic waves are excited is significantly improved in the first acoustic wave resonator 3A, and the effect of enclosing acoustic wave energy into the piezoelectric layer 6B and the interdigital transducer electrode 7B in which acoustic waves are excited is significantly improved in the second acoustic wave resonator 3B. Thus, with the acoustic wave device 1, in each of the first acoustic wave resonator 3A and the second acoustic wave resonator 3B, the quality factor is increased, and a loss is reduced, as compared to when no low acoustic velocity film 5A or no low acoustic velocity film 5B is included.

In the acoustic wave device 1 according to the first preferred embodiment, the first acoustic wave resonator 3A and the second acoustic wave resonator 3B are chips different from each other. In the example of FIG. 1, the two first acoustic wave resonators 3A surrounded by the one alternate long and short dashed line are integrated into a single chip, and the seven second acoustic wave resonators 3B surrounded by the other one alternate long and short dashed line are integrated into another single chip.

The acoustic wave device 1 according to the first preferred embodiment is provided between the first terminal 101 defining and functioning as the antenna terminal and the second terminal 102 different from the first terminal 101. The acoustic wave device 1 includes the plurality of acoustic wave resonators 31 to 39. The plurality of acoustic wave resonators 31 to 39 include the plurality of series arm resonators (acoustic wave resonators 31, 33, 35, 37, 39) provided in the first path r1 connecting the first terminal 101 and the second terminal 102 and the plurality of parallel arm resonators (acoustic wave resonators 32, 34, 36, 38) provided in the plurality of second paths respectively connecting the plurality of nodes N1, N2, N3, N4 in the first path r1 to the ground. Where, of the plurality of acoustic wave resonators 31 to 39, the acoustic wave resonator electrically closest to the first terminal 101 is the antenna end resonator, the antenna end resonator is the first acoustic wave resonator 3A, and, of the plurality of acoustic wave resonators 31 to 39, at least one acoustic wave resonator other than the antenna end resonator is the second acoustic wave resonator 3B. The interdigital transducer electrode 7A of the first acoustic wave resonator 3A is provided on or above the piezoelectric layer 6A. The interdigital transducer electrode 7B of the second acoustic wave resonator 3B is provided on or above the piezoelectric layer 6B. The high acoustic velocity member 4A is located across the piezoelectric layer 6A from the interdigital transducer electrode 7A. The high acoustic velocity member 4B is located across the piezoelectric layer 6B from the interdigital transducer electrode 7B. Bulk waves propagate through the high acoustic velocity member 4A at an acoustic velocity higher than acoustic waves propagate through the piezoelectric layer 6A. Bulk waves propagate through the high acoustic velocity member 4B at an acoustic velocity higher than acoustic waves propagate through the piezoelectric layer 6B. In each of the first acoustic wave resonator 3A and the second acoustic wave resonator 3B, the thickness of the piezoelectric layer 6A or the piezoelectric layer 6B is less than or equal to about 3.5λ where the wave length of acoustic waves, which is determined by the electrode finger pitch of the interdigital transducer electrode 7A or the interdigital transducer electrode 7B, is λ. The intensity of higher modes of the first acoustic wave resonator 3A is less than the intensity of higher modes of the second acoustic wave resonator 3B.

With the above-described acoustic wave device 1, higher modes are significantly reduced or prevented.

### (1.6) First Modification of First Embodiment

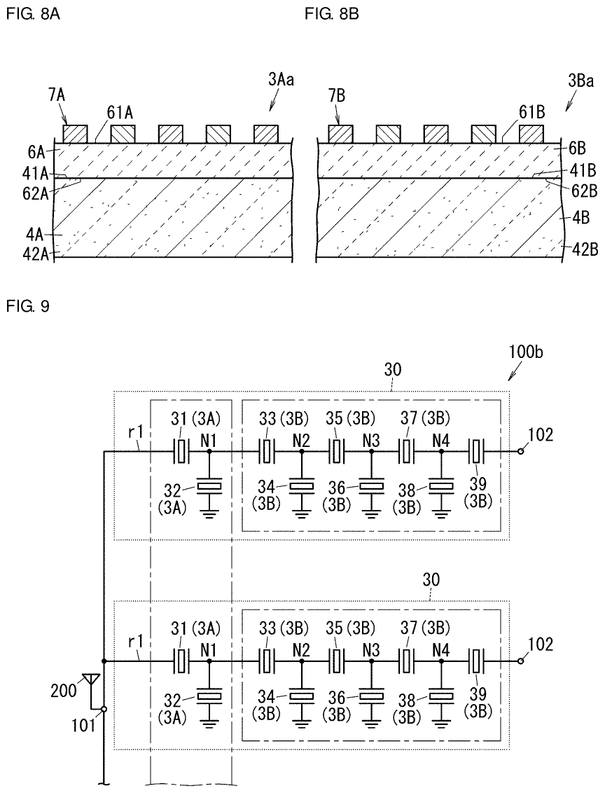

An acoustic wave device according to a first modification of the first preferred embodiment differs from the acoustic wave device 1 according to the first preferred embodiment in that first acoustic wave resonators 3Aa and second acoustic wave resonators 3Ba as shown in FIGS. 8A and 8B are provided instead of the first acoustic wave resonators 3A and the second acoustic wave resonators 3B of the acoustic wave device 1 according to the first preferred embodiment. The other features, components, and elements of the acoustic wave device according to the first modification are the same as or similar to the acoustic wave device 1 according to the first preferred embodiment, so the drawings and description thereof are omitted where appropriate. As for the acoustic wave device according to the first modification, like reference numerals denote the same or similar components to those of the acoustic wave device 1 according to the first preferred embodiment, and the description thereof is omitted.

The first acoustic wave resonator 3Aa does not include the low acoustic velocity film 5A of the first acoustic wave resonator 3A of the acoustic wave device 1 according to the first preferred embodiment, and the second acoustic wave resonator 3Ba does not include the low acoustic velocity film 5B of the second acoustic wave resonator 3B of the acoustic wave device 1 according to the first preferred embodiment. In the first acoustic wave resonator 3Aa, the piezoelectric layer 6A is provided on or above the high acoustic velocity member 4A. In the second acoustic wave resonator 3Ba, the piezoelectric layer 6B is provided on or above the high acoustic velocity member 4B. The first acoustic wave resonator 3Aa may include an adhesion layer, a dielectric film, or the like between the high acoustic velocity member 4A and the piezoelectric layer 6A. The second acoustic wave resonator 3Ba may include an adhesion layer, a dielectric film, or the like between the high acoustic velocity member 4B and the piezoelectric layer 6B.

### (1.7) Second Modification of First Embodiment

As shown in FIG. 9, a multiplexer 100b according to a second modification of the first preferred embodiment includes a plurality of resonator groups 30 each including the plurality of acoustic wave resonators 31 to 39. For the plurality of resonator groups 30, the first terminal 101 is a common terminal, and the second terminals 102 are individual terminals. In the multiplexer 100b, the antenna end resonators (acoustic wave resonators 31) of the plurality of resonator groups 30 are integrated into a single chip. Thus, with the multiplexer 100b according to the second modification, including the plurality of resonator groups 30, the size is reduced, and variations in the characteristics of the antenna end resonators are reduced or prevented. In FIG. 9, for example, the seven second acoustic wave resonators 3B in each one resonator group 30 are integrated into a single chip. In addition, the two first acoustic wave resonators 3A for each of the plurality of resonator groups 30 (for example, the four first acoustic wave resonators 3A) are integrated into a single chip. In the multiplexer 100b according to the second modification, the acoustic wave resonators 31, 32 of the plurality of resonator groups 30 are integrated into a single chip; however, at least the acoustic wave resonators 31 of the plurality of resonator groups 30 are integrated into a single chip.

In the multiplexer 100b according to the second modification of the first preferred embodiment, the plurality of resonator groups 30 respectively define filters having different pass band frequencies by, for example, varying the wave lengths of acoustic waves of the resonator groups 30.

### (1.8) Third Modification of First Embodiment

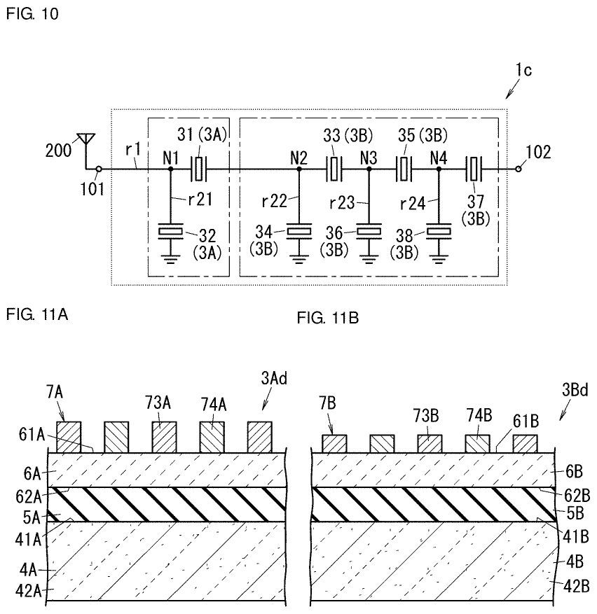

As shown in FIG. 10, an acoustic wave device 1c according to a third modification of the first preferred embodiment differs from the acoustic wave device 1 according to the first preferred embodiment in the connection relationship among the plurality of (eight) acoustic wave resonators 31 to 38. The other features, components, and elements of the acoustic wave device 1c according to the third modification are the same as or similar to the acoustic wave device 1 according to the first preferred embodiment, so the drawings and description thereof are omitted where appropriate. As for the acoustic wave device 1c according to the third modification, like reference numerals denote the same or similar components to those of the acoustic wave device 1 according to the first preferred embodiment, and the description thereof is omitted.

In the acoustic wave device 1c, in the plurality of acoustic wave resonators 31 to 38, one series arm resonator (acoustic wave resonator 31) of the plurality of (four) series arm resonators (acoustic wave resonators 31, 33, 35, 37) and one parallel arm resonator (acoustic wave resonator 32) of the plurality of (four) parallel arm resonators (acoustic wave resonators 32, 34, 36, 38) are directly connected to the first terminal 101 defining and functioning as the antenna terminal. The phrase “one series arm resonator (acoustic wave resonator 31) is directly connected to the first terminal 101” means a state of being electrically connected to the first terminal 101 without intervening the other acoustic wave resonators 32 to 38. The phrase “one parallel arm resonator (acoustic wave resonator 32) is directly connected to the first terminal 101” means a state of being electrically connected to the first terminal 101 without intervening the other acoustic wave resonators 31, 33 to 38.

In the acoustic wave device 1c, both the one series arm resonator (acoustic wave resonator 31) and the one parallel arm resonator (acoustic wave resonator 32) each include the first acoustic wave resonator 3A as the antenna end resonator. However, the one series arm resonator (acoustic wave resonator 31) and the one parallel arm resonator (acoustic wave resonator 32) are not limited to this implementation. For example, in the acoustic wave device 1c, at least one of the one series arm resonator (acoustic wave resonator 31) and the one parallel arm resonator (acoustic wave resonator 32), may include at least the first acoustic wave resonator 3A as the antenna end resonator.

### Second Preferred Embodiment

The circuitry of an acoustic wave device according to a second preferred embodiment of the present invention is the same as or similar to the circuitry of the acoustic wave device 1 according to the first preferred embodiment, so the drawings and description thereof are omitted. The acoustic wave device according to a second preferred embodiment differs from the acoustic wave device 1 according to the first preferred embodiment in that first acoustic wave resonators 3Ad and second acoustic wave resonators 3Bd as shown in FIGS. 11A and 11B are provided, instead of the first acoustic wave resonators 3A and the second acoustic wave resonators 3B of the acoustic wave device 1 according to the first preferred embodiment. As for the acoustic wave device according to the second preferred embodiment, like reference numerals denote the same or similar components to those of the acoustic wave device 1 according to the first preferred embodiment, and the description thereof is omitted.

In the acoustic wave device according to the second preferred embodiment, the thickness of the interdigital transducer electrode 7A of the first acoustic wave resonator 3Ad is different from the thickness of the interdigital transducer electrode 7B of the second acoustic wave resonator 3Bd. The first acoustic wave resonator 3Ad and the second acoustic wave resonator 3Bd are respectively similar to those of the first acoustic wave resonator 3A and the second acoustic wave resonator 3B of the acoustic wave device 1 according to the first preferred embodiment, and the thicknesses of the interdigital transducer electrodes 7A, 7B, the thicknesses of the piezoelectric layers 6A, 6B, and the thicknesses of the low acoustic velocity films 5A, 5B are different from each other. In the acoustic wave device according to the second preferred embodiment, a mass per unit length in the electrode finger longitudinal direction (the third direction D3 in FIG. 4A) of each of the electrode fingers (the first electrode fingers 73A and the second electrode fingers 74A in FIG. 4A) of the interdigital transducer electrode 7A is greater than a mass per unit length in the electrode finger longitudinal direction (the third direction D3 in FIG. 5A) of each of the electrode fingers (the first electrode fingers 73B and the second electrode fingers 74B in FIG. 5A) of the interdigital transducer electrode 7B. The unit length in the electrode finger longitudinal direction of each of the electrode fingers is, for example, in FIG. 4A, the length (overlap width LA), in the third direction D3, of each of the first electrode fingers 73A and the second electrode fingers 74A in a region in which the first electrode fingers 73A and the second electrode fingers 74A overlap (region in which acoustic waves are excited) when viewed in the second direction D2, and, in FIG. 5A, the length (overlap width LB), in the third direction D3, of each of the first electrode fingers 73B and the second electrode fingers 74B in a region in which the first electrode fingers 73B and the second electrode fingers 74B overlap (region in which acoustic waves are excited) when viewed in the second direction D2.

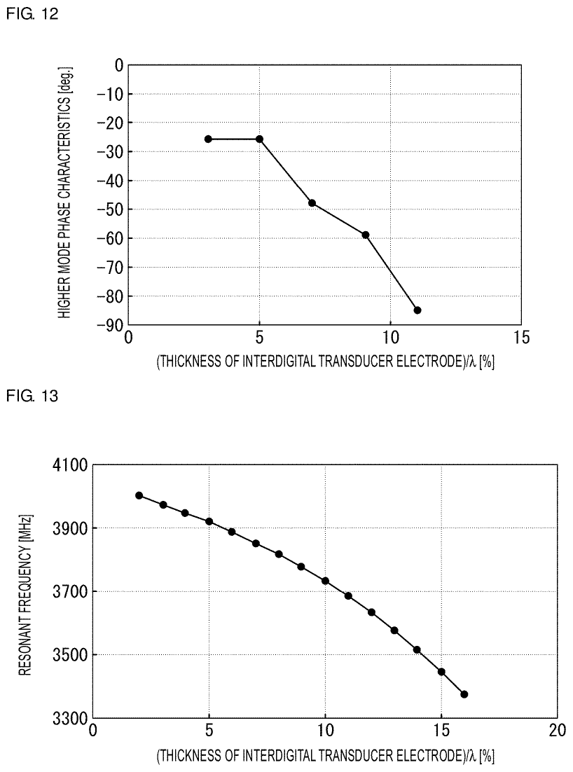

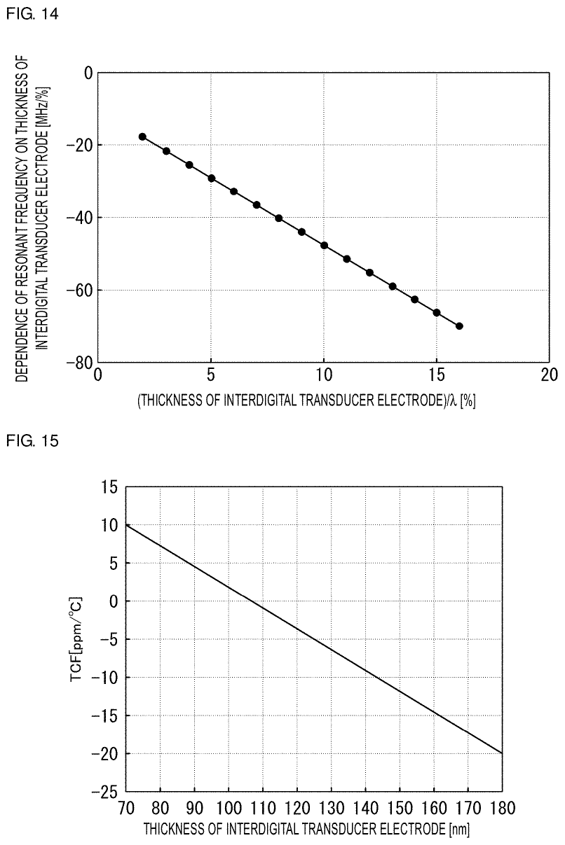

For the first acoustic wave resonator 3Ad, the surface 41A of the high acoustic velocity member 4A made of the silicon substrate is a (111) plane. The thicknesses of the low acoustic velocity film 5A, the piezoelectric layer 6A, and the interdigital transducer electrode 7A are normalized by λ that is the wave length of acoustic waves, which is determined by the electrode finger pitch of the interdigital transducer electrode 7A. In the first acoustic wave resonator 3Ad, λ is about 1 μm. FIG. 12 shows the relationship between the thickness of an interdigital transducer electrode and the phase characteristic of higher modes when, in an acoustic wave resonator of a first reference example having similar features, components, and elements as the first acoustic wave resonator 3Ad, the thickness of a low acoustic velocity film made of silicon oxide is about 0.225λ, the thickness of a piezoelectric layer made of 50° Y-cut X-propagation LiTaO₃ piezoelectric monocrystal is about 0.225λ, and the thickness of the interdigital transducer electrode made of aluminum is changed among about 3% (about 0.03λ), about 5% (about 0.05λ), about 7% (about 0.07λ), about 9% (about 0.09λ), and about 11% (about 0.11) as a percentage to λ. In addition, FIG. 13 shows a change in resonant frequency when the thickness of the interdigital transducer electrode in the acoustic wave resonator of the first reference example is changed. FIG. 14 shows the relationship between the thickness of the interdigital transducer electrode in the acoustic wave resonator of the first reference example and the dependence of the resonant frequency of the acoustic wave resonator of the first reference example on the thickness of the interdigital transducer electrode. In FIG. 14, the ordinate axis “DEPENDENCE OF RESONANT FREQUENCY ON THICKNESS OF INTERDIGITAL TRANSDUCER ELECTRODE” is a value determined by approximating a change in resonant frequency in the result of FIG. 13 as a function of the thickness of the interdigital transducer electrode with respect to a curve of the second order and then finding a differential coefficient of the curve of the second order. In the acoustic wave resonator of the first reference example, in the frequency characteristics of the phase of impedance (not shown), a mode in the range from about 3700 MHz to about 4200 MHz is a main mode, and modes that occur in the range from about 5500 MHz to about 6000 MHz are higher modes at issue.

It is found from FIG. 12 that, in the acoustic wave resonator of the first reference example, the response of higher modes tends to be significantly reduced or prevented as the thickness of the interdigital transducer electrode is increased. This tendency also applies to the case where the surface, closer to the piezoelectric layer, of the silicon substrate included in the high acoustic velocity member is a (110) plane or a (100) plane. From the viewpoint of significantly reducing or preventing higher modes of the acoustic wave resonator of the first reference example, the thickness of the interdigital transducer electrode is preferably increased. In other words, from the viewpoint of significantly reducing or preventing higher modes of the first acoustic wave resonator 3Ad, a mass per unit length in the electrode finger longitudinal direction of each of the electrode fingers (the first electrode fingers 73A and the second electrode fingers 74A) of the interdigital transducer electrode 7A is preferably increased.

In addition, it is found from FIG. 13 that, in the acoustic wave resonator of the first reference example, the resonant frequency tends to decrease as the thickness of the interdigital transducer electrode is increased. In addition, it is found from FIG. 14 that, in the acoustic wave resonator of the first reference example, the dependence of the resonant frequency on the thickness of the interdigital transducer electrode tends to increase as the thickness of the interdigital transducer electrode is increased. Therefore, from the viewpoint of reducing variations in resonant frequency due to variations of interdigital transducer electrodes within a wafer surface during manufacturing, the thickness of the interdigital transducer electrode in the acoustic wave resonator of the first reference example is preferably decreased.

With the acoustic wave device according to the second preferred embodiment, as well as the acoustic wave device 1 according to the first preferred embodiment, the antenna end resonator is the first acoustic wave resonator 3Ad, and the surface 41A closer to the piezoelectric layer 6A in the silicon substrate included in the high acoustic velocity member 4A of the first acoustic wave resonator 3Ad is a (111) plane or a (110) plane, so higher modes are significantly reduced or prevented. In addition, with the acoustic wave device according to the second preferred embodiment, of the plurality of acoustic wave resonators 31 to 39, at least one acoustic wave resonator 33 to 39 other than the antenna end resonator is the second acoustic wave resonator 3Bd, and the surface closer to the piezoelectric layer 6B in the silicon substrate included in the high acoustic velocity member 4B of the second acoustic wave resonator 3Bd is a (100) plane, so characteristic degradation is significantly reduced or prevented.

In addition, with the acoustic wave device according to the second preferred embodiment, a mass per unit length in the electrode finger longitudinal direction of each of the electrode fingers (the first electrode fingers 73A and the second electrode fingers 74A) of the interdigital transducer electrode 7A of the first acoustic wave resonator 3Ad is preferably greater than a mass per unit length in the electrode finger longitudinal direction of each of the electrode fingers (the first electrode fingers 73B and the second electrode fingers 74B) of the interdigital transducer electrode 7B of the second acoustic wave resonator 3Bd. Thus, with the acoustic wave device according to the second preferred embodiment, higher modes are further significantly reduced or prevented while variations in resonant frequency are reduced or prevented.

FIG. 15 is a graph showing the relationship between the thickness of the interdigital transducer electrode and a TCF in an acoustic wave resonator of a second reference example having similar features, components, and elements as the first acoustic wave resonator 3Ad. The resonant frequency of the acoustic wave resonator of the second reference example is different from the resonant frequency of the acoustic wave resonator of the first reference example. In the acoustic wave resonator of the second reference example, λ is about 2 μm, the thickness of the low acoustic velocity film made of silicon oxide is about 0.35λ, the thickness of the piezoelectric layer made of 50° Y-cut X-propagation LiTaO₃ piezoelectric monocrystal is about 0.3λ, and the thickness of the interdigital transducer electrode is changed in the range from about 70 nm to about 180 nm.

It is found from FIG. 15 that in the acoustic wave resonator of the second reference example, the thickness of the interdigital transducer electrode is set within the range from about 70 nm to about 140 nm to, for example, bring the absolute value of TCF to less than or equal to about 10 ppm and the thickness of the interdigital transducer electrode is set within the range from about 90 nm to about 125 nm to bring the absolute value of TCF to less than or equal to about 5 ppm. This tendency also applies to the case where the surface, closer to the piezoelectric layer, of the silicon substrate included in the high acoustic velocity member is a (110) plane or a (100) plane. In addition, with the acoustic wave resonator of the second reference example, when the thickness of the interdigital transducer electrode is reduced, the resistance value of the interdigital transducer electrode increases and a loss increases. Accordingly, the thickness of the interdigital transducer electrode is preferably increased from the viewpoint of reducing a loss. Therefore, in the acoustic wave device according to the second preferred embodiment, from the viewpoint of the temperature stability of higher modes and significantly reducing or preventing an increase in the loss of a filter, a mass per unit length in the electrode finger longitudinal direction of each of the electrode fingers (the first electrode fingers 73A and the second electrode fingers 74A) of the interdigital transducer electrode 7A of the first acoustic wave resonator 3Ad is preferably less than a mass per unit length in the electrode finger longitudinal direction of each of the electrode fingers (the first electrode fingers 73B and the second electrode fingers 74B) of the interdigital transducer electrode 7B of the second acoustic wave resonator 3Bd.

In addition, with the acoustic wave resonator of the second reference example, as a mass per unit length in the electrode finger longitudinal direction of the interdigital transducer electrode increases, the quality factor tends to increase. This tendency also applies to the case where the surface, closer to the piezoelectric layer, of the silicon substrate included in the high acoustic velocity member is a (110) plane or a (100) plane. Therefore, in the acoustic wave resonator of the second reference example, from the viewpoint of increasing the quality factor, a mass per unit length in the electrode finger longitudinal direction is preferably increased. Therefore, with the acoustic wave device according to the second preferred embodiment, higher modes are significantly reduced or prevented while the quality factor is significantly improved.

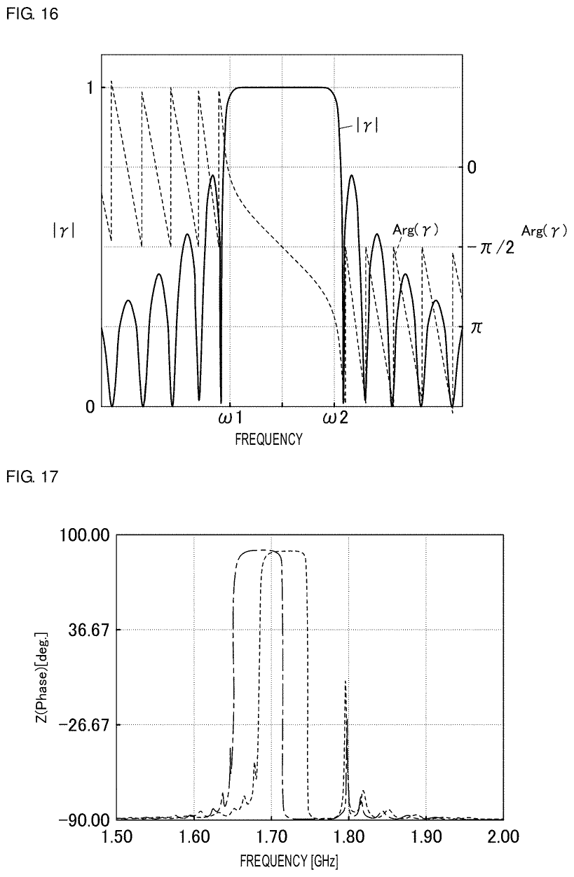

The acoustic wave resonator of the second reference example, as well as the first acoustic wave resonator 3Ad and the second acoustic wave resonator 3Bd, includes the high acoustic velocity member and the low acoustic velocity film, so the effect of enclosing acoustic wave energy into the piezoelectric layer and the interdigital transducer electrode in which acoustic waves are excited is significantly improved. Accordingly, with the acoustic wave resonator of the second reference example, in the phase characteristics of impedance, a stop band ripple occurs at frequencies higher than an anti-resonant frequency. Here, the stop band ripple is a ripple that occurs at frequencies higher than the anti-resonant frequency under the influence of stop band end in the phase characteristics of impedance of the acoustic wave resonator. More specifically, the stop band ripple is a ripple that occurs under the influence of sidelobe characteristics of the reflection characteristics (see FIG. 16) of the interdigital transducer electrode at frequencies higher than the upper end frequency (stop band end) of a stop band (rejection band) for acoustic waves. In FIG. 16, the abscissa axis represents frequency, the left-side ordinate axis represents the absolute value of reflectance γ, and the right-side ordinate axis represents the argument of reflectance γ. In the abscissa axis of FIG. 16, ω2 is the upper end frequency of the stop band, and ω1 is the lower end frequency of the stop band. The argument of the reflectance γ is the same in meaning as ∠Γ described in, for example, Document “Introduction to surface acoustic wave device simulation technology”, Kenya HASHIMOTO, published by Realize Inc., p. 215. A stop band is a frequency range in which Bragg reflection occurs for acoustic waves. The Bragg frequency of Bragg reflection, which is the center frequency of a reflection range, is determined by an electrode finger pitch and the acoustic velocity of acoustic waves. The width of a reflection band is determined by the material, the thickness, the width of each electrode finger, and the like of an interdigital transducer electrode.

FIG. 17 is a graph showing the phase characteristics of impedance of the acoustic wave resonator of the second reference example. In FIG. 17, the alternate long and short dashed line and the dashed line are different in mass per unit length in the electrode finger longitudinal direction of each of electrode fingers of the interdigital transducer electrode. In FIG. 17, the alternate long and short dashed line represents the phase characteristics of impedance when the mass of the interdigital transducer electrode is relatively large, and the dashed line represents the phase characteristics of impedance when the mass of the interdigital transducer electrode is relatively small. In FIG. 17, a ripple that is at frequencies higher than a pass band including about 1.70 GHz is a stop band ripple. It is found from FIG. 17 that, in the acoustic wave resonator of the second reference example, as the mass per unit length in the electrode finger longitudinal direction of each of the electrode fingers of the interdigital transducer electrode increases, the intensity of a stop band ripple at frequencies higher than the maximum frequency of the pass band decreases. In the example of FIG. 17, the pass band includes about 1.70 GHz, and the stop band ripple is occurring at about 1.79 GHz. This tendency also applies to the case where the surface, closer to the piezoelectric layer, of the silicon substrate included in the high acoustic velocity member is a (110) plane or a (100) plane. In the acoustic wave resonator of the second reference example, the mass per unit length in the electrode finger longitudinal direction of each of the electrode fingers of the interdigital transducer electrode is changed by changing the thickness of the interdigital transducer electrode. However, changing the mass per unit length in the electrode finger longitudinal direction of each of the electrode fingers of the interdigital transducer electrode is not limited to this implementation. The mass per unit length in the electrode finger longitudinal direction of each of the electrode fingers of the interdigital transducer electrode may be changed by changing the specific gravity of the interdigital transducer electrode.

### Third Preferred Embodiment

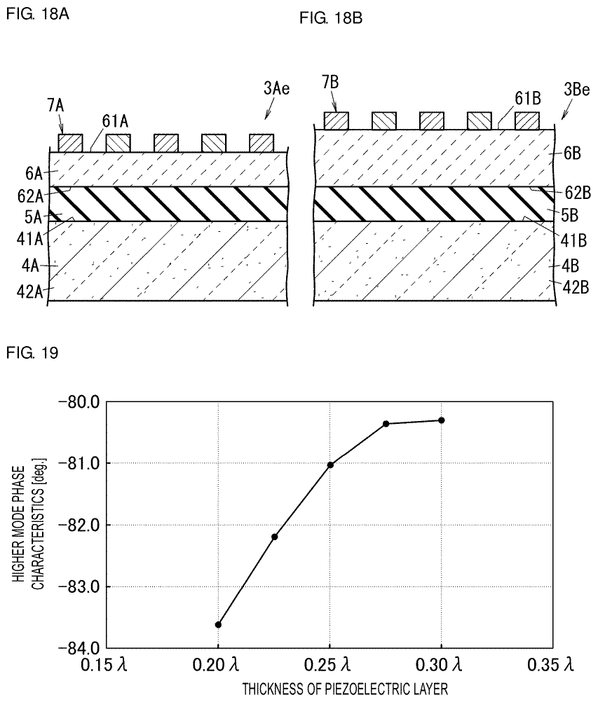

The circuitry of an acoustic wave device according to a third preferred embodiment of the present invention is the same as or similar to the circuitry of the acoustic wave device 1 according to the first preferred embodiment, so the drawings and description thereof are omitted. The acoustic wave device according to the third preferred embodiment differs from the acoustic wave device 1 according to the first preferred embodiment in that first acoustic wave resonators 3Ae and second acoustic wave resonators 3Be as shown in FIGS. 18A and 18B are provided instead of the first acoustic wave resonators 3A and the second acoustic wave resonators 3B of the acoustic wave device 1 according to the first preferred embodiment. As for the acoustic wave device according to the third preferred embodiment, like reference numerals denote the same or similar components to those of the acoustic wave device 1 according to the first preferred embodiment, and the description thereof is omitted.

In the acoustic wave device according to the third preferred embodiment, the piezoelectric layer 6A of the first acoustic wave resonator 3Ae is thinner than the piezoelectric layer 6B of the second acoustic wave resonator 3Be. The first acoustic wave resonator 3Ae and the second acoustic wave resonator 3Be are respectively similar to the first acoustic wave resonator 3A and the second acoustic wave resonator 3B of the acoustic wave device 1 according to the first preferred embodiment. In the first acoustic wave resonator 3Ad, the thickness of the piezoelectric layer 6A and the thickness of the low acoustic velocity film 5A are respectively different from the thickness of the piezoelectric layer 6A and the thickness of the low acoustic velocity film 5A of the acoustic wave device 1 according to the first preferred embodiment. In the second acoustic wave resonator 3Bd, the thickness of the piezoelectric layer 6B and the thickness of the low acoustic velocity film 5B are respectively different from the thickness of the piezoelectric layer 6B and the thickness of the low acoustic velocity film 5B of the acoustic wave device 1 according to the first preferred embodiment.

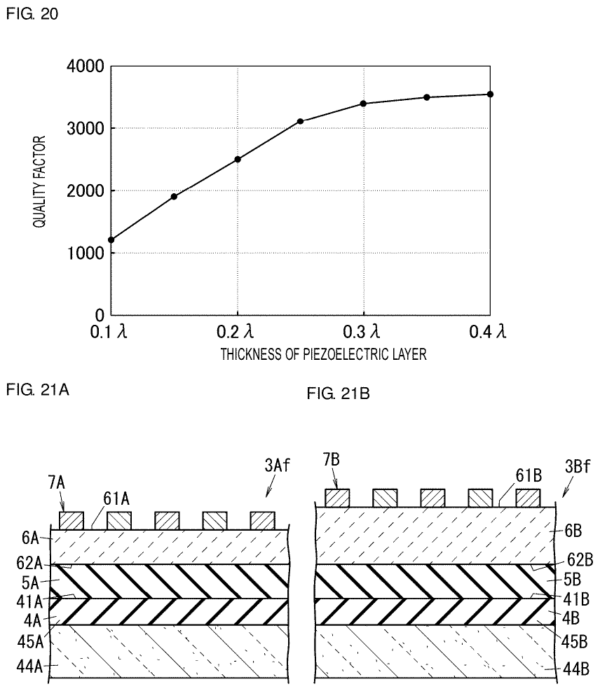

For the first acoustic wave resonator 3Ae, the surface 41A of the high acoustic velocity member 4A made of the silicon substrate is a (111) plane. The thicknesses of the low acoustic velocity film 5A, the piezoelectric layer 6A, and the interdigital transducer electrode 7A are normalized by λ that is the wave length of acoustic waves, which is determined by the electrode finger pitch of the interdigital transducer electrode 7A. In the first acoustic wave resonator 3Ae, λ is preferably about 1 μm, for example. FIG. 19 shows the relationship between the thickness of the piezoelectric layer and the phase characteristic of higher modes when, in an acoustic wave resonator of a third reference example, having similar features, components, and elements as the first acoustic wave resonator 3Ad, the thickness of the low acoustic velocity film made of silicon oxide is about 0.2λ, the thickness of the interdigital transducer electrode made of aluminum is about 0.08λ, and the thickness of the piezoelectric layer made of 50° Y-cut X-propagation LiTaO₃ piezoelectric monocrystal is changed in the range from about 0.2λ to about 0.3λ. In addition, FIG. 20 shows a change in quality factor when the thickness of the piezoelectric layer in the acoustic wave resonator of the third reference example is changed in the range from about 0.1λ to about 0.4λ. In the acoustic wave resonator of the third reference example, the response of higher modes occurs at about 5500 MHz.

It is found from FIG. 19 that, in the acoustic wave resonator of the third reference example, the response of higher modes tends to be significantly reduced or prevented as the thickness of the piezoelectric layer is reduced. This tendency also applies to the case where the surface, closer to the piezoelectric layer, of the high acoustic velocity member is a (110) plane or a (100) plane. From the viewpoint of significantly reducing or preventing higher modes of the acoustic wave resonator of the third reference example, the thickness of the piezoelectric layer is preferably decreased. In other words, from the viewpoint of significantly reducing or preventing higher modes of the first acoustic wave resonator 3Ae, the thickness of the piezoelectric layer 6A is preferably decreased.

In addition, it is found from FIG. 20 that, in the acoustic wave resonator of the third reference example, the quality factor tends to decrease as the thickness of the piezoelectric layer is reduced. In short, in the acoustic wave resonator of the third reference example, significant reduction or prevention of higher modes and significant improvement in quality factor are in a trade-off relationship. In addition, in the acoustic wave resonator of the third reference example, characteristic variations due to variations in the thickness of the piezoelectric layer tend to increase as the thickness of the piezoelectric layer reduces.

The acoustic wave device according to the third preferred embodiment, as well as the acoustic wave device 1 according to the first preferred embodiment (see FIG. 1 to FIG. 5B), is provided between the first terminal 101 defining and functioning as the antenna terminal and the second terminal 102 different from the first terminal 101. The acoustic wave device 1 includes the plurality of acoustic wave resonators 31 to 39. The plurality of acoustic wave resonators 31 to 39 include the plurality of series arm resonators (acoustic wave resonators 31, 33, 35, 37, 39) provided in the first path r1 connecting the first terminal 101 and the second terminal 102 and the plurality of parallel arm resonators (acoustic wave resonators 32, 34, 36, 38) provided in the plurality of second paths r21, r22, r23, r24 respectively connecting the plurality of nodes N1, N2, N3, N4 in the first path r1 to the ground. Where, of the plurality of acoustic wave resonators 31 to 39, the acoustic wave resonator electrically closest to the first terminal 101 is the antenna end resonator, the antenna end resonator is the first acoustic wave resonator 3Ae, and, of the plurality of acoustic wave resonators 31 to 39, at least one acoustic wave resonator other than the antenna end resonator is the second acoustic wave resonator 3Be. The first acoustic wave resonator 3Ae includes the piezoelectric layer 6A, the interdigital transducer electrode 7A including the plurality of electrode fingers (the plurality of first electrode fingers 73A and the plurality of second electrode fingers 74A), and the high acoustic velocity member 4A. The second acoustic wave resonator 3Be includes the piezoelectric layer 6B, the interdigital transducer electrode 7B including the plurality of electrode fingers (the plurality of first electrode fingers 73B and the plurality of second electrode fingers 74B), and the high acoustic velocity member 4B. The interdigital transducer electrode 7A of the first acoustic wave resonator 3Ae is provided on or above the piezoelectric layer 6A. The interdigital transducer electrode 7B of the second acoustic wave resonator 3Be is provided on or above the piezoelectric layer 6B. The high acoustic velocity member 4A is located across the piezoelectric layer 6A from the interdigital transducer electrode 7A. The high acoustic velocity member 4B is located across the piezoelectric layer 6B from the interdigital transducer electrode 7B. Bulk waves propagate through the high acoustic velocity member 4A at an acoustic velocity higher than acoustic waves propagate through the piezoelectric layer 6A. Bulk waves propagate through the high acoustic velocity member 4B at an acoustic velocity higher than acoustic waves propagate through the piezoelectric layer 6B. In each of the first acoustic wave resonator 3Ae and the second acoustic wave resonator 3Be, the thickness of the piezoelectric layer 6A or the piezoelectric layer 6B is preferably, for example, less than or equal to about 3.5λ where the wave length of acoustic waves, which is determined by the electrode finger pitch of the interdigital transducer electrode 7A or the interdigital transducer electrode 7B, is λ. The acoustic wave device satisfies a first condition and a second condition. The first condition is a condition that the high acoustic velocity member 4A of the first acoustic wave resonator 3Ae and the high acoustic velocity member 4B of the second acoustic wave resonator 3Be each include a silicon substrate, the surface 41A closer to the piezoelectric layer 6A in the silicon substrate of the first acoustic wave resonator 3Ae is a (111) plane or a (110) plane, and the surface 41B closer to the piezoelectric layer 6B in the silicon substrate of the second acoustic wave resonator 3Be is a (100) plane. The second condition is a condition that the piezoelectric layer 6A of the first acoustic wave resonator 3Ae is thinner than the piezoelectric layer 6B of the second acoustic wave resonator 3Be.

With the acoustic wave device according to the third preferred embodiment, the antenna end resonator is the first acoustic wave resonator 3Ae, and the surface 41A closer to the piezoelectric layer 6A in the silicon substrate of the first acoustic wave resonator 3Ae is a (111) plane or a (110) plane, so higher modes are significantly reduced or prevented. In addition, with the acoustic wave device according to the third preferred embodiment, of the plurality of acoustic wave resonators 31 to 39, at least one acoustic wave resonator 33 to 39 other than the antenna end resonator is the second acoustic wave resonator 3Be, and the surface 41B closer to the piezoelectric layer 6B in the silicon substrate of the second acoustic wave resonator 3Be is a (100) plane, so characteristic degradation is significantly reduced or prevented. With the acoustic wave device according to the third preferred embodiment, the piezoelectric layer 6A of the first acoustic wave resonator 3Ae is thinner than the piezoelectric layer 6B of the second acoustic wave resonator 3Be, so higher modes are significantly reduced or prevented.

The acoustic wave device according to the third preferred embodiment satisfies both the first condition and the second condition. However, when the acoustic wave device according to the third preferred embodiment satisfies at least one of the first condition and the second condition, higher modes are significantly reduced or prevented. Therefore, in the acoustic wave device according to the third preferred embodiment, the surface 41A, closer to the piezoelectric layer 6A, of the high acoustic velocity member 4A of the first acoustic wave resonator 3Ae and the surface 41B closer to the piezoelectric layer 6B, of the high acoustic velocity member 4B of the second acoustic wave resonator 3Be may be the same or similar plane directions. For example, both the surface 41A, closer to the piezoelectric layer 6A, of the silicon substrate of the first acoustic wave resonator 3Ae and the surface 41B, closer to the piezoelectric layer 6B, of the silicon substrate of the second acoustic wave resonator 3Be each may preferably be a (111) plane or may be a (110) plane or may be a (100) plane.

### First Modification of Third Embodiment

The acoustic wave device according to a first modification of the third preferred embodiment differs from the acoustic wave device according to the third preferred embodiment in that first acoustic wave resonators 3Af and second acoustic wave resonators 3Bf as shown in FIGS. 21A and 21B are provided instead of the first acoustic wave resonators 3Ae and the second acoustic wave resonators 3Be of the acoustic wave device according to the third preferred embodiment. The other features, components, and elements of the acoustic wave device according to the first modification of the third preferred embodiment are the same as or similar to the acoustic wave device according to the third preferred embodiment, so the drawings and description thereof are omitted where appropriate. As for the acoustic wave device according to the first modification of the third preferred embodiment, like reference numerals denote the same or similar components to those of the acoustic wave device according to the third preferred embodiment, and the description thereof is omitted.

The first acoustic wave resonator 3Af further includes a support substrate 44A. The second acoustic wave resonator 3Bf further includes a support substrate 44B. The high acoustic velocity member 4A includes a high acoustic velocity film 45A instead of the high acoustic velocity support substrate 42A. The high acoustic velocity member 4B includes a high acoustic velocity film 45B instead of the high acoustic velocity support substrate 42B. The high acoustic velocity film 45A is provided on or above the support substrate 44A. The high acoustic velocity film 45B is provided on or above the support substrate 44B. Here, the state of being provided on or above the support substrate 44A or the support substrate 44B includes a state of being directly provided on the support substrate 44A or the support substrate 44B and a state of being indirectly provided on the support substrate 44A or the support substrate 44B. A bulk wave that propagates at the lowest acoustic velocity of a plurality of bulk waves that propagate through the high acoustic velocity film 45A propagates at an acoustic velocity higher than acoustic waves propagate through the piezoelectric layer 6A. A bulk wave that propagates at the lowest acoustic velocity of a plurality of bulk waves that propagate through the high acoustic velocity film 45B propagates at an acoustic velocity higher than acoustic waves propagate through the piezoelectric layer 6B. The low acoustic velocity film 5A is provided on or above the high acoustic velocity film 45A. The low acoustic velocity film 5B is provided on or above the high acoustic velocity film 45B. Here, the state of being provided on or above the high acoustic velocity film 45A or the high acoustic velocity film 45B includes a state of being directly provided on the high acoustic velocity film 45A or the high acoustic velocity film 45B and a state of being indirectly provided on the high acoustic velocity film 45A or the high acoustic velocity film 45B. Transversal bulk waves propagate through the low acoustic velocity film 5A at an acoustic velocity lower than bulk waves propagate through the piezoelectric layer 6A. Transversal bulk waves propagate through the low acoustic velocity film 5B at an acoustic velocity lower than bulk waves propagate through the piezoelectric layer 6B. The piezoelectric layer 6A is provided on or above the low acoustic velocity film 5A. The piezoelectric layer 6B is provided on or above the low acoustic velocity film 5B. Here, the state of being provided on or above the low acoustic velocity film 5A or the low acoustic velocity film 5B includes a state of being directly provided on the low acoustic velocity film 5A or the low acoustic velocity film 5B and a state of being indirectly provided on the low acoustic velocity film 5A or the low acoustic velocity film 5B.

The material of each of the support substrates 44A, 44B is preferably, for example, silicon. However, the material is not limited thereto. The material may be a piezoelectric body, for example, sapphire, lithium tantalate, lithium niobate, and quartz crystal, various ceramics, for example, alumina, magnesia, silicon nitride, aluminum nitride, silicon carbide, zirconia, cordierite, mullite, steatite, and forsterite, a dielectric, for example, glass, a semiconductor, for example, gallium nitride, a resin, or the like.

In the first acoustic wave resonator 3Af, the high acoustic velocity film 45A significantly reduces or prevents the energy of acoustic waves of a main mode from leaking to the structure below the high acoustic velocity film 45A. In the second acoustic wave resonator 3Bf, the high acoustic velocity film 45B significantly reduces or prevents the energy of acoustic waves of a main mode from leaking to the structure below the high acoustic velocity film 45B.

In the first acoustic wave resonator 3Af, when the thickness of the high acoustic velocity film 45A is sufficiently large, the energy of acoustic waves of a main mode is distributed all over the piezoelectric layer 6A and the low acoustic velocity film 5A, distributed also to a portion, closer to the low acoustic velocity film 5A, of the high acoustic velocity film 45A, and not distributed to the support substrate 44A. In the second acoustic wave resonator 3Bf, when the thickness of the high acoustic velocity film 45B is sufficiently large, the energy of acoustic waves of a main mode is distributed all over the piezoelectric layer 6B and the low acoustic velocity film 5B, distributed also to a portion, closer to the low acoustic velocity film 5B, of the high acoustic velocity film 45B, and not distributed to the support substrate 44B. The mechanism of enclosing acoustic waves by the high acoustic velocity film 45A or the high acoustic velocity film 45B is a similar mechanism to the case of Love wave-type surface acoustic waves that are non-leaking SH (shear horizontal) waves and are described in, for example, Document “Introduction to surface acoustic wave device simulation technology”, Kenya HASHIMOTO, published by Realize Inc., pp. 26-28. The above-described mechanism differs from the mechanism of enclosing acoustic waves by Bragg reflector with an acoustic multilayer film.

The material of each of the high acoustic velocity films 45A, 45B is preferably, for example, at least one material selected from a group consisting of diamond-like carbon, aluminum nitride, aluminum oxide, silicon carbide, silicon nitride, silicon, sapphire, lithium tantalate, lithium niobate, quartz crystal, alumina, zirconia, cordierite, mullite, steatite, forsterite, magnesia, and diamond.

The thickness of the high acoustic velocity film 45A is preferably increased from the viewpoint of enclosing acoustic waves in the piezoelectric layer 6A and the low acoustic velocity film 5A. The thickness of the high acoustic velocity film 45B is preferably increased from the viewpoint of enclosing acoustic waves in the piezoelectric layer 6B and the low acoustic velocity film 5B. The first acoustic wave resonator 3Af may include an adhesion layer, a dielectric film, or the like other than the high acoustic velocity film 45A, the low acoustic velocity film 5A, or the piezoelectric layer 6A. The second acoustic wave resonator 3Bf may include an adhesion layer, a dielectric film, or the like other than the high acoustic velocity film 45B, the low acoustic velocity film 5B, or the piezoelectric layer 6B.

With the acoustic wave device according to the first modification of the third preferred embodiment, as well as the acoustic wave device according to the third preferred embodiment, the piezoelectric layer 6A of the first acoustic wave resonator 3Af is thinner than the piezoelectric layer 6B of the second acoustic wave resonator 3Bf, so higher modes are significantly reduced or prevented. In addition, with the acoustic wave device according to the first modification of the third preferred embodiment, the first acoustic wave resonator 3Af includes the high acoustic velocity film 45A, and the second acoustic wave resonator 3Bf includes the high acoustic velocity film 45B, so a leak of the energy of acoustic waves of a main mode to the support substrate 44A or the support substrate 44B is significantly reduced or prevented.

### Second Modification of Third Embodiment

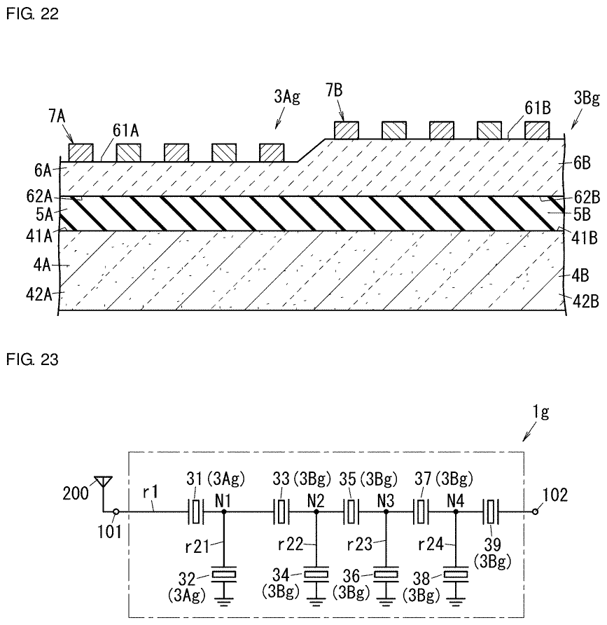

As shown in FIG. 22 and FIG. 23, in an acoustic wave device 1g according to a second modification of the third preferred embodiment, the plurality of acoustic wave resonators 31 to 39 including first acoustic wave resonators 3Ag and second acoustic wave resonators 3Bg are integrated into a single chip. For the first acoustic wave resonator 3Ag and the second acoustic wave resonator 3Bg, like reference numerals denote similar components to those of the first acoustic wave resonator 3Ae and the second acoustic wave resonator 3Be of the acoustic wave device according to the third preferred embodiment, and the description thereof is omitted.

As shown in FIG. 22, in the acoustic wave device 1g according to the second modification of the third preferred embodiment, the high acoustic velocity member 4A of the first acoustic wave resonator 3Ag and the high acoustic velocity member 4B of the second acoustic wave resonator 3Bg define an integrated high acoustic velocity layer. In addition, the low acoustic velocity film 5A of the first acoustic wave resonator 3Ag and the low acoustic velocity film 5B of the second acoustic wave resonator 3Bg define an integrated low acoustic velocity film. In addition, the piezoelectric layer 6A of the first acoustic wave resonator 3Ag and the piezoelectric layer 6B of the second acoustic wave resonator 3Bg define an integrated piezoelectric layer. In FIG. 23, the state where the plurality of acoustic wave resonators 31 to 39 is integrated into a single chip is represented by the alternate long and short dashed line. With the acoustic wave device 1g according to the second modification of the third preferred embodiment, the size is reduced as compared to the acoustic wave device according to the third preferred embodiment. In addition, with the acoustic wave device according to the second modification of the third preferred embodiment, as well as the acoustic wave device according to the third preferred embodiment, the piezoelectric layer 6A of the first acoustic wave resonator 3Ag is thinner than the piezoelectric layer 6B of the second acoustic wave resonator 3Bg, so higher modes are significantly reduced or prevented.

### Fourth Preferred Embodiment

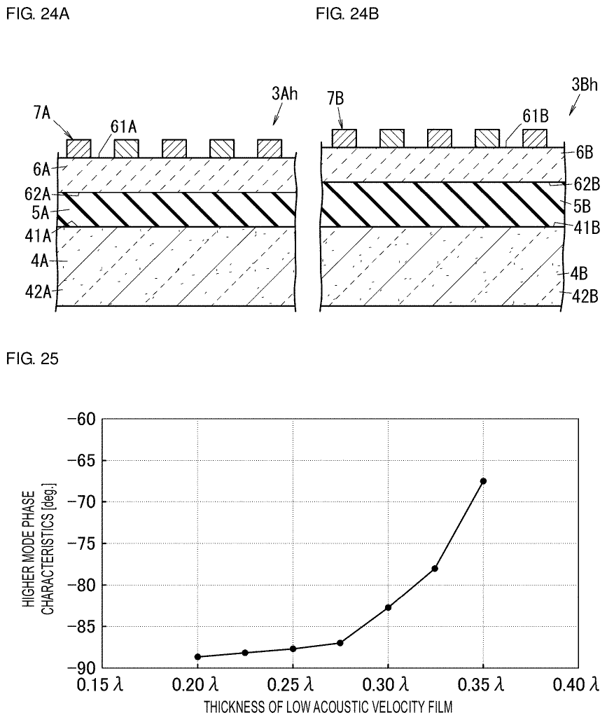

The circuitry of an acoustic wave device according to a fourth preferred embodiment of the present invention is the same as or similar to the circuitry of the acoustic wave device 1 according to the first preferred embodiment, so the drawings and description thereof are omitted. The acoustic wave device according to the fourth preferred embodiment differs from the acoustic wave device 1 according to the first preferred embodiment in that first acoustic wave resonators 3Ah and second acoustic wave resonators 3Bh as shown in FIGS. 24A and 24B are provided instead of the first acoustic wave resonators 3A and the second acoustic wave resonators 3B of the acoustic wave device 1 according to the first preferred embodiment. As for the acoustic wave device according to the fourth preferred embodiment, like reference numerals denote similar components to those of the acoustic wave device 1 according to the first preferred embodiment, and the description thereof is omitted.

In the acoustic wave device according to the fourth preferred embodiment, the low acoustic velocity film 5A of the first acoustic wave resonator 3Ah is thinner than the low acoustic velocity film 5B of the second acoustic wave resonator 3Bh. The first acoustic wave resonator 3Ah and the second acoustic wave resonator 3Bh are respectively similar to the first acoustic wave resonator 3A and the second acoustic wave resonator 3B of the acoustic wave device according to the first preferred embodiment. In the first acoustic wave resonator 3Ah, the thickness of the piezoelectric layer 6A and the thickness of the low acoustic velocity film 5A are respectively different from the thickness of the piezoelectric layer 6A and the thickness of the low acoustic velocity film 5A of the acoustic wave device according to the first preferred embodiment. In the second acoustic wave resonator 3Bh, the thickness of the piezoelectric layer 6B and the thickness of the low acoustic velocity film 5B are respectively different from the thickness of the piezoelectric layer 6B and the thickness of the low acoustic velocity film 5B of the acoustic wave device according to the first preferred embodiment.

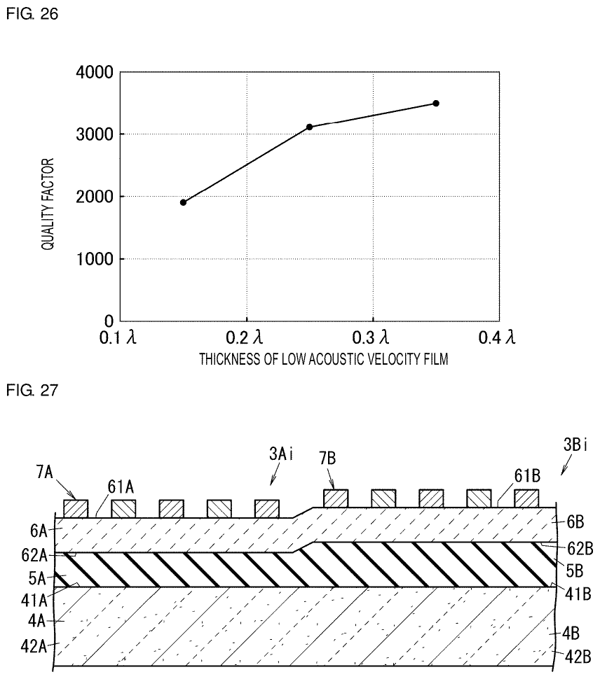

For the first acoustic wave resonator 3Ah, the surface 41A of the high acoustic velocity member 4A made of the silicon substrate is a (111) plane. The thicknesses of the low acoustic velocity film 5A, the piezoelectric layer 6A, and the interdigital transducer electrode 7A are normalized by λ that is the wave length of acoustic waves, which is determined by the electrode finger pitch of the interdigital transducer electrode 7A. In the first acoustic wave resonator 3Ah, λ is about 1 μm, for example. FIG. 25 shows the relationship between the thickness of the low acoustic velocity film and the phase characteristic of higher modes when, in an acoustic wave resonator of a fourth reference example, having similar features, components, and elements as the first acoustic wave resonator 3Ah, the thickness of the interdigital transducer electrode made of aluminum is about 0.08λ, the thickness of the piezoelectric layer made of 50° Y-cut X-propagation LiTaO₃ piezoelectric monocrystal is about 0.2λ, and the thickness of the low acoustic velocity film made of silicon oxide is changed in the range from about 0.2λ to about 0.35λ. In addition, FIG. 26 shows a change in quality factor when the thickness of the low acoustic velocity film in the acoustic wave resonator of the fourth reference example is changed in the range from about 0.15λ to about 0.35λ. In the acoustic wave resonator of the fourth reference example, the response of higher modes occurs at about 700 MHz.

It is found from FIG. 25 that, in the acoustic wave resonator of the fourth reference example, the response of higher modes tends to be significantly reduced or prevented as the thickness of the low acoustic velocity film is reduced. This tendency also applies to the case where the surface, closer to the piezoelectric layer, of the silicon substrate included in the high acoustic velocity member is a (110) plane or a (100) plane. From the viewpoint of significantly reducing or preventing higher modes of the acoustic wave resonator of the fourth reference example, the thickness of the low acoustic velocity film is preferably decreased. In other words, for the first acoustic wave resonator 3Ah, the thickness of the low acoustic velocity film 5A is preferably decreased from the viewpoint of significantly reducing or preventing higher modes of the first acoustic wave resonator 3Ah. With the acoustic wave resonator of the fourth reference example, the absolute value of TCF tends to increase as the thickness of the low acoustic velocity film is reduced. This tendency also applies to the case where the surface, closer to the piezoelectric layer, of the silicon substrate included in the high acoustic velocity member is a (110) plane or a (100) plane. For the first acoustic wave resonator 3Ah, the thickness of the low acoustic velocity film 5A is preferably decreased from the viewpoint of reducing the absolute value of TCF while significantly reducing or preventing higher modes of the first acoustic wave resonator 3Ah.

In addition, it is found from FIG. 26 that, in the acoustic wave resonator of the fourth reference example, the quality factor tends to decrease as the thickness of the low acoustic velocity film is reduced. This tendency also applies to the case where the surface, closer to the piezoelectric layer, of the silicon substrate included in the high acoustic velocity member is a (110) plane or a (100) plane. In the acoustic wave resonator of the fourth reference example, significant reduction or prevention of higher modes and significant improvement in quality factor are in a trade-off relationship. Therefore, in the acoustic wave device according to the fourth preferred embodiment, the low acoustic velocity film 5B of the second acoustic wave resonator 3Bh is preferably thicker than the low acoustic velocity film 5B of the first acoustic wave resonator 3Ah.

The acoustic wave device according to the fourth preferred embodiment, as well as the acoustic wave device 1 according to the first preferred embodiment (see FIG. 1 to FIG. 5B), is provided between the first terminal 101 defining and functioning as the antenna terminal and the second terminal 102 different from the first terminal 101. The acoustic wave device 1 includes the plurality of acoustic wave resonators 31 to 39. The plurality of acoustic wave resonators 31 to 39 include the plurality of series arm resonators (acoustic wave resonators 31, 33, 35, 37, 39) provided in the first path r1 connecting the first terminal 101 and the second terminal 102 and the plurality of parallel arm resonators (acoustic wave resonators 32, 34, 36, 38) provided in the plurality of second paths r21, r22, r23, r24 respectively connecting the plurality of nodes N1, N2, N3, N4 in the first path r1 to the ground. Where, of the plurality of acoustic wave resonators 31 to 39, the acoustic wave resonator electrically closest to the first terminal 101 is the antenna end resonator, the antenna end resonator is the first acoustic wave resonator 3Ah, and, of the plurality of acoustic wave resonators 31 to 39, at least one acoustic wave resonator other than the antenna end resonator is the second acoustic wave resonator 3Bh. The first acoustic wave resonator 3Ah includes the piezoelectric layer 6A, the interdigital transducer electrode 7A including the plurality of electrode fingers (the plurality of first electrode fingers 73A and the plurality of second electrode fingers 74A), and the high acoustic velocity member 4A. The second acoustic wave resonator 3Bh includes the piezoelectric layer 6B, the interdigital transducer electrode 7B including the plurality of electrode fingers (the plurality of first electrode fingers 73B and the plurality of second electrode fingers 74B), and the high acoustic velocity member 4B. The interdigital transducer electrode 7A of the first acoustic wave resonator 3Ah is provided on or above the piezoelectric layer 6A. The interdigital transducer electrode 7B of the second acoustic wave resonator 3Bh is provided on or above the piezoelectric layer 6B. The high acoustic velocity member 4A is located across the piezoelectric layer 6A from the interdigital transducer electrode 7A. The high acoustic velocity member 4B is located across the piezoelectric layer 6B from the interdigital transducer electrode 7B. Bulk waves propagate through the high acoustic velocity member 4A at an acoustic velocity higher than acoustic waves propagate through the piezoelectric layer 6A. Bulk waves propagate through the high acoustic velocity member 4B at an acoustic velocity higher than acoustic waves propagate through the piezoelectric layer 6B. In the first acoustic wave resonator 3Ah, the thickness of the piezoelectric layer 6A is preferably, for example, less than or equal to about 3.5λ where the wave length of acoustic waves, which is determined by the electrode finger pitch of the interdigital transducer electrode 7A, is λ. In the second acoustic wave resonator 3Bh, the piezoelectric layer 6B is preferably, for example, less than or equal to about 3.5λ where the wave length of acoustic waves, which is determined by the electrode finger pitch of the interdigital transducer electrode 7B, is λ. The acoustic wave device satisfies a first condition and a third condition. The first condition is a condition that the high acoustic velocity member 4A of the first acoustic wave resonator 3Ah and the high acoustic velocity member 4B of the second acoustic wave resonator 3Bh each include a silicon substrate, the surface 41A closer to the piezoelectric layer 6A in the silicon substrate of the first acoustic wave resonator 3Ah is a (111) plane or a (110) plane, and the surface 41B closer to the piezoelectric layer 6B in the silicon substrate of the second acoustic wave resonator 3Bh is a (100) plane. The third condition is a condition that the first acoustic wave resonator 3Ah includes the low acoustic velocity film 5A, the second acoustic wave resonator 3Bh includes the low acoustic velocity film 5B, and the low acoustic velocity film 5A of the first acoustic wave resonator 3Ah is thinner than the low acoustic velocity film 5B of the second acoustic wave resonator 3Bh. The low acoustic velocity film 5A is provided between the high acoustic velocity member 4A and the piezoelectric layer 6A. The low acoustic velocity film 5B is provided between the high acoustic velocity member 4B and the piezoelectric layer 6B. Bulk waves propagate through the low acoustic velocity film 5A at an acoustic velocity lower than bulk waves propagate through the piezoelectric layer 6A. Bulk waves propagate through the low acoustic velocity film 5B at an acoustic velocity lower than bulk waves propagate through the piezoelectric layer 6B.

With the acoustic wave device according to the fourth preferred embodiment, the antenna end resonator is the first acoustic wave resonator 3Ah, and the surface 41A closer to the piezoelectric layer 6A in the silicon substrate of the first acoustic wave resonator 3Ah is a (111) plane or a (110) plane, so higher modes are significantly reduced or prevented. In addition, with the acoustic wave device according to the fourth preferred embodiment, of the plurality of acoustic wave resonators 31 to 39, at least one acoustic wave resonator 33 to 39 other than the antenna end resonator is the second acoustic wave resonator 3Bh, and the surface 41B closer to the piezoelectric layer 6B in the silicon substrate of the second acoustic wave resonator 3Bh is a (100) plane, so characteristic degradation is significantly reduced or prevented. With the acoustic wave device according to the fourth preferred embodiment, the low acoustic velocity film 5A of the first acoustic wave resonator 3Ah is thinner than the low acoustic velocity film 5B of the second acoustic wave resonator 3Bh, so higher modes are significantly reduced or prevented.

The acoustic wave device according to the fourth preferred embodiment satisfies both the first condition and the third condition. However, when the acoustic wave device according to the fourth preferred embodiment satisfies at least one of the first condition and the third condition, higher modes are significantly reduced or prevented. Therefore, in the acoustic wave device according to the fourth preferred embodiment, the surface 41A closer to the piezoelectric layer 6A in the silicon substrate of the first acoustic wave resonator 3Ah and the surface 41B closer to the piezoelectric layer 6B in the silicon substrate of the second acoustic wave resonator 3Bh may be the same or similar plane directions. For example, both the surface 41A closer to the piezoelectric layer 6A in the silicon substrate of the first acoustic wave resonator 3Ah and the surface 41B closer to the piezoelectric layer 6B in the silicon substrate of the second acoustic wave resonator 3Bh each may be a (111) plane or may be a (110) plane or may be a (100) plane.

### Modification of Fourth Embodiment

As shown in FIG. 27, in an acoustic wave device according to a modification of the fourth preferred embodiment, the plurality of acoustic wave resonators 31 to 39 (see FIG. 1) including first acoustic wave resonators 3Ai and second acoustic wave resonators 3Bi are integrated into a single chip. For the first acoustic wave resonator 3Ai and the second acoustic wave resonator 3Bi, like reference numerals denote similar components to those of the first acoustic wave resonator 3Ah and the second acoustic wave resonator 3Bh of the acoustic wave device according to the fourth preferred embodiment, and the description thereof is omitted.

In the acoustic wave device according to the modification of the fourth preferred embodiment, the high acoustic velocity member 4A of the first acoustic wave resonator 3Ai and the high acoustic velocity member 4B of the second acoustic wave resonator 3Bi define an integrated high acoustic velocity layer. In addition, the low acoustic velocity film 5A of the first acoustic wave resonator 3Ai and the low acoustic velocity film 5B of the second acoustic wave resonator 3Bi define an integrated low acoustic velocity film. In addition, the piezoelectric layer 6A of the first acoustic wave resonator 3Ai and the piezoelectric layer 6B of the second acoustic wave resonator 3Bi define an integrated piezoelectric layer. With the acoustic wave device according to the modification of the fourth preferred embodiment, the size is reduced as compared to the acoustic wave device according to the fourth preferred embodiment. In addition, with the acoustic wave device according to the modification of the fourth preferred embodiment, the low acoustic velocity film 5A of the first acoustic wave resonator 3Ai is thinner than the low acoustic velocity film 5B of the second acoustic wave resonator 3Bi, so higher modes are significantly reduced or prevented as in the case of the acoustic wave device according to the fourth preferred embodiment.

### Fifth Preferred Embodiment

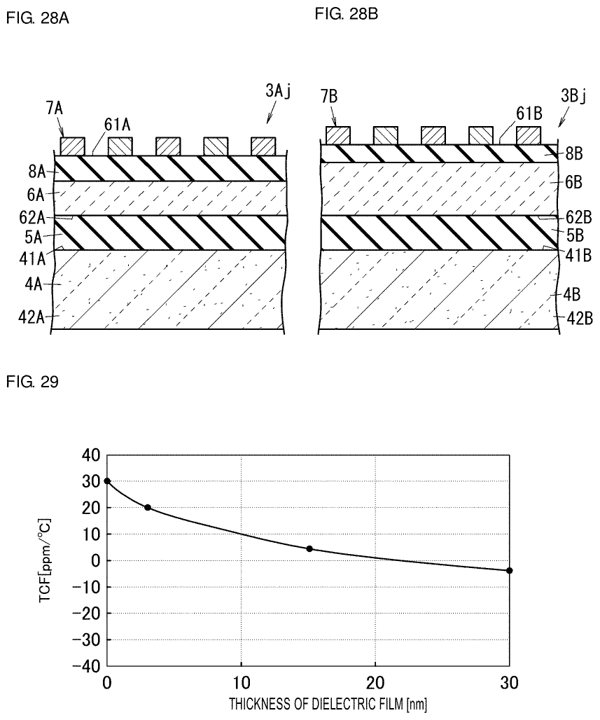

The circuitry of an acoustic wave device according to a fifth preferred embodiment of the present invention is the same as or similar to the circuitry of the acoustic wave device 1 according to the first preferred embodiment (FIG. 1 to FIG. 5B), so the drawings and description thereof are omitted. The acoustic wave device according to the fifth preferred embodiment differs from the acoustic wave device 1 according to the first preferred embodiment in that first acoustic wave resonators 3Aj and second acoustic wave resonators 3Bj as shown in FIGS. 28A and 28B are provided instead of the first acoustic wave resonators 3A and the second acoustic wave resonators 3B of the acoustic wave device 1 according to the first preferred embodiment. As for the acoustic wave device according to the fifth preferred embodiment, like reference numerals denote similar components to those of the acoustic wave device 1 according to the first preferred embodiment, and the description thereof is omitted.

The first acoustic wave resonator 3Aj includes a dielectric film 8A. The second acoustic wave resonator 3Bj includes a dielectric film 8B. The dielectric film 8A is provided on or above the piezoelectric layer 6A. The dielectric film 8B is provided on or above the piezoelectric layer 6B. The interdigital transducer electrode 7A is provided on or above the dielectric film 8A. The interdigital transducer electrode 7B is provided on or above the dielectric film 8B. The material of each of the dielectric films 8A, 8B is, for example, silicon oxide.

In addition, in the acoustic wave device according to the fifth preferred embodiment, as well as the acoustic wave device according to the third preferred embodiment, the piezoelectric layer 6A of the first acoustic wave resonator 3Aj is thinner than the piezoelectric layer 6B of the second acoustic wave resonator 3Bj. The first acoustic wave resonator 3Aj and the second acoustic wave resonator 3Bj are respectively the same as or similar to the first acoustic wave resonator 3A and the second acoustic wave resonator 3B of the acoustic wave device according to the first preferred embodiment. In the first acoustic wave resonator 3Aj, the thickness of the piezoelectric layer 6A and the thickness of the low acoustic velocity film 5A are respectively different from the thickness of the piezoelectric layer 6A and the thickness of the low acoustic velocity film 5A of the acoustic wave device 1 according to the first preferred embodiment. In the second acoustic wave resonator 3Bj, the thickness of the piezoelectric layer 6B and the thickness of the low acoustic velocity film 5B are respectively different from the thickness of the piezoelectric layer 6B and the thickness of the low acoustic velocity film 5B of the acoustic wave device 1 according to the first preferred embodiment.

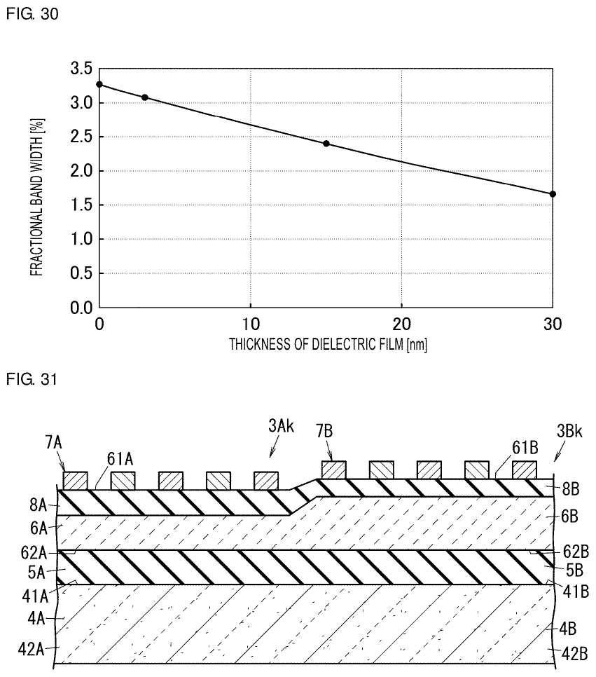

For the first acoustic wave resonator 3Aj, the surface 41A of the silicon substrate included in the high acoustic velocity member 4A is a (111) plane. The thicknesses of the low acoustic velocity film 5A, the piezoelectric layer 6A, and the interdigital transducer electrode 7A are normalized by λ that is the wave length of acoustic waves, which is determined by the electrode finger pitch of the interdigital transducer electrode 7A. In the first acoustic wave resonator 3Aj, λ is about 1.48 μm, for example. FIG. 29 shows the relationship between the thickness of the dielectric film and a TCF when, in an acoustic wave resonator of a fifth reference example, having similar features, components, and elements as the first acoustic wave resonator 3Aj, the thickness of the interdigital transducer electrode made of aluminum is about 0.07λ, the thickness of the piezoelectric layer made of 50° Y-cut X-propagation LiTaO₃ piezoelectric monocrystal is about 0.3λ, the thickness of the low acoustic velocity film made of silicon oxide is about 0.35λ, and the thickness of the dielectric film is changed in the range from about 0 nm to about 30 nm. In addition, FIG. 30 shows the relationship between the thickness of the dielectric film and a fractional band width in the acoustic wave resonator of the fifth reference example.

It is found from FIG. 29 that, in the acoustic wave resonator of the fifth reference example, the TCF tends to reduce as the thickness of the dielectric film is increased in the range in which the TCF is a positive value. This tendency also applies to the case where the surface closer to the piezoelectric layer in the silicon substrate included in the high acoustic velocity member is a (110) plane or a (100) plane. From the viewpoint of significantly reducing or preventing fluctuations in frequency to a change in temperature in the resonant characteristics of the acoustic wave resonator of the fifth reference example, the thickness of the dielectric film is preferably increased when the thickness is less than or equal to about 22 nm. In other words, for the first acoustic wave resonator 3Aj, the thickness of the dielectric film 8A is preferably increased from the viewpoint of reducing the TCF of the first acoustic wave resonator 3Aj. From FIG. 30, in the acoustic wave resonator of the fifth reference example, the fractional band width tends to narrow as the thickness of the dielectric film is increased. This tendency also applies to the case where the surface closer to the piezoelectric layer in the silicon substrate included in the high acoustic velocity member is a (110) plane or a (100) plane. For the first acoustic wave resonator 3Aj, from the viewpoint of expanding the fractional band width of the first acoustic wave resonator 3Aj, the thickness of the dielectric film 8A is preferably decreased, and the dielectric film 8A is preferably not included.

With the acoustic wave device according to the fifth preferred embodiment, the antenna end resonator is the first acoustic wave resonator 3Aj, and the surface 41A closer to the piezoelectric layer 6A in the silicon substrate included in the high acoustic velocity member 4A of the first acoustic wave resonator 3Aj is a (111) plane or a (110) plane, so higher modes are significantly reduced or prevented. In addition, with the acoustic wave device according to the fifth preferred embodiment, of the plurality of acoustic wave resonators 31 to 39 (see FIG. 1), at least one acoustic wave resonator 33 to 39 other than the antenna end resonator is the second acoustic wave resonator 3Bj, and the surface 41B closer to the piezoelectric layer 6B in the silicon substrate included in the high acoustic velocity member 4B of the second acoustic wave resonator 3Bj is a (100) plane, so characteristic degradation is significantly reduced or prevented. With the acoustic wave device according to the fifth preferred embodiment, the piezoelectric layer 6A of the first acoustic wave resonator 3Aj is thinner than the piezoelectric layer 6B of the second acoustic wave resonator 3Bj, so higher modes are significantly reduced or prevented.

The acoustic wave device according to the fifth preferred embodiment, as well as the acoustic wave device according to the third preferred embodiment, satisfies both the first condition and the second condition. However, when the acoustic wave device according to the fifth preferred embodiment satisfies at least one of the first condition and the second condition, higher modes are significantly reduced or prevented. Therefore, in the acoustic wave device according to the fifth preferred embodiment, the surface 41A closer to the piezoelectric layer 6A in the silicon substrate included in the high acoustic velocity member 4A of the first acoustic wave resonator 3Aj and the surface 41B closer to the piezoelectric layer 6B in the silicon substrate included in the high acoustic velocity member 4B of the second acoustic wave resonator 3Bj may be the same or similar plane directions. For example, both the surface 41A closer to the piezoelectric layer 6A in the silicon substrate of the first acoustic wave resonator 3Aj and the surface 41B closer to the piezoelectric layer 6B in the silicon substrate of the second acoustic wave resonator 3Bj each may be a (111) plane or may be a (110) plane or may be a (100) plane.

In addition, in the acoustic wave device according to the fifth preferred embodiment, when the second condition is satisfied, the first acoustic wave resonator 3Aj further includes the dielectric film 8A provided between the piezoelectric layer 6A and the interdigital transducer electrode 7A, and the second acoustic wave resonator 3Bj further includes the dielectric film 8B provided between the piezoelectric layer 6B and the interdigital transducer electrode 7B. The thickness of the dielectric film 8A of the first acoustic wave resonator 3Aj is greater than the thickness of the dielectric film 8B of the second acoustic wave resonator 3Bj. Therefore, with the acoustic wave device according to the fifth preferred embodiment, an excessive increase in the electromechanical coupling coefficient of the first acoustic wave resonator 3Aj is significantly reduced or prevented.

The acoustic wave device according to the fifth preferred embodiment may have a structure in which, of the first acoustic wave resonator 3Aj and the second acoustic wave resonator 3Bj, only the first acoustic wave resonator 3Aj includes the dielectric film 8A provided between the piezoelectric layer 6A and the interdigital transducer electrode 7A and the second acoustic wave resonator 3Bj does not include the dielectric film 8B provided between the piezoelectric layer 6B and the interdigital transducer electrode 7B.

The acoustic wave device according to the fifth preferred embodiment may have a structure in which, of the first acoustic wave resonator 3Aj and the second acoustic wave resonator 3Bj, only the second acoustic wave resonator 3Bj includes the dielectric film 8B provided between the piezoelectric layer 6B and the interdigital transducer electrode 7B and the first acoustic wave resonator 3Aj does not include the dielectric film 8A provided between the piezoelectric layer 6A and the interdigital transducer electrode 7A.

### First Modification of Fifth Embodiment

As shown in FIG. 31, in an acoustic wave device according to a first modification of the fifth preferred embodiment, the plurality of acoustic wave resonators 31 to 39 (see FIG. 1) including first acoustic wave resonators 3Ak and second acoustic wave resonators 3Bk are integrated into a single chip. For the first acoustic wave resonator 3Ak and the second acoustic wave resonator 3Bk, like reference numerals denote the same or similar components to those of the first acoustic wave resonator 3Aj and the second acoustic wave resonator 3Bj of the acoustic wave device according to the fifth preferred embodiment, and the description thereof is omitted.

In the acoustic wave device according to the first modification of the fifth preferred embodiment, the high acoustic velocity member 4A of the first acoustic wave resonator 3Ak and the high acoustic velocity member 4B of the second acoustic wave resonator 3Bk define an integrated high acoustic velocity layer. In addition, the low acoustic velocity film 5A of the first acoustic wave resonator 3Ak and the low acoustic velocity film 5B of the second acoustic wave resonator 3Bk define an integrated low acoustic velocity film. In addition, the piezoelectric layer 6A of the first acoustic wave resonator 3Ak and the piezoelectric layer 6B of the second acoustic wave resonator 3Bk define an integrated piezoelectric layer. In addition, the dielectric film 8A of the first acoustic wave resonator 3Ak and the dielectric film 8B of the second acoustic wave resonator 3Bk define an integrated dielectric film. With the acoustic wave device according to the first modification of the fifth preferred embodiment, the size is reduced as compared to the acoustic wave device according to the fifth preferred embodiment. In addition, with the acoustic wave device according to the first modification of the fifth preferred embodiment, the piezoelectric layer 6A of the first acoustic wave resonator 3Ak is thinner than the piezoelectric layer 6B of the second acoustic wave resonator 3Bk, higher modes are significantly reduced or prevented as in the case of the acoustic wave device according to the fifth preferred embodiment.

### Second Modification of Fifth Embodiment

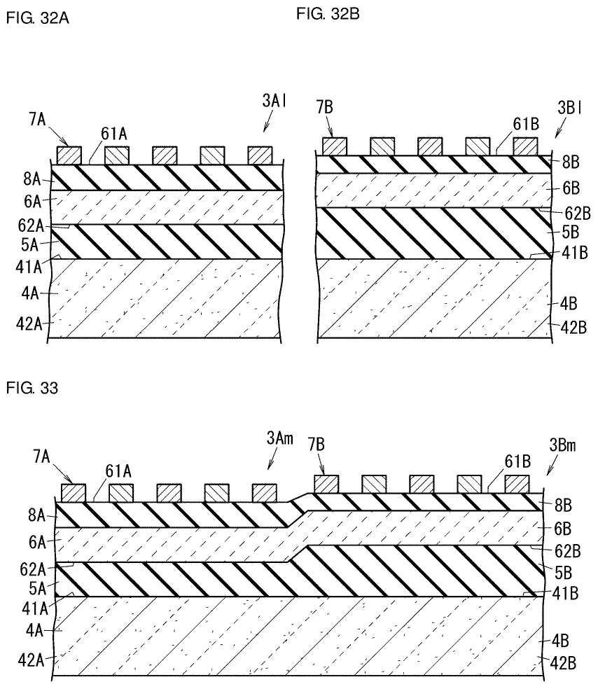

The acoustic wave device according to a second modification of the fifth preferred embodiment differs from the acoustic wave device according to the fifth preferred embodiment in that first acoustic wave resonators 3A1 and second acoustic wave resonators 3B1 as shown in FIGS. 32A and 32B are provided instead of the first acoustic wave resonators 3Aj and the second acoustic wave resonators 3Bj of the acoustic wave device according to the fifth preferred embodiment. As for the acoustic wave device according to the second modification of the fifth preferred embodiment, like reference numerals denote the same or similar components to those of the acoustic wave device according to the fifth preferred embodiment, and the description thereof is omitted.

In the acoustic wave device according to the second modification of the fifth preferred embodiment, as well as the acoustic wave device according to the fourth preferred embodiment, the low acoustic velocity film 5A of the first acoustic wave resonator 3A1 is thinner than the low acoustic velocity film 5B of the second acoustic wave resonator 3B1. In the acoustic wave device according to the second modification of the fifth preferred embodiment, the thickness of the piezoelectric layer 6A of the first acoustic wave resonator 3A1 and the thickness of the piezoelectric layer 6B of the second acoustic wave resonator 3B1 are the same or substantially the same.

With the acoustic wave device according to the second modification of the fifth preferred embodiment, the antenna end resonator is the first acoustic wave resonator 3Aj, and the surface 41A closer to the piezoelectric layer 6A in the silicon substrate included in the high acoustic velocity member 4A of the first acoustic wave resonator 3A1 is a (111) plane or a (110) plane, so higher modes are significantly reduced or prevented. In addition, with the acoustic wave device according to the second modification of the fifth preferred embodiment, of the plurality of acoustic wave resonators 31 to 39, at least one acoustic wave resonator 33 to 39 (see FIG. 1) other than the antenna end resonator is the second acoustic wave resonator 3B1, and the surface 41B closer to the piezoelectric layer 6B in the silicon substrate included in the high acoustic velocity member 4B of the second acoustic wave resonator 3B1 is a (100) plane, so characteristic degradation is significantly reduced or prevented. With the acoustic wave device according to the second modification of the fifth preferred embodiment, the low acoustic velocity film 5A of the first acoustic wave resonator 3A1 is thinner than the low acoustic velocity film 5B of the second acoustic wave resonator 3B1, so higher modes are significantly reduced or prevented.

### Third Modification of Fifth Embodiment

As shown in FIG. 33, in an acoustic wave device according to a third modification of the fifth preferred embodiment, the plurality of acoustic wave resonators 31 to 39 (see FIG. 3) including first acoustic wave resonators 3Am and second acoustic wave resonators 3Bm are integrated into a single chip. For the first acoustic wave resonator 3Am and the second acoustic wave resonator 3Bm, like reference numerals denote the same or similar components to those of the first acoustic wave resonator 3A1 and the second acoustic wave resonator 3B1 of the acoustic wave device according to the second modification of the fifth preferred embodiment, and the description thereof is omitted.

In the acoustic wave device according to the third modification of the fifth preferred embodiment, the high acoustic velocity member 4A of the first acoustic wave resonator 3Am and the high acoustic velocity member 4B of the second acoustic wave resonator 3Bm define an integrated high acoustic velocity layer. In addition, the low acoustic velocity film 5A of the first acoustic wave resonator 3Am and the low acoustic velocity film 5B of the second acoustic wave resonator 3Bm define an integrated low acoustic velocity film. In addition, the piezoelectric layer 6A of the first acoustic wave resonator 3Am and the piezoelectric layer 6B of the second acoustic wave resonator 3Bm define an integrated piezoelectric layer. In addition, the dielectric film 8A of the first acoustic wave resonator 3Am and the dielectric film 8B of the second acoustic wave resonator 3Bm define an integrated dielectric film. With the acoustic wave device according to the third modification of the fifth preferred embodiment, the size is reduced as compared to the acoustic wave device according to the second modification of the fifth preferred embodiment. In addition, with the acoustic wave device according to the third modification of the fifth preferred embodiment, the low acoustic velocity film 5A of the first acoustic wave resonator 3Am is thinner than the low acoustic velocity film 5B of the second acoustic wave resonator 3Bm, so higher modes are significantly reduced or prevented as in the case of the acoustic wave device according to the fifth preferred embodiment.

### Sixth Preferred Embodiment

The circuitry of an acoustic wave device according to a sixth preferred embodiment of the present invention is the same as or similar to the circuitry of the acoustic wave device 1 according to the first preferred embodiment, so the drawings and description thereof are omitted. The acoustic wave device according to the sixth preferred embodiment differs from the acoustic wave device 1 according to the first preferred embodiment in that first acoustic wave resonators 3An and second acoustic wave resonators 3Bn as shown in FIGS. 34A and 34B are provided instead of the first acoustic wave resonators 3A and the second acoustic wave resonators 3B of the acoustic wave device 1 according to the first preferred embodiment. As for the acoustic wave device according to the sixth preferred embodiment, like reference numerals denote the same or similar components to those of the acoustic wave device 1 according to the first preferred embodiment, and the description thereof is omitted.

In the acoustic wave device according to the sixth preferred embodiment, a cut angle θ_{A} of the piezoelectric layer 6A of the first acoustic wave resonator 3An is preferably greater than a cut angle θ_{B} of the piezoelectric layer 6B of the second acoustic wave resonator 3Bn.

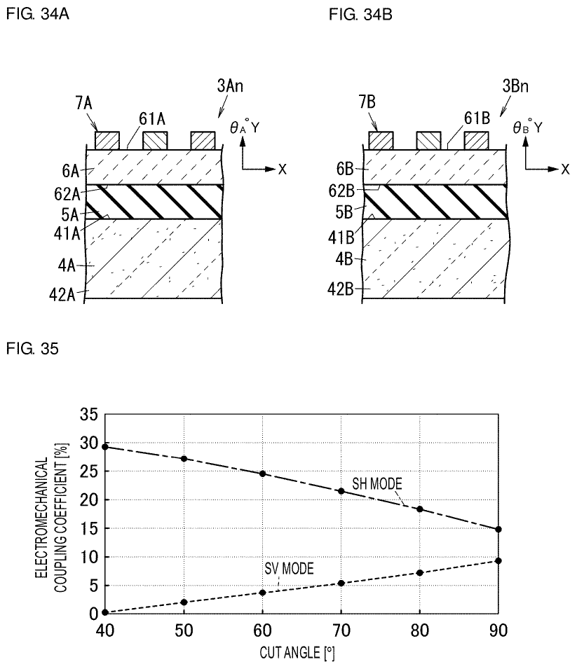

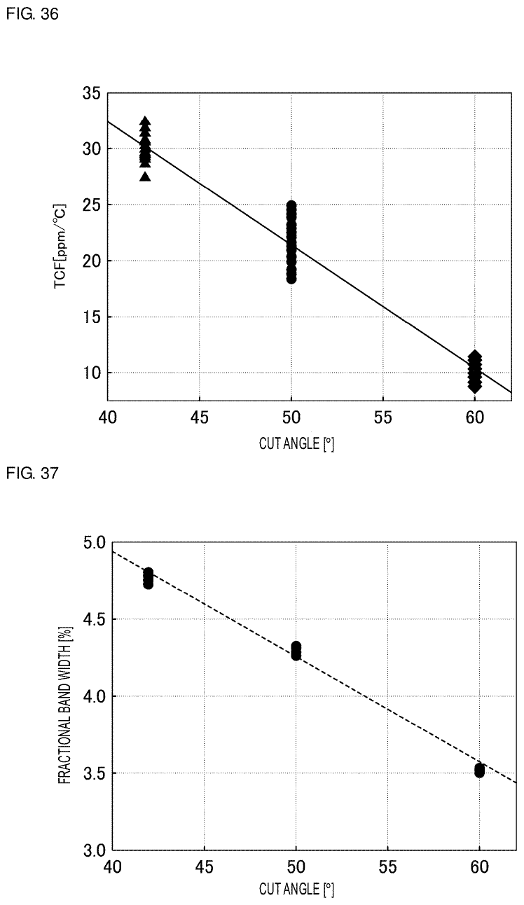

For the first acoustic wave resonator 3An, the surface 41A of the high acoustic velocity member 4A including the silicon substrate is a (111) plane. The thicknesses of the low acoustic velocity film 5A, the piezoelectric layer 6A, and the interdigital transducer electrode 7A are normalized by λ that is the wave length of acoustic waves, which is determined by the electrode finger pitch of the interdigital transducer electrode 7A. In the first acoustic wave resonator 3An, λ is about 2.00 μm, for example. FIG. 35 shows the relationship between a cut angle and an electromechanical coupling coefficient when, in an acoustic wave resonator of a sixth reference example, having similar features, components, and elements as the first acoustic wave resonator 3An, the thickness of the interdigital transducer electrode made of aluminum is about 0.07λ, the thickness of the piezoelectric layer made of Γ° Y-cut X-propagation LiTaO₃ piezoelectric monocrystal is about 0.3λ, the thickness of the low acoustic velocity film made of silicon oxide is about 0.35λ, and the cut angle θ is changed in the range from about 40° to about 90°. In FIG. 35, the alternate long and short dashed line represents the relationship between a cut angle and an electromechanical coupling coefficient when SH waves are used as a main mode, and the dashed line represents the relationship between a cut angle and an electromechanical coupling coefficient when SV waves are used as a main mode. FIG. 36 shows the relationship between a cut angle and a TCF in the acoustic wave resonator of the sixth reference example. FIG. 37 shows the relationship between a cut angle and a fractional band width in the acoustic wave resonator of the sixth reference example.

It is found from FIG. 35 that, in the acoustic wave resonator of the sixth reference example, the electromechanical coupling coefficient for SH waves as a main mode tends to reduce as the cut angle increases and the electromechanical coupling coefficient for SV waves as a main mode tends to increase as the cut angle increases. This tendency also applies to the case where the surface closer to the piezoelectric layer in the silicon substrate included in the high acoustic velocity member is a (110) plane or a (100) plane. From the viewpoint of increasing the electromechanical coupling coefficient of the acoustic wave resonator of the sixth reference example, the cut angle is preferably decreased.

In addition, it is found from FIG. 36 that, in the acoustic wave resonator of the sixth reference example, the absolute value of TCF tends to decrease as the cut angle increases. This tendency also applies to the case where the surface closer to the piezoelectric layer in the silicon substrate included in the high acoustic velocity member is a (110) plane or a (100) plane. From the viewpoint of reducing the TCF of the acoustic wave resonator of the sixth reference example, the cut angle is preferably increased.

In addition, it is found from FIG. 37 that, in the acoustic wave resonator of the sixth reference example, the fractional band width tends to narrow as the cut angle increases. This tendency also applies to the case where the surface closer to the piezoelectric layer in the silicon substrate included in the high acoustic velocity member is a (110) plane or a (100) plane. From the viewpoint of expanding the fractional band width of the acoustic wave resonator of the sixth reference example, the cut angle is preferably decreased.

With the acoustic wave device according to the sixth preferred embodiment, the antenna end resonator is the first acoustic wave resonator 3An, and the surface 41A closer to the piezoelectric layer 6A in the silicon substrate included in the high acoustic velocity member 4A of the first acoustic wave resonator 3An is a (111) plane or a (110) plane, so higher modes are significantly reduced or prevented. In addition, with the acoustic wave device according to the sixth preferred embodiment, of the plurality of acoustic wave resonators 31 to 39 (see FIG. 1), at least one acoustic wave resonator 33 to 39 other than the antenna end resonator is the second acoustic wave resonator 3Bn, and the surface 41B closer to the piezoelectric layer 6B in the silicon substrate included in the high acoustic velocity member 4B of the second acoustic wave resonator 3Bn is a (100) plane, so characteristic degradation is significantly reduced or prevented.

In addition, with the acoustic wave device according to the sixth preferred embodiment, the cut angle θ_{A} of the piezoelectric layer 6A of the first acoustic wave resonator 3An is greater than the cut angle θ_{B} of the piezoelectric layer 6B of the second acoustic wave resonator 3Bn, so the absolute value of TCF of the first acoustic wave resonator 3An is lower than the absolute value of TCF of the second acoustic wave resonator 3Bn. Thus, with the acoustic wave device according to the sixth preferred embodiment, fluctuations in the frequency of higher modes, resulting from a temperature change, are significantly reduced or prevented. In the acoustic wave device according to the sixth preferred embodiment, the cut angle θ_{B} of the piezoelectric layer 6B of the second acoustic wave resonator 3Bn is greater than the cut angle θ_{A} of the piezoelectric layer 6A of the first acoustic wave resonator 3An. Thus, with the acoustic wave device according to the sixth preferred embodiment, as compared to the case where all the acoustic wave resonators 31 to 39 are the first acoustic wave resonators 3An, a decrease in the characteristics of the electromechanical coupling coefficient and fractional band width are significantly reduced or prevented.

In the acoustic wave device according to the sixth preferred embodiment, in each of the first acoustic wave resonator 3An and the second acoustic wave resonator 3Bn, Rayleigh waves occur at frequencies lower than the pass band. Accordingly, in the acoustic wave device according to the sixth preferred embodiment, for the first acoustic wave resonator 3An, where the wave length of acoustic waves, which is determined by the electrode finger pitch of the interdigital transducer electrode 7A, is λ [μm], the thickness of the interdigital transducer electrode 7A is T_{IDT} [μm], the specific gravity of the interdigital transducer electrode 7A is ρ [g/cm³], a duty ratio that is a value determined by dividing the width W_{A} of each electrode finger by a value (W_{A}+S_{A}) half the electrode finger pitch is Dᵤ, the thickness of the piezoelectric layer 6A is T_{LT} [μm], and the thickness of the low acoustic velocity film 5A is T_{VL} [μm], the cut angle θ_{A} of the piezoelectric layer 6A of the first acoustic wave resonator 3An is preferably, for example, within the range of about ±4° from θ₀[° ] determined by the following expression (1).

$$\begin{matrix}[ Expression 1 ] & \\ {θ}_{B} = 43.09 - 27.5 \times ( \frac{{ }_{{T}_{IDT}}}{λ} \times ρ - 0.19 \; 56 ) - 19.2 \times ( {D}_{u} - 0 .5 ) + 17.4578 \times ( \frac{{T}_{LT}}{λ} - 0.35 ) + 5.619 \times ( \frac{{T}_{V L}}{λ} - 0 .3 ) + 32.66 \times \{ {( \frac{{T}_{LT}}{λ} - 0.35 )}^{2} - 0.01 \; 25 \} + 24.63 \times ( \frac{{T}_{L T}}{λ} - 0.35 ) \times ( \frac{{T}_{VL}}{λ} - 0.3 ) & ( 1 )\end{matrix}$$

A piezoelectric substrate having a specific cut angle may significantly reduce or prevent spurious. On the other hand, in the filter 11, the thickness T_{IDT} of the interdigital transducer electrode 7A, the duty ratio Dᵤ, the thickness T_{LT} of the piezoelectric layer 6A, and the thickness T_{VL} of the low acoustic velocity film 5A, which define the first acoustic wave resonator 3A, are preferably selected according to predetermined filter characteristics. The inventors of preferred embodiments of the present invention determined that, for the first acoustic wave resonator 3An including Γ° Y-cut X-propagation LiTaO₃ piezoelectric monocrystal, a cut angle at which the response of Rayleigh waves that occur at frequencies lower than the pass band is significantly reduced or prevented is not uniquely determined and varies according to λ, T_{IDT}, ρ, Dᵤ, T_{LT}, and T_{VL} and is defined by the expression (1).

Thus, by determining the cut angle of the piezoelectric layer 6A according to the structural parameters of the interdigital transducer electrode 7A and the piezoelectric layer 6A, spurious in a stop band that is at frequencies lower than the pass band is reduced or prevented.

In deriving the expression (1), the inventors of preferred embodiments of the present invention determined, for the relationship between each structural parameter and the cut angle of the piezoelectric layer 6A, a change in cut angle at which the spurious of Rayleigh waves is minimum when the normalized film thickness (T_{IDT}/λ), the duty ratio Dᵤ, the normalized thickness (T_{LT}/λ), and the normalized film thickness (T_{VL}/λ) are changed by performing simulation with a finite element method.

As a result, as the normalized film thickness (T_{IDT}/λ) increases, the cut angle reduces. As the duty ratio Dᵤ increases, the cut angle reduces. As the normalized thickness (T_{LT}/λ) increases, the cut angle increases. As the normalized film thickness (T_{VL}/λ) increases, the cut angle increases.

With the acoustic wave device according to the sixth preferred embodiment, the cut angle θ_{A} of the piezoelectric layer 6A of the first acoustic wave resonator 3An falls within the range of about θ₀±4°, so the response intensity of Rayleigh waves is reduced.

### Seventh Preferred Embodiment

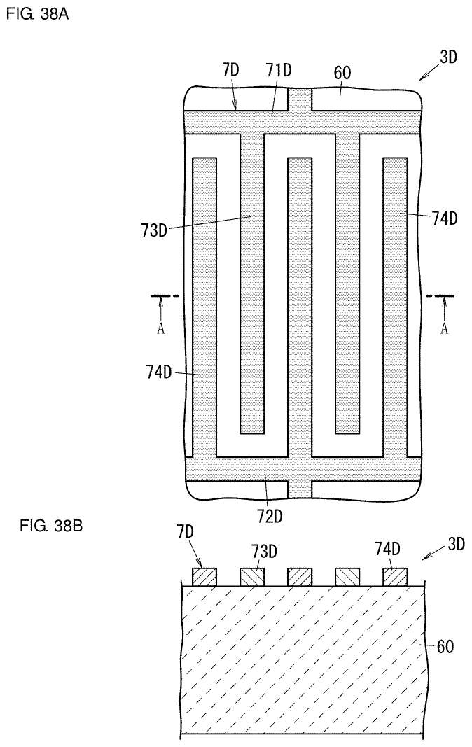

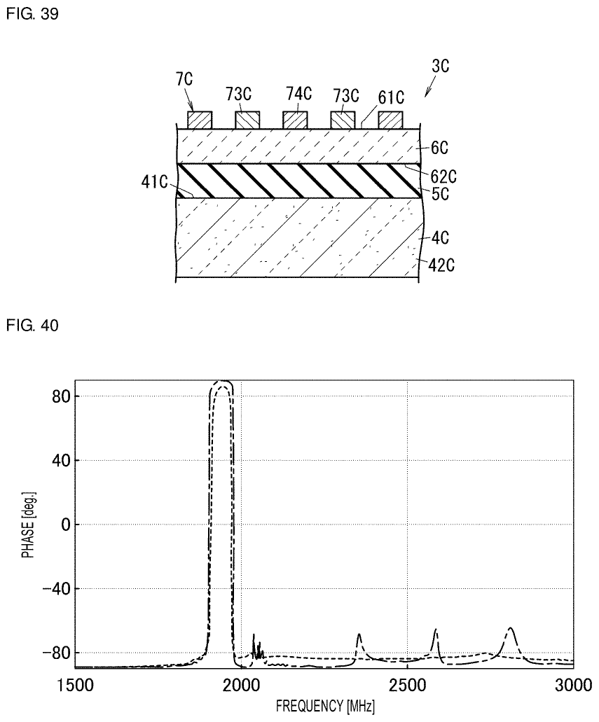

The circuitry of an acoustic wave device according to a seventh preferred embodiment of the present invention is the same as or similar to the circuitry of the acoustic wave device 1 according to the first preferred embodiment, so the drawings and description thereof are omitted. The acoustic wave device according to the seventh preferred embodiment includes a SAW (surface acoustic wave) resonator 3D as shown in FIGS. 38A and 38B instead of the first acoustic wave resonator 3A of the acoustic wave device 1 according to the first preferred embodiment and includes a third acoustic wave resonator 3C as shown in FIG. 39 instead of the second acoustic wave resonator 3B. As for the acoustic wave device according to the seventh preferred embodiment, like reference numerals denote similar components to those of the acoustic wave device 1 according to the first preferred embodiment, and the description thereof is omitted.

The SAW resonator 3D includes a piezoelectric substrate 60, and an interdigital transducer electrode 7D provided on or above the piezoelectric substrate 60.

The piezoelectric substrate 60 is preferably, for example, a 50° Y-cut X-propagation LiTaO₃ substrate. The cut angle of the piezoelectric substrate 60 is not limited to about 50° and may be another value. The piezoelectric substrate is not limited to the LiTaO₃ substrate and may be, for example, a LiNbO₃ substrate. The LiNbO₃ substrate is, for example, a 128° Y-cut X-propagation LiNbO₃ substrate.

The interdigital transducer electrode 7D has similar features, components, and elements as the interdigital transducer electrode 7A (see FIG. 4A and FIG. 4B) of the first acoustic wave resonator 3A of the acoustic wave device 1 according to the first preferred embodiment. In other words, the interdigital transducer electrode 7D includes a first busbar 71D, a second busbar 72D, a plurality of first electrode fingers 73D, and a plurality of second electrode fingers 74D respectively similar to the first busbar 71A, the second busbar 72A, the plurality of first electrode fingers 73A, and the plurality of second electrode fingers 74A of the interdigital transducer electrode 7A.

The third acoustic wave resonator 3C has similar features, components, and elements as the first acoustic wave resonator 3A and the second acoustic wave resonator 3B. More specifically, the third acoustic wave resonator 3C includes a piezoelectric layer 6C, an interdigital transducer electrode 7C, and a high acoustic velocity member 4C. The interdigital transducer electrode 7C is provided on or above the piezoelectric layer 6C. The interdigital transducer electrode 7C has similar features, components, and elements as the interdigital transducer electrode 7A (see FIGS. 4A and 4B) of the first acoustic wave resonator 3A of the acoustic wave device 1 according to the first preferred embodiment. In other words, the interdigital transducer electrode 7C includes a first busbar 71C, a second busbar 72C, a plurality of first electrode fingers 73C, and a plurality of second electrode fingers 74C respectively similar to the first busbar 71A, the second busbar 72A, the plurality of first electrode fingers 73A, and the plurality of second electrode fingers 74A of the interdigital transducer electrode 7A. The high acoustic velocity member 4C is located across the piezoelectric layer 6C from the interdigital transducer electrode 7C. The piezoelectric layer 6C has a first main surface 61C closer to the interdigital transducer electrode 7C and a second main surface 62C closer to the high acoustic velocity member 4C. Bulk waves propagate through the high acoustic velocity member 4C at an acoustic velocity higher than acoustic waves propagate through the piezoelectric layer 6C.

The third acoustic wave resonator 3C further includes a low acoustic velocity film 5C. The low acoustic velocity film 5C is provided between the high acoustic velocity member 4C and the piezoelectric layer 6C. Bulk waves propagate through the low acoustic velocity film 5C at an acoustic velocity lower than bulk waves propagate through the piezoelectric layer 6C. The high acoustic velocity member 4C is a high acoustic velocity support substrate 42C. The high acoustic velocity support substrate 42C supports the low acoustic velocity film 5C, the piezoelectric layer 6C, and the interdigital transducer electrode 7C. Bulk waves propagate through the high acoustic velocity support substrate 42C at an acoustic velocity higher than acoustic waves propagate through the piezoelectric layer 6C. The third acoustic wave resonator 3C is a one-port acoustic wave resonator including a reflector (for example, a short-circuited grating) at each side in an acoustic wave propagation direction of the interdigital transducer electrode 7C. However, the reflectors are not indispensable. The third acoustic wave resonator 3C is not limited to a one-port acoustic wave resonator and may be, for example, a longitudinally coupled acoustic wave resonator.

The piezoelectric layer 6C is preferably, for example, Γ° Y-cut X-propagation LiTaO₃ piezoelectric monocrystal (for example, 50° Y-cut X-propagation LiTaO₃ piezoelectric monocrystal).

In the third acoustic wave resonator 3C, there are modes of longitudinal wave, SH wave, SV wave, or a combination of some of these waves as modes of acoustic waves that propagate through the piezoelectric layer 6C. In the third acoustic wave resonator 3C, a mode having an SH wave as a main component is used as a main mode.

The dashed line in FIG. 40 represents the frequency characteristics of the phase of the impedance of the SAW resonator 3D. The alternate long and short dashed line in FIG. 40 represents the frequency characteristics of the phase of the impedance of the third acoustic wave resonator 3C. Here, in the SAW resonator 3D, the thickness of the interdigital transducer electrode 7D is normalized by λ that is the wave length of acoustic waves, which is determined by the electrode finger pitch of the interdigital transducer electrode 7D. In the third acoustic wave resonator 3C, λ is about 2 μm, for example. In the SAW resonator 3D, for example, the thickness of the piezoelectric substrate 60 made of 42° Y-cut X-propagation LiTaO₃ piezoelectric monocrystal is about 120 μm, the thickness of the interdigital transducer electrode 7C made of aluminum is about 0.08λ, and the duty ratio is about 0.5. For the third acoustic wave resonator 3C, a surface 41C closer to the piezoelectric layer 6C in the silicon substrate included in the high acoustic velocity member 4C including the silicon substrate is a (100) plane. The thicknesses of the low acoustic velocity film 5C, the piezoelectric layer 6C, and the interdigital transducer electrode 7C are normalized by λ that is the wave length of acoustic waves, which is determined by the electrode finger pitch of the interdigital transducer electrode 7C. In the third acoustic wave resonator 3C, λ is about 2 μm, for example. In the third acoustic wave resonator 3C, for example, the thickness of the low acoustic velocity film made of silicon oxide is about 0.35λ, the thickness of the piezoelectric layer 6C made of 50° Y-cut X-propagation LiTaO₃ piezoelectric monocrystal is about 0.3λ, the thickness of the interdigital transducer electrode 7C made of aluminum is about 0.08λ, and the duty ratio is about 0.5.

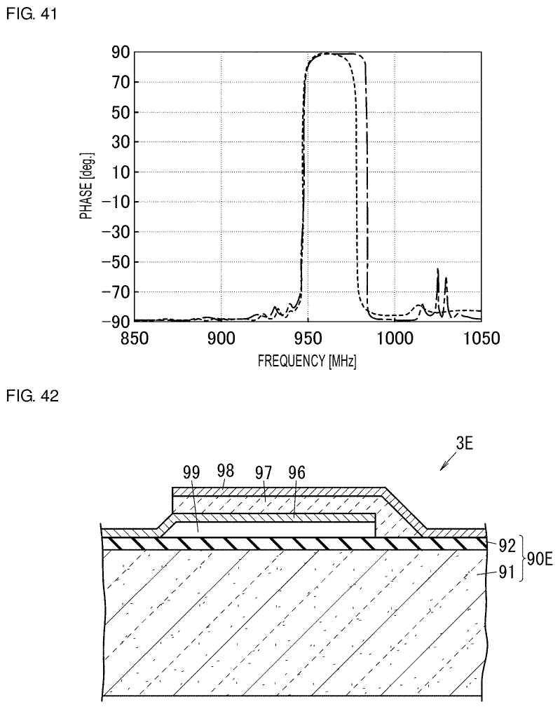

From FIG. 40, in the third acoustic wave resonator 3C, in the phase characteristics of impedance, a stop band ripple occurs on maximum frequency side of the pass band. In the example of FIG. 40, the pass band includes about 1950 MHz, and the stop band ripple is occurring at about 2050 MHz. In contrast, in the SAW resonator 3D, in the phase characteristics of impedance, no ripple is occurring at about 2050 MHz. However, in the SAW resonator 3D, the characteristics of the pass band are decreased as compared to the third acoustic wave resonator 3C. These tendencies also apply to the case where, as shown in FIG. 41, a pass band is at frequencies lower than that in the case of FIG. 40. The dashed line in FIG. 41 represents the frequency characteristics of the phase of the impedance of the SAW resonator 3D. The alternate long and short dashed line in FIG. 41 represents the frequency characteristics of the phase of the impedance of the third acoustic wave resonator 3C. In the example of FIG. 41, the pass band includes about 970 MHz, and the stop band ripple is occurring at about 1030 MHz.

The acoustic wave device according to the seventh preferred embodiment, as well as the acoustic wave device 1 according to the first preferred embodiment (see FIG. 1 to FIG. 5B), is provided between the first terminal 101 defining and functioning as the antenna terminal and the second terminal 102 different from the first terminal 101. The acoustic wave device 1 includes the plurality of acoustic wave resonators 31 to 39. The plurality of acoustic wave resonators 31 to 39 include the plurality of series arm resonators (acoustic wave resonators 31, 33, 35, 37, 39) provided in the first path r1 connecting the first terminal 101 and the second terminal 102 and the plurality of parallel arm resonators (acoustic wave resonators 32, 34, 36, 38) provided in the plurality of second paths r21, r22, r23, r24 respectively connecting the plurality of nodes N1, N2, N3, N4 in the first path r1 to the ground. Where, of the plurality of acoustic wave resonators 31 to 39, the acoustic wave resonator electrically closest to the first terminal 101 is the antenna end resonator, the antenna end resonator is the SAW resonator 3D, and, of the plurality of acoustic wave resonators 31 to 39, at least one acoustic wave resonator 33 to 39 other than the antenna end resonator is the third acoustic wave resonator 3C. The SAW resonator 3D includes the piezoelectric substrate 60, and the interdigital transducer electrode 7D provided on or above the piezoelectric substrate 60 and including the plurality of first electrode fingers (the plurality of first electrode fingers 73D and the plurality of second electrode fingers 74D). The third acoustic wave resonator 3C includes the piezoelectric layer 6C, the interdigital transducer electrode 7C including the plurality of electrode fingers (the plurality of first electrode fingers 73C and the plurality of second electrode fingers 74C), and the high acoustic velocity member 4C. The interdigital transducer electrode 7C of the third acoustic wave resonator 3C is provided on or above the piezoelectric layer 6C. The high acoustic velocity member 4C is located across the piezoelectric layer 6C from the interdigital transducer electrode 7C. Bulk waves propagate through the high acoustic velocity member 4C at an acoustic velocity higher than acoustic waves propagate through the piezoelectric layer 6C. In the third acoustic wave resonator 3C, the thickness of the piezoelectric layer 6C is, for example, less than or equal to about 3.5λ where the wave length of acoustic waves, which is determined by the electrode finger pitch of the interdigital transducer electrode 7C, is λ. In the acoustic wave device, when the antenna end resonator is the SAW resonator 3D, at least one acoustic wave resonator 33 to 39 other than the antenna end resonator of the plurality of acoustic wave resonators 31 to 39 is the third acoustic wave resonator 3C.

With the acoustic wave device according to the seventh preferred embodiment, when the antenna end resonator is the SAW resonator 3D, at least one acoustic wave resonator 33 to 39 other than the antenna end resonator of the plurality of acoustic wave resonators 31 to 39 is the third acoustic wave resonator 3C, so higher modes are significantly reduced or prevented while a decrease in reflection characteristics and bandpass characteristics is significantly reduced or prevented.

### First Modification of Seventh Preferred Embodiment

An acoustic wave device according to a first modification of the seventh preferred embodiment differs from the acoustic wave device according to the seventh preferred embodiment in that a BAW (bulk acoustic wave) resonator as shown in FIG. 42 is provided instead of the SAW resonator 3D of the acoustic wave device according to the seventh preferred embodiment. As for the acoustic wave device according to the first modification of the seventh preferred embodiment, like reference numerals denote the same or similar components to those of the acoustic wave device according to the seventh preferred embodiment, and the description thereof is omitted.

The BAW resonator 3E includes a first electrode 96, a piezoelectric film 97, and a second electrode 98. The piezoelectric film 97 is provided on or above the first electrode 96. The second electrode 98 is provided on or above the piezoelectric film 97.

The BAW resonator 3E further includes a support 90E. The support 90E supports the first electrode 96, the piezoelectric film 97, and the second electrode 98. The support 90E includes a support substrate 91, and an electrically insulating film 92 provided on or above the support substrate 91. The support substrate 91 is preferably, for example, a silicon substrate. The electrically insulating film 92 is preferably, for example, a silicon oxide film. The piezoelectric film 97 is preferably made of, for example, PZT (lead zirconate titanate).

The BAW resonator 3E includes a cavity 99 on a side away from the piezoelectric film 97 in the first electrode 96. The BAW resonator 3E is able to significantly reduce or prevent propagation of acoustic wave energy toward the support 90E by increasing an acoustic impedance ratio between the first electrode 96 and a medium just below the first electrode 96 and is able to increase the electromechanical coupling coefficient as compared to when no cavity 99 is provided. The BAW resonator 3E is an FBAR (film bulk acoustic resonator). The structure of the BAW resonator 3E that defines the FBAR is an example and is not limited.

In the BAW resonator 3E, as well as the SAW resonator 3D, in the phase characteristics of impedance, no stop band ripple occurs at frequencies higher than the pass band. In addition, in the BAW resonator 3E, as well as the SAW resonator 3D, the characteristics of the pass band decrease as compared to the third acoustic wave resonator 3C.

The acoustic wave device according to the first modification of the seventh preferred embodiment, as well as the acoustic wave device 1 according to the first preferred embodiment (see FIG. 1 to FIG. 5B), is provided between the first terminal 101 defining and functioning as the antenna terminal and the second terminal 102 different from the first terminal 101. The acoustic wave device 1 includes the plurality of acoustic wave resonators 31 to 39. The plurality of acoustic wave resonators 31 to 39 includes the plurality of series arm resonators (acoustic wave resonators 31, 33, 35, 37, 39) provided in the first path r1 connecting the first terminal 101 and the second terminal 102 and the plurality of parallel arm resonators (acoustic wave resonators 32, 34, 36, 38) provided in the plurality of second paths r21, r22, r23, r24 respectively connecting the plurality of nodes N1, N2, N3, N4 in the first path r1 to the ground. Where, of the plurality of acoustic wave resonators 31 to 39, the acoustic wave resonator electrically closest to the first terminal 101 is the antenna end resonator, the antenna end resonator is the BAW resonator 3E, and, of the plurality of acoustic wave resonators 31 to 39, at least one acoustic wave resonator other than the antenna end resonator is the third acoustic wave resonator 3C. The BAW resonator 3E includes the first electrode 96, the piezoelectric film 97 provided on or above the first electrode 96, and the second electrode 98 provided on or above the piezoelectric film 97. The third acoustic wave resonator 3C includes the piezoelectric layer 6C, the interdigital transducer electrode 7C having the plurality of electrode fingers (the plurality of first electrode fingers 73C and the plurality of second electrode fingers 74C), and the high acoustic velocity member 4C. The interdigital transducer electrode 7C of the third acoustic wave resonator 3C is provided on or above the piezoelectric layer 6C. The high acoustic velocity member 4C is located across the piezoelectric layer 6C from the interdigital transducer electrode 7C. Bulk waves propagate through the high acoustic velocity member 4C at an acoustic velocity higher than acoustic waves propagate through the piezoelectric layer 6C. In the third acoustic wave resonator 3C, the thickness of the piezoelectric layer 6C is, for example, less than or equal to about 3.5λ where the wave length of acoustic waves, which is determined by the electrode finger pitch of the interdigital transducer electrode 7C, is λ. In the acoustic wave device, when the antenna end resonator is the BAW resonator 3E, at least one acoustic wave resonator 33 to 39 other than the antenna end resonator of the plurality of acoustic wave resonators 31 to 39 is the third acoustic wave resonator 3C.

With the acoustic wave device according to the first modification of the seventh preferred embodiment, when the antenna end resonator is the BAW resonator 3E, at least one acoustic wave resonator 33 to 39 other than the antenna end resonator of the plurality of acoustic wave resonators 31 to 39 is the third acoustic wave resonator 3C, so higher modes are significantly reduced or prevented while a decrease in reflection characteristics and bandpass characteristics is significantly reduced or prevented.

### Second Modification of Seventh Preferred Embodiment

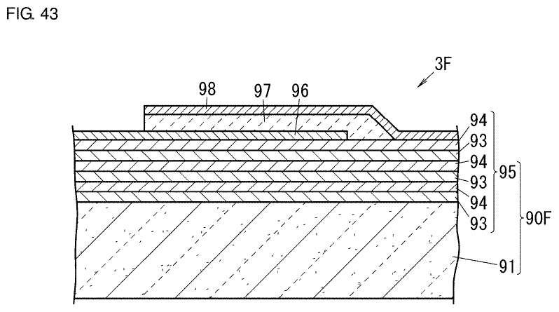

An acoustic wave device according to a second modification of the seventh preferred embodiment includes a BAW resonator 3F as shown in FIG. 43 instead of the BAW resonator 3E of the acoustic wave device according to the first modification of the seventh preferred embodiment.

The BAW resonator 3F includes the first electrode 96, the piezoelectric film 97, and the second electrode 98. The piezoelectric film 97 is provided on or above the first electrode 96. The second electrode 98 is provided on or above the piezoelectric film 97.

The BAW resonator 3F further includes a support 90F. The support 90F supports the first electrode 96, the piezoelectric film 97, and the second electrode 98. The support 90F includes the support substrate 91, and an acoustic multilayer film 95 provided on or above the support substrate 91. The acoustic multilayer film 95 reflects bulk acoustic waves generated in the piezoelectric film 97. The acoustic multilayer film 95 has a structure including a plurality of high acoustic impedance layers 93 having a relatively high acoustic impedance and a plurality of low acoustic impedance layers 94 having a relatively low acoustic impedance that are alternately provided one by one in the thickness direction of the support substrate 91. The material of the high acoustic impedance layers 93 is preferably, for example, Pt. The material of the low acoustic impedance layers 94 is preferably, for example, silicon oxide. The support substrate 91 is preferably, for example, a silicon substrate. The piezoelectric film 97 is preferably made of, for example, PZT.

The BAW resonator 3F has the acoustic multilayer film 95 on a side away from the piezoelectric film 97 in the first electrode 96. The BAW resonator 3F is preferably an SMR (solidly mounted resonator). The structure of the BAW resonator 3F that defines the SMR is an example and is not limited.

In the BAW resonator 3F, as well as the SAW resonator 3D, in the phase characteristics of impedance, no stop band ripple occurs at frequencies higher than the pass band. In addition, in the BAW resonator 3F, as well as the SAW resonator 3D, the reflection characteristics of the stop band decrease as compared to the third acoustic wave resonator 3C.

With the acoustic wave device according to the second modification of the seventh preferred embodiment, when the antenna end resonator is the BAW resonator 3F, at least one acoustic wave resonator 33 to 39 other than the antenna end resonator of the plurality of acoustic wave resonators 31 to 39 is the third acoustic wave resonator 3C, so higher modes are significantly reduced or prevented while a decrease in reflection characteristics and bandpass characteristics is significantly reduced or prevented.

The above-described first to seventh preferred embodiments, and the like each are just one of various preferred embodiments of the present invention. The above-described first to seventh preferred embodiments, and the like each may be modified into various forms according to design, or the like.

From the above-described first to seventh preferred embodiments, and the like, the following features and elements are provided.

An acoustic wave device (1; 1c; 1g) according to a preferred embodiment of the present invention is provided between a first terminal (101) defining and functioning as an antenna terminal and a second terminal (102) different from the first terminal (101). The acoustic wave device (1; 1c; 1g) includes a plurality of acoustic wave resonators (31 to 39). The plurality of acoustic wave resonators (31 to 39) include a plurality of series arm resonators (acoustic wave resonators 31, 33, 35, 37, 39) provided in a first path (r1) connecting the first terminal (101) and the second terminal (102) and a plurality of parallel arm resonators (acoustic wave resonators 32, 34, 36, 38) provided in a plurality of second paths respectively connecting a plurality of nodes (N1, N2, N3, N4) in the first path (r1) to a ground. Where, of the plurality of acoustic wave resonators (31 to 39), the acoustic wave resonator electrically closest to the first terminal (101) is an antenna end resonator, the antenna end resonator is a first acoustic wave resonator (3A; 3Aa to 3An), a SAW resonator (3D), or a BAW resonator (3E; 3F) and, of the plurality of acoustic wave resonators (31 to 39), at least one acoustic wave resonator other than the antenna end resonator is a second acoustic wave resonator (3B; 3Ba to 3Bn) or a third acoustic wave resonator (3C). Where the antenna end resonator is the first acoustic wave resonator (3A; 3Aa to 3An), the at least one acoustic wave resonator is the second acoustic wave resonator (3B; 3Ba to 3Bn). Where the antenna end resonator is the SAW resonator (3D) or the BAW resonator (3E; 3F), the at least one acoustic wave resonator other than the antenna end resonator of the plurality of acoustic wave resonators (31 to 39) is the third acoustic wave resonator (3C). The SAW resonator (3D) includes a piezoelectric substrate (60), and an interdigital transducer electrode (7D) including a plurality of electrode fingers (a plurality of first electrode fingers 73D and a plurality of second electrode fingers 74D). The interdigital transducer electrode (7D) is provided on or above the piezoelectric substrate (60). Each of the first acoustic wave resonator (3A; 3Aa to 3An), the second acoustic wave resonator (3B; 3Ba to 3Bn), and the third acoustic wave resonator (3C) includes a piezoelectric layer (6A, 6B, 6C), an interdigital transducer electrode (7A, 7B, 7C) including a plurality of electrode fingers (a plurality of first electrode fingers 73A, 73B, 73C and a plurality of second electrode fingers 74A, 74B, 74C), and a high acoustic velocity member (4A, 4B, 4C). The interdigital transducer electrode (7A, 7B, 7C) of each of the first acoustic wave resonator (3A; 3Aa to 3An), the second acoustic wave resonator (3B; 3Ba to 3Bn), and the third acoustic wave resonator (3C) is provided on or above the piezoelectric layer (6A, 6B, 6C). The high acoustic velocity member (4A, 4B, 4C) is located across the piezoelectric layer (6A, 6B, 6C) from the interdigital transducer electrode (7A, 7B, 7C). Bulk waves propagate through the high acoustic velocity member (4A, 4B, 4C) at an acoustic velocity higher than acoustic waves propagate through the piezoelectric layer (6A, 6B, 6C). In each of the first acoustic wave resonator (3A; 3Aa to 3An), the second acoustic wave resonator (3B; 3Ba to 3Bn), and the third acoustic wave resonator (3C), a thickness of the piezoelectric layer (6A, 6B, 6C) is less than or substantially equal to about 3.5λ where a wave length of acoustic waves, which is determined by an electrode finger pitch of the interdigital transducer electrode (7A, 7B, 7C), is λ. Where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies at least one of a first condition, a second condition, and a third condition. The first condition is a condition that the high acoustic velocity members (4A, 4B) of the first acoustic wave resonator (3A; 3Aa to 3An) and the second acoustic wave resonator (3B; 3Ba to 3Bn) each include a silicon substrate, a surface (41A) closer to the piezoelectric layer (6A) in the silicon substrate of the first acoustic wave resonator (3A; 3Aa to 3An) is a (111) plane or a (110) plane, and a surface (41B) closer to the piezoelectric layer (6B) in the silicon substrate of the second acoustic wave resonator (3B; 3Ba to 3Bn) is a (100) plane. The second condition is a condition that the piezoelectric layer (6A) of the first acoustic wave resonator (3A; 3Aa to 3An) is thinner than the piezoelectric layer (6B) of the second acoustic wave resonator (3B; 3Ba to 3Bn). The third condition is a condition that each of the first acoustic wave resonator (3A; 3Aa to 3An) and the second acoustic wave resonator (3B; 3Ba to 3Bn) includes a low acoustic velocity film (5A, 5B) and the low acoustic velocity film (5A) of the first acoustic wave resonator (3A; 3Aa to 3An) is thinner than the low acoustic velocity film (5B) of the second acoustic wave resonator (3B; 3Ba to 3Bn). The low acoustic velocity film (5A, 5B) is provided between the high acoustic velocity member (4A, 4B) and the piezoelectric layer (6A, 6B). Bulk waves propagate through the low acoustic velocity film (5A, 6B) at an acoustic velocity lower than bulk waves propagate through the piezoelectric layer (6A, 6B).

With the acoustic wave device (1; 1c; 1g) according to the above-described preferred embodiment, higher modes are significantly reduced or prevented.

In an acoustic wave device (1; 1c; 1g) according to a preferred embodiment of the present invention, the BAW resonator (3E; 3F) includes a first electrode (96), a piezoelectric film (97), and a second electrode (98). The piezoelectric film (97) is provided on or above the first electrode (96). The second electrode (98) is provided on or above the piezoelectric film (97).

In an acoustic wave device (1; 1c; 1g) according to a preferred embodiment of the present invention, where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies a fourth condition. The fourth condition is a condition that a mass per unit length in an electrode finger longitudinal direction of each of the electrode fingers of the interdigital transducer electrode (7A) of the first acoustic wave resonator (3A; 3Aa to 3An) is greater than a mass per unit length in an electrode finger longitudinal direction of each of the electrode fingers of the interdigital transducer electrode (7B) of the second acoustic wave resonator (3B; 3Ba to 3Bn).

With the acoustic wave device (1; 1c; 1g) according to the above-described preferred embodiment, an electromechanical coupling coefficient is increased, and a stop band ripple is significantly reduced or prevented.

In an acoustic wave device (1; 1c; 1g) according to a preferred embodiment of the present invention, where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies a fourth condition. The fourth condition is a condition that a mass per unit length in an electrode finger longitudinal direction of each of the electrode fingers of the interdigital transducer electrode (7A) of the first acoustic wave resonator (3A; 3Aa to 3An) is less than the mass per unit length in an electrode finger longitudinal direction of each of the electrode fingers of the interdigital transducer electrode (7B) of the second acoustic wave resonator (3B; 3Ba to 3Bn).

With the acoustic wave device (1; 1c; 1g) according to the above-described preferred embodiment, the TCF of the first acoustic wave resonator (3A; 3Aa to 3An) is lower than the TCF of the second acoustic wave resonator (3B; 3Ba to 3Bn).

In an acoustic wave device (1; 1c; 1g) according to a preferred embodiment of the present invention, where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies at least one of the first condition and the second condition. Of the first acoustic wave resonator (3A; 3Aa to 3An) and the second acoustic wave resonator (3B; 3Ba to 3Bn), only the first acoustic wave resonator (3A; 3Aa to 3An) includes the low acoustic velocity film (5A). The low acoustic velocity film (5A) is provided between the high acoustic velocity member (4A) and the piezoelectric layer (6A). Bulk waves propagate through the low acoustic velocity film (5A) at an acoustic velocity lower than bulk waves propagate through the piezoelectric layer (6A).

With the acoustic wave device (1; 1c; 1g) according to the above-described preferred embodiment, both an expansion of fractional band width resulting from an increase in electromechanical coupling coefficient and significant improvement in frequency-temperature characteristics are able to be provided.

In an acoustic wave device (1; 1c; 1g) according to a preferred embodiment of the present invention, where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies at least one of the first condition and the second condition. Of the first acoustic wave resonator (3A; 3Aa to 3An) and the second acoustic wave resonator (3B; 3Ba to 3Bn), only the second acoustic wave resonator (3B; 3Ba to 3Bn) includes the low acoustic velocity film (5B). The low acoustic velocity film (5B) is provided between the high acoustic velocity member (4B) and the piezoelectric layer (6B). Bulk waves propagate through the low acoustic velocity film (5B) at an acoustic velocity lower than bulk waves propagate through the piezoelectric layer (6B).

With the acoustic wave device (1; 1c; 1g) according to the above-described preferred embodiment, higher modes that occur in the first acoustic wave resonator (3A; 3Aa to 3An) are further significantly reduced or prevented.

In an acoustic wave device (1; 1c; 1g) according to a preferred embodiment of the present invention, a material of the piezoelectric layer (6A, 6B, 6C) is lithium tantalate or lithium niobate. A material of the low acoustic velocity film (5A, 5B, 5C) is silicon oxide. A material of the high acoustic velocity member (4A, 4B, 4C) is silicon.

With the acoustic wave device (1; 1c; 1g) according to the above-described preferred embodiment, a loss is reduced, and the quality factor is increased, in comparison with the case where no low acoustic velocity film (5A, 5B, 5C) is provided.

In an acoustic wave device (1; 1c; 1g) according to a preferred embodiment of the present invention, the high acoustic velocity member (4A, 4B) includes a high acoustic velocity film (45A, 45B), and a support substrate (44A, 44B) supporting the high acoustic velocity film (45A, 45B). Bulk waves propagate through the high acoustic velocity film (45A, 45B) at an acoustic velocity higher than acoustic waves propagate through the piezoelectric layer (6A, 6B). Each of the first acoustic wave resonator (3A; 3Aa to 3An), the second acoustic wave resonator (3B; 3Ba to 3Bn), and the third acoustic wave resonator (3C) includes the low acoustic velocity film (5A, 5B, 5C) provided on or above the high acoustic velocity film (45A, 45B). Bulk waves propagate through the low acoustic velocity film (5A, 5B, 5C) at an acoustic velocity lower than bulk waves propagate through the piezoelectric layer (6A, 6B, 6C). When the acoustic wave device (1; 1c; 1g) satisfies the first condition, the support substrate (44A, 44B) is the silicon substrate.

With the acoustic wave device (1; 1c; 1g) according to the above-described preferred embodiment, a leak of acoustic waves to the support substrate (44A, 44B) is significantly reduced or prevented.

In an acoustic wave device (1; 1c; 1g) according to a preferred embodiment of the present invention, a material of the piezoelectric layer (6A, 6B, 6C) is lithium tantalate or lithium niobate. A material of the low acoustic velocity film (5A, 5B, 5C) is at least one material selected from a group consisting of silicon oxide, glass, silicon oxynitride, tantalum oxide, and a chemical compound provided by adding fluorine, carbon, or boron to silicon oxide. A material of the high acoustic velocity film (45A, 45B) is at least one material selected from a group consisting of diamond-like carbon, aluminum nitride, aluminum oxide, silicon carbide, silicon nitride, silicon, sapphire, lithium tantalate, lithium niobate, quartz crystal, alumina, zirconia, cordierite, mullite, steatite, forsterite, magnesia, and diamond.

In an acoustic wave device (1; 10; 1g) according to a preferred embodiment of the present invention, each of the first acoustic wave resonator (3A; 3Aa to 3An), the second acoustic wave resonator (3B; 3Ba to 3Bn), and the third acoustic wave resonator (3C) includes the low acoustic velocity film (5A, 5B, 5C). The low acoustic velocity film (5A, 5B, 5C) is provided between the high acoustic velocity member (4A, 4B, 4C) and the piezoelectric layer (6A, 6B, 6C). Bulk waves propagate through the low acoustic velocity film (5A, 5B, 5C) at an acoustic velocity lower than bulk waves propagate through the piezoelectric layer (6A, 6B, 6C). The high acoustic velocity member (4A, 4B, 4C) is a high acoustic velocity support substrate (42A, 42B, 42C). Bulk waves propagate through the high acoustic velocity support substrate (42A, 42B, 42C) at an acoustic velocity higher than acoustic waves propagate through the piezoelectric layer (6A, 6B, 6C).

With the acoustic wave device (1; 1c; 1g) according to the above-described preferred embodiment, a loss is reduced, and the quality factor is increased, in comparison with the case where each of the first acoustic wave resonator (3A; 3Aa to 3An), the second acoustic wave resonator (3B; 3Ba to 3Bn), and the third acoustic wave resonator (3C) does not include the low acoustic velocity film (5A, 5B, 5C).

In an acoustic wave device (1; 1c; 1g) according to a preferred embodiment of the present invention, when the second condition is satisfied, each of the first acoustic wave resonator (3A; 3Aa to 3An) and the second acoustic wave resonator (3B; 3Ba to 3Bn) further includes a dielectric film (8A, 8B) provided between the piezoelectric layer (6A, 6B) and the interdigital transducer electrode (7A, 7B) A thickness of the dielectric film (8A) of the first acoustic wave resonator (3A; 3Aa to 3An) is greater than a thickness of the dielectric film (8B) of the second acoustic wave resonator (3B; 3Ba to 3Bn).

With the acoustic wave device (1; 1c; 1g) according to the above-described preferred embodiment, an excessive increase in the electromechanical coupling coefficient of the first acoustic wave resonator (3A; 3Aa to 3An) is significantly reduced or prevented.

In an acoustic wave device (1; 1c; 1g) according to a preferred embodiment of the present invention, where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies at least one of the first condition and the second condition. Of the first acoustic wave resonator (3A; 3Aa to 3An) and the second acoustic wave resonator (3B; 3Ba to 3Bn), only the first acoustic wave resonator (3A; 3Aa to 3An) further includes a dielectric film (8A) provided between the piezoelectric layer (6A) and the interdigital transducer electrode (7A).

In an acoustic wave device (1; 1c; 1g) according to a preferred embodiment of the present invention, where the antenna end resonator is the first acoustic wave resonator (3A; 3Aa to 3An) and the at least one acoustic wave resonator is the second acoustic wave resonator (3B; 3Ba to 3Bn), the acoustic wave device (1; 1c; 1g) satisfies at least one of the first condition and the second condition. Of the first acoustic wave resonator (3A; 3Aa to 3An) and the second acoustic wave resonator (3B; 3Ba to 3Bn), only the second acoustic wave resonator (3B; 3Ba to 3Bn) further includes a dielectric film (8B) provided between the piezoelectric layer (6B) and the interdigital transducer electrode (7B).

In an acoustic wave device (1; 1c; 1g) according to a preferred embodiment of the present invention, where the antenna end resonator is the first acoustic wave resonator (3A; 3Aa to 3An) and the at least one acoustic wave resonator (32 to 39) is the second acoustic wave resonator (3B; 3Ba to 3Bn), a cut angle (θ_{A}) of the piezoelectric layer (6A) of the first acoustic wave resonator (3A; 3Aa to 3An) is greater than a cut angle (θ_{B}) of the piezoelectric layer (6B) of the second acoustic wave resonator (3B; 3Ba to 3Bn).

With the acoustic wave device (1; 1c; 1g) according to the above-described preferred embodiment, the absolute value of TCF of the first acoustic wave resonator (3An) is lower than the absolute value of TCF of the second acoustic wave resonator (3Bn). Thus, with the acoustic wave device (1; 1c; 1g), fluctuations in the frequency of higher modes, resulting from a temperature change, are significantly reduced or prevented. In addition, with the acoustic wave device (1; 1c; 1g), the cut angle (θ_{B}) of the piezoelectric layer (6B) of the second acoustic wave resonator (3Bn) is less than the cut angle (θ_{A}) of the piezoelectric layer (6A) of the first acoustic wave resonator (3An), so a decrease in the characteristics of the electromechanical coupling coefficient and fractional band width is significantly reduced or prevented in comparison with the case where all the acoustic wave resonators (31 to 39) are the first acoustic wave resonators (3An).

In an acoustic wave device (1; 1c; 1g) according to a preferred embodiment of the present invention, where the antenna end resonator is the first acoustic wave resonator (3A; 3Aa to 3An) and the at least one acoustic wave resonator (33 to 39) is the second acoustic wave resonator (3B; 3Ba to 3Bn), for the first acoustic wave resonator (3A; 3Aa to 3An), the cut angle (θ_{A}) of the piezoelectric layer (6A) falls within a range of about ±4° from θ₀ determined by a following expression (1). The following expression (1) is an expression where the wave length is λ [μm], a thickness of the interdigital transducer electrode (7A) is T_{IDT}[μm], a specific gravity of the interdigital transducer electrode (7A) is ρ [g/cm³], a duty ratio that is a value determined by dividing a width (W_{A}) of each electrode finger by a value (W_{A}+S_{A}) half an electrode finger pitch (cycle period P_{λA}) is Dᵤ, a thickness of the piezoelectric layer (6A) is T_{LT} [μm], and a thickness of the low acoustic velocity film (5A) is T_{VL} [μm].

$$\begin{matrix}[ Expression 2 ] & \\ {θ}_{B} = 43.09 - 27.5 \times ( \frac{{ }_{{T}_{IDT}}}{λ} \times ρ - 0.19 \; 56 ) - 19.2 \times ( {D}_{u} - 0 .5 ) + 17.4578 \times ( \frac{{T}_{LT}}{λ} - 0.35 ) + 5.619 \times ( \frac{{T}_{V L}}{λ} - 0 .3 ) + 32.66 \times \{ {( \frac{{T}_{LT}}{λ} - 0.35 )}^{2} - 0.01 \; 25 \} + 24.63 \times ( \frac{{T}_{L T}}{λ} - 0.35 ) \times ( \frac{{T}_{VL}}{λ} - 0.3 ) & ( 1 )\end{matrix}$$

With the acoustic wave device (1; 1c; 1g) according to the above-described preferred embodiment, the response intensity of Rayleigh waves is reduced.

In an acoustic wave device (1; 1g) according to a preferred embodiment of the present invention, of the plurality of series arm resonators (acoustic wave resonators 31, 33, 35, 37, 39), one series arm resonator (acoustic wave resonator 31) is electrically closer to the first terminal (101) than the plurality of parallel arm resonators (acoustic wave resonators 32, 34, 36, 38). The one series arm resonator (acoustic wave resonator 31) is the antenna end resonator.

In an acoustic wave device (1c) according to a preferred embodiment of the present invention, one series arm resonator (acoustic wave resonator 31) of the plurality of series arm resonators (acoustic wave resonators 31, 33, 35, 37) and one parallel arm resonator (acoustic wave resonator 32) of the plurality of parallel arm resonators (acoustic wave resonators 32, 34, 36, 38) are directly connected to the first terminal (101). At least one of the one series arm resonator (acoustic wave resonator 31) and the one parallel arm resonator is the antenna end resonator.

In an acoustic wave device (1; 10; 1g) according to a preferred embodiment of the present invention, the antenna end resonator is a chip different from the acoustic wave resonators (32 to 39) other than the antenna end resonator in the plurality of acoustic wave resonators (31 to 39).

With the acoustic wave device (1; 1c; 1g) according to the above-described preferred embodiment, variations in the characteristics of the acoustic wave resonators other than the antenna end resonator are significantly reduced or prevented.

A multiplexer (100; 100b) according to a preferred embodiment of the present invention includes a first filter (11) and a second filter (12). The first filter (11) includes an acoustic wave device (1; 1c; 1g) according to a preferred embodiment of the present invention. The second filter (12) is provided between the first terminal (101) and a third terminal (103) different from the first terminal (101). A pass band of the first filter (11) is at frequencies lower than a pass band of the second filter (12).

With the multiplexer (100; 100b) according to the above-described preferred embodiment, the influence of higher modes, which occur in the first filter (11), on the second filter (12) is significantly reduced or prevented.

A multiplexer (100; 100b) according to a preferred embodiment of the present invention, includes a plurality of resonator groups (30) each including the plurality of acoustic wave resonators (31 to 39). For the plurality of resonator groups (30), the first terminal (101) is a common terminal, and the second terminal (102) is each individual terminal. The antenna end resonators of the plurality of resonator groups (30) are integrated into a single chip.

With the multiplexer (100; 100b) according to the above-described preferred embodiment, variations in the characteristics of the antenna end resonators of the plurality of resonator groups (30) are reduced, and the size of the multiplexer (100; 100b) is reduced.

In a multiplexer (100; 100b) according to a preferred embodiment of the present invention, a maximum frequency of a pass band of the first filter (11) is lower than a minimum frequency of a pass band of the second filter (12).

A radio-frequency front-end circuit (300) according to a preferred embodiment of the present invention includes a multiplexer (100; 100b) according to a preferred embodiment of the present invention, and an amplifier circuit (303) connected to the multiplexer (100; 100b).

The radio-frequency front-end circuit (300) according to the above-described preferred embodiment is able to significantly reduce or prevent higher modes.

A communication device (400) according to a preferred embodiment of the present invention includes a radio-frequency front-end circuit (300) according to a preferred embodiment of the present invention, and an RF signal processing circuit (401). The RF signal processing circuit (401) processes a radio-frequency signal received by an antenna (200). The radio-frequency front-end circuit (300) transmits a radio-frequency signal between the antenna (200) and the RF signal processing circuit (401).

With the communication device (400) according to the above-described preferred embodiment, higher modes are significantly reduced or prevented.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device that is provided between a first terminal defining and functioning as an antenna terminal and a second terminal different from the first terminal, the acoustic wave device comprising:
a plurality of acoustic wave resonators; wherein
the plurality of acoustic wave resonators include:
a plurality of series arm resonators provided in a first path connecting the first terminal and the second terminal; and
a plurality of parallel arm resonators provided in a plurality of second paths each connecting an associated one of a plurality of nodes in the first path and a ground;
of the plurality of acoustic wave resonators, the acoustic wave resonator electrically closest to the first terminal is an antenna end resonator;
the antenna end resonator is a first acoustic wave resonator, a SAW resonator, or a BAW resonator;
of the plurality of acoustic wave resonators, at least one acoustic wave resonator other than the antenna end resonator is a second acoustic wave resonator or a third acoustic wave resonator;
the antenna end resonator is the first acoustic wave resonator, the at least one acoustic wave resonator is the second acoustic wave resonator;
the antenna end resonator is the SAW resonator or the BAW resonator, the at least one acoustic wave resonator is the third acoustic wave resonator;
the SAW resonator includes:
a piezoelectric substrate; and
a first interdigital transducer electrode provided on or above the piezoelectric substrate and including a plurality of electrode fingers;
each of the first acoustic wave resonator, the second acoustic wave resonator, and the third acoustic wave resonator includes:
a piezoelectric layer;
a second interdigital transducer electrode provided on or above the piezoelectric layer and including a plurality of electrode fingers; and
a high acoustic velocity member located across the piezoelectric layer from the second interdigital transducer electrode and through which bulk waves propagate at an acoustic velocity higher than acoustic waves propagate through the piezoelectric layer;
a wave length of acoustic waves, which is determined by an electrode finger pitch of the second interdigital transducer electrode, is λ, a thickness of the piezoelectric layer is less than or equal to about 3.5λ;
the antenna end resonator is the first acoustic wave resonator and the at least one acoustic wave resonator is the second acoustic wave resonator, the acoustic wave device satisfies at least one of a first condition, a second condition, and a third condition;
the first condition is a condition that the high acoustic velocity member of the first acoustic wave resonator and the high acoustic velocity member of the second acoustic wave resonator each include a silicon substrate, a surface closer to the piezoelectric layer in the silicon substrate of the first acoustic wave resonator is a (111) plane or a (110) plane, and a surface closer to the piezoelectric layer in the silicon substrate of the second acoustic wave resonator is a (100) plane;
the second condition is a condition that the piezoelectric layer of the first acoustic wave resonator is thinner than the piezoelectric layer of the second acoustic wave resonator; and
the third condition is a condition that each of the first acoustic wave resonator and the second acoustic wave resonator includes a low acoustic velocity film provided between the high acoustic velocity member and the piezoelectric layer and through which bulk waves propagate at an acoustic velocity lower than bulk waves propagate through the piezoelectric layer, and the low acoustic velocity film of the first acoustic wave resonator is thinner than the low acoustic velocity film of the second acoustic wave resonator.

2. The acoustic wave device according to claim 1, wherein
the BAW resonator includes:
a first electrode;
a piezoelectric film provided on or above the first electrode; and
a second electrode provided on or above the piezoelectric film.

3. The acoustic wave device according to claim 1, wherein
when the antenna end resonator is the first acoustic wave resonator and the at least one acoustic wave resonator is the second acoustic wave resonator, the acoustic wave device satisfies a fourth condition; and
the fourth condition is a condition that a mass per unit length in an electrode finger longitudinal direction of each of the electrode fingers of the second interdigital transducer electrode of the first acoustic wave resonator is greater than the mass per unit length in an electrode finger longitudinal direction of each of the electrode fingers of the second interdigital transducer electrode of the second acoustic wave resonator.

4. The acoustic wave device according to claim 1, wherein
where the antenna end resonator is the first acoustic wave resonator and the at least one acoustic wave resonator is the second acoustic wave resonator, the acoustic wave device satisfies a fourth condition; and
the fourth condition is a condition that a mass per unit length in an electrode finger longitudinal direction of each of the electrode fingers of the second interdigital transducer electrode of the first acoustic wave resonator is less than the mass per unit length in an electrode finger longitudinal direction of each of the electrode fingers of the second interdigital transducer electrode of the second acoustic wave resonator.

5. The acoustic wave device according to claim 1, wherein
where the antenna end resonator is the first acoustic wave resonator and the at least one acoustic wave resonator is the second acoustic wave resonator:
the acoustic wave device satisfies at least one of the first condition and the second condition; and
of the first acoustic wave resonator and the second acoustic wave resonator, only the first acoustic wave resonator includes a low acoustic velocity film provided between the high acoustic velocity member and the piezoelectric layer and through which bulk waves propagate at an acoustic velocity low;

6. The acoustic wave device according to claim 1, wherein
where the antenna end resonator is the first acoustic wave resonator and the at least one acoustic wave resonator is the second acoustic wave:
the acoustic wave device satisfies at least one of the first condition and the second condition; and
of the first acoustic wave resonator and the second acoustic wave resonator, only the second acoustic wave resonator includes a low acoustic velocity film provided between the high acoustic velocity member and the piezoelectric layer and through which bulk waves propagate at an acoustic velocity lower than bulk waves propagate through the piezoelectric layer.

7. The acoustic wave device according to claim 1, wherein
a material of the piezoelectric layer is lithium tantalate or lithium niobate;
a material of the low acoustic velocity film is silicon oxide; and
a material of the high acoustic velocity member is silicon.

8. The acoustic wave device according to claim 1, wherein
the high acoustic velocity member includes:
a high acoustic velocity film through which bulk waves propagate at an acoustic velocity higher than acoustic waves propagate through the piezoelectric layer; and
a support substrate supporting the high acoustic velocity film;
each of the first acoustic wave resonator, the second acoustic wave resonator, and the third acoustic wave resonator includes a low acoustic velocity film provided on or above the high acoustic velocity film and through which bulk waves propagate at an acoustic velocity lower than bulk waves propagate through the piezoelectric layer; and
when the acoustic wave device satisfies the first condition, the support substrate is the silicon substrate.

9. The acoustic wave device according to claim 8, wherein
a material of the piezoelectric layer is lithium tantalate or lithium niobate;
a material of the low acoustic velocity film is at least one material selected from a group consisting of silicon oxide, glass, silicon oxynitride, tantalum oxide, and a chemical compound provided by adding fluorine, carbon, or boron to silicon oxide; and
a material of the high acoustic velocity film is at least one material selected from a group consisting of diamond-like carbon, aluminum nitride, aluminum oxide, silicon carbide, silicon nitride, silicon, sapphire, lithium tantalate, lithium niobate, quartz crystal, alumina, zirconia, cordierite, mullite, steatite, forsterite, magnesia, and diamond.

10. The acoustic wave device according to claim 1, wherein
each of the first acoustic wave resonator, the second acoustic wave resonator, and the third acoustic wave resonator includes a low acoustic velocity film provided between the high acoustic velocity member and the piezoelectric layer and through which bulk waves propagate at an acoustic velocity lower than bulk waves propagate through the piezoelectric layer; and
the high acoustic velocity member is a high acoustic velocity support substrate through which bulk waves propagate at an acoustic velocity higher than acoustic waves propagate through the piezoelectric layer.

11. The acoustic wave device according to claim 1, wherein
when the acoustic wave device satisfies the second condition, each of the first acoustic wave resonator and the second acoustic wave resonator further includes a dielectric film provided between the piezoelectric layer and the second interdigital transducer electrode; and
a thickness of the dielectric film of the first acoustic wave resonator is greater than a thickness of the dielectric film of the second acoustic wave resonator.

12. The acoustic wave device according to claim 1, wherein
where the antenna end resonator is the first acoustic wave resonator and the at least one acoustic wave resonator is the second acoustic wave resonator:
the acoustic wave device satisfies at least one of the first condition and the second condition; and
of the first acoustic wave resonator and the second acoustic wave resonator, only the first acoustic wave resonator further includes a dielectric film provided between the piezoelectric layer and the second interdigital transducer electrode.

13. The acoustic wave device according to claim 1, wherein
where the antenna end resonator is the first acoustic wave resonator and the at least one acoustic wave resonator is the second acoustic wave resonator:
the acoustic wave device satisfies at least one of the first condition and the second condition; and
of the first acoustic wave resonator and the second acoustic wave resonator, only the second acoustic wave resonator further includes a dielectric film provided between the piezoelectric layer and the second interdigital transducer electrode.

14. The acoustic wave device according to claim 1, wherein
where the antenna end resonator is the first acoustic wave resonator and the at least one acoustic wave resonator is the second acoustic wave resonator, in the acoustic wave device, a cut angle of the piezoelectric layer of the first acoustic wave resonator is greater than a cut angle of the piezoelectric layer of the second acoustic wave resonator.

15. The acoustic wave device according to claim 1, wherein
where the antenna end resonator is the first acoustic wave resonator and the at least one acoustic wave resonator is the second acoustic wave resonator in the acoustic wave device, for the first acoustic wave resonator, where the wave length is λ [μm], a thickness of the second interdigital transducer electrode is T_{IDT} [μm], a specific gravity of the second interdigital transducer electrode is ρ [g/cm³], a duty ratio that is a value determined by dividing a width of each electrode finger by a value half the electrode finger pitch is Dᵤ, a thickness of the piezoelectric layer is T_{LT} [μm], and a thickness of the low acoustic velocity film is T_{VL} [μm], a cut angle of the piezoelectric layer of the first acoustic wave resonator falls within a range of ±4° from θ₀[° ] determined by a following expression (1):
$$\begin{matrix}[ Expression 1 ] & \\ {θ}_{B} = 43.09 - 27.5 \times ( \frac{{ }_{{T}_{IDT}}}{λ} \times ρ - 0.19 \; 56 ) - 19.2 \times ( {D}_{u} - 0 .5 ) + 17.4578 \times ( \frac{{T}_{LT}}{λ} - 0.35 ) + 5.619 \times ( \frac{{T}_{V L}}{λ} - 0 .3 ) + 32.66 \times \{ {( \frac{{T}_{LT}}{λ} - 0.35 )}^{2} - 0.01 \; 25 \} + 24.63 \times ( \frac{{T}_{L T}}{λ} - 0.35 ) \times ( \frac{{T}_{VL}}{λ} - 0 .3 ) . & ( 1 )\end{matrix}$$

16. The acoustic wave device according to claim 1, wherein
of the plurality of series arm resonators, one series arm resonator is electrically closer to the first terminal than the plurality of parallel arm resonators; and
the one series arm resonator is the antenna end resonator.

17. The acoustic wave device according to claim 1, wherein
one series arm resonator of the plurality of series arm resonators and one parallel arm resonator of the plurality of parallel arm resonators are directly connected to the first terminal; and
at least one of the one series arm resonator and the one parallel arm resonator is the antenna end resonator.

18. The acoustic wave device according to claim 1, wherein the antenna end resonator is a chip different from the at least one acoustic wave resonator.

19. A multiplexer comprising:
a first filter including the acoustic wave device according to claim 1; and
a second filter provided between the first terminal and a third terminal different from the first terminal; wherein
a pass band of the first filter is at frequencies lower than a pass band of the second filter.

20. The multiplexer according to claim 19, comprising:
a plurality of resonator groups each including the plurality of acoustic wave resonators; wherein
for the plurality of resonator groups, the first terminal is a common terminal and the second terminal is each individual terminal; and
the antenna end resonators of the plurality of resonator groups are integrated in a single chip.

21. The multiplexer according to claim 19, wherein a maximum frequency of the pass band of the first filter is lower than a minimum frequency of the pass band of the second filter.

22. A radio-frequency front-end circuit comprising:
the multiplexer according to claim 19; and
an amplifier circuit connected to the multiplexer.

23. A communication device comprising:
the radio-frequency front-end circuit according to claim 22; and
an RF signal processing circuit to process a radio-frequency signal received by an antenna; wherein
the radio-frequency front-end circuit transmits the radio-frequency signal between the antenna and the RF signal processing circuit.
